(19) United States
(12) Patent Application Publication
(10) Pub. No.: US 2008/0122454 A1
(43) Pub. Date: May 29, 2008

(54) Capacitance detecting apparatus

(75) Inventor: Manabu Kato, Nagoya-shi (JP)

Correspondence Address: BUCHANAN, INGERSOLL & ROONEY PC, POST OFFICE BOX 1404, ALEXANDRIA, VA, 22313-1404, US

(73) Assignee: AISIN SEIKI KABUSHIKI KAISHA, Kariya-shi (JP)

(21) Appl. No.: 11/987,208

(22) Filed: Nov. 28, 2007

(30) Foreign Application Priority Data
Nov. 29, 2006 (JP) 2006-321613
Nov. 7, 2007 (JP) 2007-289624

(51) Int. Cl. G01R 27/26

(52) U.S. Cl. 324/661

(57) ABSTRACT

A capacitance detecting apparatus includes a first differential amplifier, a first reference capacitor, a first on/off switch, a second on/off switch, a third on/off switch, a first sensor electrode facing a ground electrode, a first variable capacitance being formed between the first sensor electrode and the ground electrode in response to a distance between the first sensor electrode and the ground electrode, switch controlling means for performing first to third switch operations, a comparator comparing an output voltage from the first differential amplifier and a voltage input to one of input terminals, counting means for counting the number of times the second switch operation is repeated, and determining means for determining changes in the first variable capacitance based on the number of times the second switch operation is repeated before an output level of the comparator is changed.

### CROSS REFERENCE TO RELATED APPLICATIONS

This application is based on and claims priority under 35 U.S.C. § 119 to Japanese Patent Applications No. 2006-321613, filed on Nov. 29, 2006 and No. 2007-289624, filed on Nov. 7, 2007, the entire content of which is incorporated herein by reference.

### FIELD OF THE INVENTION

This invention generally relates to a capacitance detecting apparatus.

### BACKGROUND

U.S. Pat. No. 6,466,036 (reference 1) and JP2005-106665A (reference 2) disclose conventional capacitance detecting apparatus.

The capacitance detecting apparatus is incorporated in a system for controlling an opening/closing operation of a door for a vehicle such as an automobile. A detection signal of the capacitance detecting apparatus is employed as a trigger signal for unlocking the vehicle door. Specifically, a control system is set at a door-unlock allowing mode when an ID code is matched between an in-vehicle control unit and an operator approaching the vehicle. In this case, when the operator touches an unlock sensor (electrode) housed inside an outside door handle of the vehicle door, the capacitance detecting apparatus detects changes in the capacitance at the electrode and outputs a trigger signal for unlocking the vehicle door. In other words, the capacitance detecting apparatus detects an intention of the operator for unlocking based upon the changes in the capacitance, so that the trigger signal for unlocking is outputted.

A capacitance detecting apparatus is incorporated in a safety device for controlling a distance between a head of an occupant and a headrest of a seat, thereby evading whiplash injury that may occur upon a vehicle rear impact. The capacitance detecting apparatus can be employed as a distance sensor for detecting a distance between the head of the occupant and the headrest based upon changes in capacitance in response to a distance between an electrode embedded in the headrest and the head of the occupant.

As illustrated in FIG. 36, according to the capacitance detecting apparatus disclosed in Reference 1, one end of a reference capacitor Cs is connected to a DC power-supply via an on/off switch S1. The reference capacitor Cs is connected, at the other end, to a variable capacitor Cx and an on/off switch S2. One end of the variable capacitor Cx is grounded, or connected to a free space, via a sensor electrode E1. Both ends of the reference capacitor Cs are connected to an on/off switch S3. The reference capacitor Cs is connected, at the one end, to a comparator CMP and a control circuit. The comparator CMP serves as a voltage measuring unit for measuring a voltage at the one end of the reference capacitor Cs.

As illustrated in FIG. 37, first of all, the on/off switches S2 and S3 are closed so that the reference capacitor Cs and the variable capacitor Cx are electrically discharged. Next, the on/off switch S1 is closed so that the reference capacitor Cs and the variable capacitor Cx are electrically charged by the DC power-supply. The voltage at the reference capacitor Cs hence increases up to a level of voltage defined by a ratio between a capacitance of the reference capacitor Cs and a capacitance of the variable capacitor Cx. The on/off switch S1 is then opened and the on/off switch S2 is then closed, whereby the other end of the reference capacitor Cs is grounded. The variable capacitor Cx is electrically discharged, and the voltage measuring unit repeatedly measures the voltage of the reference capacitor Cs. The control circuit counts a number of times before the voltage of the reference capacitor Cs reaches a predetermined voltage level. A presence, or an absence, of changes in the variable capacitance Cx is detected based upon increment/decrement of the number of times.

Reference 1 further discloses a capacitance detecting apparatus for detecting a presence, or an absence, of changes in two variable capacitances. In this capacitance detecting apparatus, a reference capacitor Cs is connected to a first sensor electrode at one end and to a second sensor electrode at the other end. The first sensor electrode is connected to a variable capacitor Cx1 of which one end is grounded or connected to a free space. The second sensor electrode is connected to a variable capacitor Cx2 of which one end is grounded or connected to a free space. The one end of the reference capacitor Cs is connected to a DC power-supply via an on/off switch S1 and is grounded via an on/off switch S2. The other end of the reference capacitor Cs is connected to a DC power-supply via an on/off switch S3 and is grounded via an on/off switch S4. In this capacitance detecting apparatus; the on/off switches S1 to S4 are operated and voltages at both ends of the reference capacitor Cs are measured by two voltage measuring units, respectively. As a result, a presence, or an absence, of changes in capacitance at each variable capacitor Cx1, Cx2 is detected.

In the capacitance detecting apparatus disclosed in Reference 2, one end of a reference capacitor Cs, which is connected to an on/off switch S1, is connected to a DC power-supply, the other end of the reference capacitor Cs is connected to one end of a variable capacitor Cx, and the other end of the variable capacitor Cx is grounded. An on/off switch S3 is connected to the one end, and the other end, of the variable capacitor Cx. The capacitance detecting apparatus alternately repeats a second switch operation, by which the on/off switch S2 is switched to a closed state and returned to an open state, and a third switch operation, by which the on/off switch S3 is switched to a closed state and returned to an open state, following a first switch operation, by which the on/off switch S1 is switched to a closed state. The capacitance detecting apparatus detects changes in a value of capacitance of the variable capacitor Cx based upon a number of times of the second switch operation before the voltage of the other end of the reference capacitor Cs reaches a predetermined voltage level.

According to each capacitance detecting apparatus disclosed in Reference 1 or 2, the voltage of the reference capacitor Cs is measured through repetition of a process of connecting the variable capacitor Cx to the reference capacitor Cs that has been electrically charged. Thus, the voltage of the reference capacitor Cs is a linear function of a value obtained by multiplying a value, which is acquired by dividing a capacitance value of the reference capacitor Cs by a sum of capacitance values of the variable capacitor Cx and the reference capacitor Cs, by the number of times the variable capacitor Cx is connected to the reference capacitor Cs. Therefore, in the cases where a value of capacitance produced by the sensor electrodes of the variable capacitor Cx is small and also an amount of change in capacitance value is small, accuracy of detecting the change in capacitance may decrease. In addition, in the cases where the capacitance detecting apparatus is employed as a distance sensor for measuring a distance between the sensor electrodes, the voltage of the reference capacitor Cs is the linear function as mentioned above to thereby prevent achievement of an output proportional to a distance between the sensor electrodes with a simple circuit.

Thus, a need exists for a capacitance detecting apparatus which is not susceptible to the drawback mentioned above.

### SUMMARY OF THE INVENTION

According to an aspect of the present invention, a capacitance detecting apparatus includes a first differential amplifier including an inverting input terminal, a non-inverting input terminal, and an output terminal, the non-inverting input terminal inputting a first fixed voltage, a first reference capacitor including a first electrode connected to the output terminal of the first differential amplifier and a second electrode connected to the inverting input terminal of the first differential amplifier, a first on/off switch including a first end connected to the output terminal of the first differential amplifier and a second end connected to the inverting input terminal of the first differential amplifier, a second on/off switch including a first end connected to the inverting input terminal of the first differential amplifier, a third on/off switch including a first end connected to a first power-supply voltage and a second end connected to the second end of the second on/off switch, a first sensor electrode connected to the second end of the second on/off switch and facing a ground electrode having a constant electric potential, a first variable capacitance being formed between the first sensor electrode and the ground electrode in response to a distance between the first sensor electrode and the ground electrode, switch controlling means for performing a first switch operation in which the first on/off switch is shifted to a closed state and returned to an open state, and then alternately repeating a second switch operation in which the second on/off switch is shifted to a closed state and returned to an open state and a third switch operation in which the third on/off switch is shifted to a closed state and returned to an open state, a comparator including a first input terminal connected to the output terminal of the first differential amplifier and a second input terminal inputting a voltage, the comparator comparing an output voltage from the first differential amplifier and the voltage input to the second input terminal, counting means for counting the number of times the second switch operation is repeated, and determining means for determining changes in the first variable capacitance formed between the first sensor electrode and the ground electrode based on the number of times the second switch operation is repeated that is counted by the counting means before an output level of the comparator is changed.

According to another aspect of the present invention, a capacitance detecting apparatus includes a first differential amplifier including an inverting input terminal, a non-inverting input terminal, and an output terminal, the non-inverting input terminal inputting a first fixed voltage, a first reference capacitor including a first electrode connected to the output terminal of the first differential amplifier and a second electrode connected to the inverting input terminal of the first differential amplifier, a first on/off switch including a first end connected to the output terminal of the first differential amplifier and a second end connected to the inverting input terminal of the first differential amplifier, a second on/off switch including a first end connected to the inverting input terminal of the first differential amplifier, a third on/off switch including a first end connected to a first power-supply voltage and a second end connected to the second end of the second on/off switch, a first sensor electrode connected to the second end of the second on/off switch and facing a ground electrode having a constant electric potential, a first variable capacitance being formed between the first sensor electrode and the ground electrode in response to a distance between the first sensor electrode and the ground electrode, a second differential amplifier including an inverting input terminal, a non-inverting input terminal, and an output terminal, the non-inverting input terminal inputting a second fixed voltage, a second referential capacitor including a first electrode connected to the output terminal of the second differential amplifier and a second electrode connected to the inverting input terminal of the second differential amplifier, a fourth on/off switch including a first end connected to the output terminal of the second differential amplifier and a second end connected to the inverting input terminal of the second differential amplifier, a fifth on/off switch including a first end connected to the inverting input terminal of the second differential amplifier, a sixth on/off switch including a first end connected to a second power-supply voltage and a second end connected to the second end of the fifth on/off switch, a second sensor electrode connected to the second end of the fifth on/off switch and facing a ground electrode, a second variable capacitance being formed between the second sensor electrode and the ground electrode in response to a distance between the second sensor electrode and the ground electrode, switch controlling means for performing a first switch operation in which the first on/off switch and the fourth on/off switch are each shifted to a closed state and returned to an open state, and then alternately repeating a second switch operation in which the second on/off switch and the fifth on/off switch are each shifted to a closed state and returned to an open state and a third switch operation in which the third on/off switch and the sixth on/off switch are each shifted to a closed state and returned to an open state, a comparator including a first input terminal connected to the output terminal of the first differential amplifier and a second input terminal connected to the output terminal of the second differential amplifier, the comparator comparing an output voltage from the first differential amplifier and an output voltage from the second differential amplifier, counting means for counting the number of times the second on/off switch operation is repeated, and determining means for determining changes in one of the first and second variable capacitances formed between the first and second sensor electrodes and the ground electrode, respectively, based on the number of times the second on/off switch operation is repeated that is counted by the counting means before an output level of the comparator is changed.

### BRIEF DESCRIPTION OF THE DRAWINGS

The foregoing and additional features and characteristics of the present invention will become more apparent from the following detailed description considered with reference to the accompanying drawings, wherein:

FIG. 1 is a schematic circuit diagram illustrating a capacitance detecting apparatus according to a first embodiment of the present invention;

FIG. 2 is an explanatory view of a portion depicted from A in FIG. 1;

FIGS. 3A to 3F are timing charts for explaining an operation of the capacitance detecting apparatus depicted in FIG. 1;

FIG. 4 is a schematic circuit diagram illustrating a capacitance detecting apparatus according to a second embodiment of the present invention;

FIG. 5 is an explanatory view of a portion depicted from A in FIG. 4;

FIGS. 6A to 6G are timing charts for explaining an operation of the capacitance detecting apparatus depicted in FIG. 4;

FIG. 7 is a schematic circuit diagram illustrating a capacitance detecting apparatus according to a third embodiment of the present invention;

FIG. 8 is a schematic circuit diagram illustrating a capacitance detecting apparatus according to a fourth embodiment of the present invention;

FIGS. 9A, 9B, and 9C are each schematic circuit diagram illustrating a capacitance detecting apparatus according to a fifth embodiment of the present invention;

FIG. 10 is an explanatory view of a portion depicted from A in FIGS. 9A, 9B, and 9C;

FIG. 11A to 11G are timing charts for explaining an operation of the capacitance detecting apparatus depicted in FIGS. 9A, 9B, and 9C;

FIG. 12 is a schematic circuit diagram illustrating a capacitance detecting apparatus according to a sixth embodiment of the present invention;

FIGS. 13A to 13G are timing charts for explaining an operation of the capacitance detecting apparatus depicted in FIG. 12;

FIGS. 14A to 14G are another timing charts for explaining an operation of the capacitance detecting apparatus depicted in FIG. 12;

FIG. 15 is a schematic circuit diagram illustrating a capacitance detecting apparatus according to a seventh embodiment of the present invention;

FIG. 16 is an explanatory view of a portion depicted from A in FIG. 15;

FIGS. 17A to 17G are timing charts for explaining an operation of the capacitance detecting apparatus depicted in FIG. 15;

FIGS. 18A to 18G are another timing charts for explaining an operation of the capacitance detecting apparatus depicted in FIG. 15;

FIG. 19 is a schematic circuit diagram illustrating a capacitance detecting apparatus according to an eighth embodiment of the present invention;

FIG. 20 is an explanatory view of a portion depicted from A in FIG. 19;

FIG. 21A to 21I are timing charts for explaining an operation of the capacitance detecting apparatus depicted in FIG. 20;

FIG. 22 is a schematic circuit diagram illustrating a capacitance detecting apparatus according to a ninth embodiment of the present invention;

FIGS. 23A to 23I are timing charts for explaining an operation of the capacitance detecting apparatus depicted in FIG. 22;

FIG. 24A to 24B are another timing charts for explaining an operation of the capacitance detecting apparatus depicted in FIG. 22;

FIG. 25 is a schematic circuit diagram illustrating a capacitance detecting apparatus according to a tenth embodiment of the present invention;

FIG. 26 is an explanatory view of a portion depicted from A in FIG. 25;

FIGS. 27A to 27I are timing charts for explaining an operation of the capacitance detecting apparatus depicted in FIG. 25;

FIG. 28A to 28I are another timing charts for explaining an operation of the capacitance detecting apparatus depicted in FIG. 25;

FIG. 29 is a view illustrating an example of first and second sensor electrodes;

FIG. 30 is a view illustrating another example of first and second sensor electrodes;

FIG. 31 is a view illustrating still another example of first and second sensor electrodes;

FIG. 32 is a view illustrating still another example of first and second sensor electrodes;

FIG. 33 is a view illustrating still another example of first and second sensor electrodes;

FIG. 34 is a view illustrating still another example of first and second sensor electrodes;

FIG. 35 is a view illustrating still another example of first and second sensor electrodes;

FIG. 36 is a schematic circuit diagram illustrating a conventional capacitance detecting apparatus; and

FIG. 37 is a timing chart for explaining an operation of the capacitance detecting apparatus depicted in FIG. 36.

### DETAILED DESCRIPTION

Embodiments of the present invention will be explained with reference to the attached drawings.

### First Embodiment

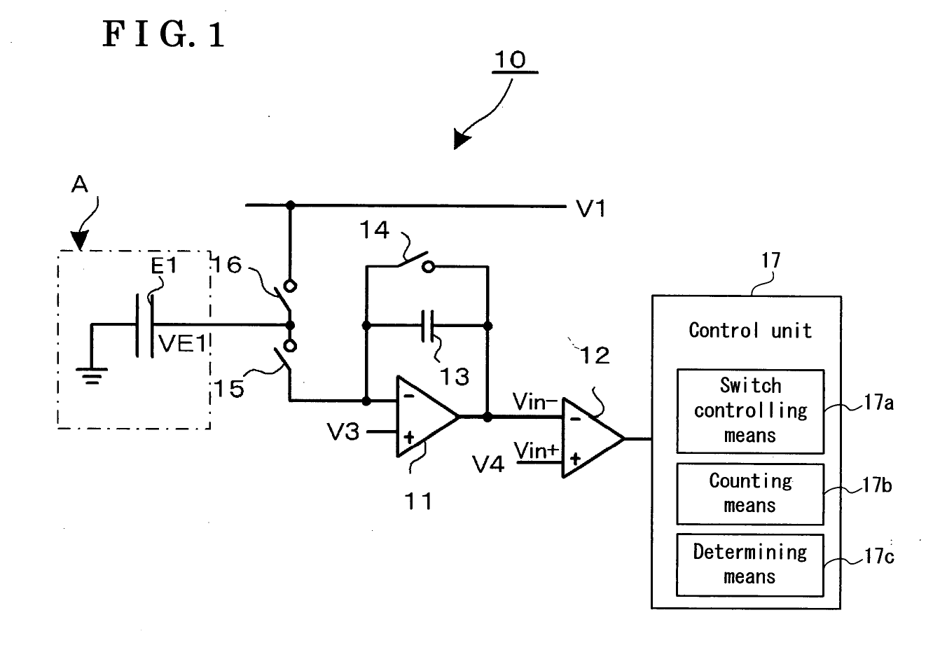

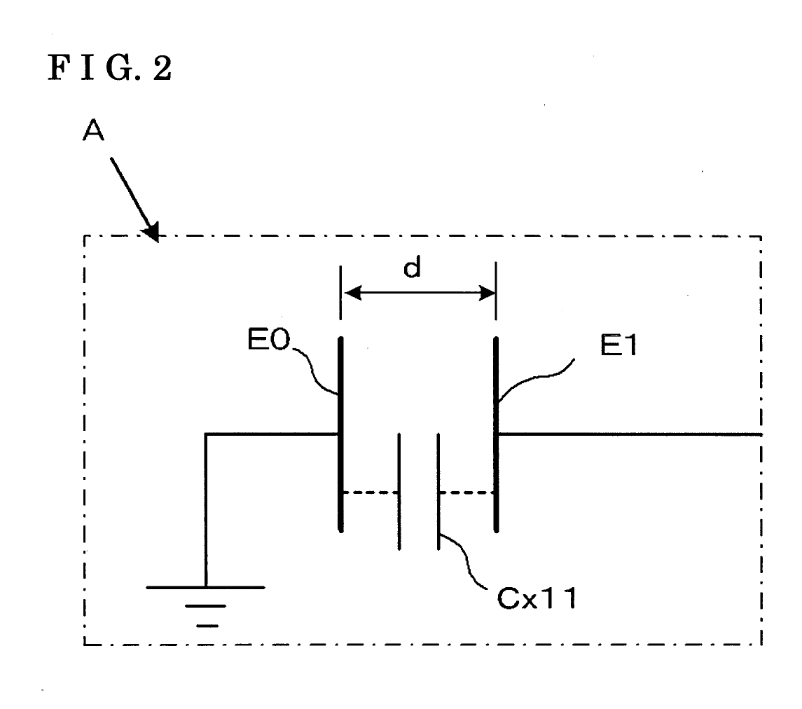

FIG. 1 is a schematic circuit diagram illustrating a capacitance detecting apparatus 10 according to a first embodiment. FIG. 2 is an explanatory view of a portion depicted from A in FIG. 1.

The capacitance detecting apparatus 10 includes a first differential amplifier, i.e., operational amplifier (hereinafter referred to as “Op-Amp”) 11, a comparator 12, a reference capacitor 13 (first reference capacitor), a first on/off switch 14 (S14), a second on/off switch 15 (S15), a third on/off switch 16 (S16), a first sensor electrode E1, and a control unit 17. The control unit 17 includes switch controlling means 17a for controlling a switch operation of each of the on/off switches 14 to 16, counting means 17b for counting the number of “on” and “off” of the on/off switch 15, and determining means 17c for determining whether or not an output level of the comparator 12 is changed so as to output a signal (i.e., output signal) in response to the number counted by the counting means 17b before the output level of the comparator 12 appears to change.

An output terminal of the Op-Amp 11 is connected to a first electrode of the reference capacitor 13, a first end of the on/off switch 14, and a first input terminal, i.e., input terminal (−), of the comparator 12. An inverting input terminal (−) of the Op-Amp 11 is connected to a second electrode of the reference capacitor 13, a second end of the on/off switch 14, and a first end of the on/off switch 15. A second end of the on/off switch 15 is connected to a second end of the on/off switch 16, of which a first end is connected to a first power-supply voltage V1, and to the sensor electrode E1. A non-inverting input terminal (+) of the Op-Amp 11 is connected to a first fixed voltage V3. An electric potential Vin+ of a second input terminal, i.e., input terminal (+), of the comparator 12 is connected to an electric potential having a fixed voltage V4. An output terminal of the comparator 12 is connected to the control unit 17.

As illustrated in FIG. 2, a reference sign Cx11 hereinbelow depicts a first variable capacitance or a first variable capacitor. The first variable capacitor Cx11 includes a ground electrode E0 having substantially a constant electric potential, and the first sensor electrode E1 arranged to face the ground electrode E0. Hence, the sensor electrode E1 serves as an electrode at one end of the first variable capacitor Cx11, and the ground electrode E0 is a grounded medium (measured object), such as a hand of an operator or head of an occupant. The first variable capacitance Cx11 varies in response to a distance between the sensor electrode E1 and the ground electrode E0.

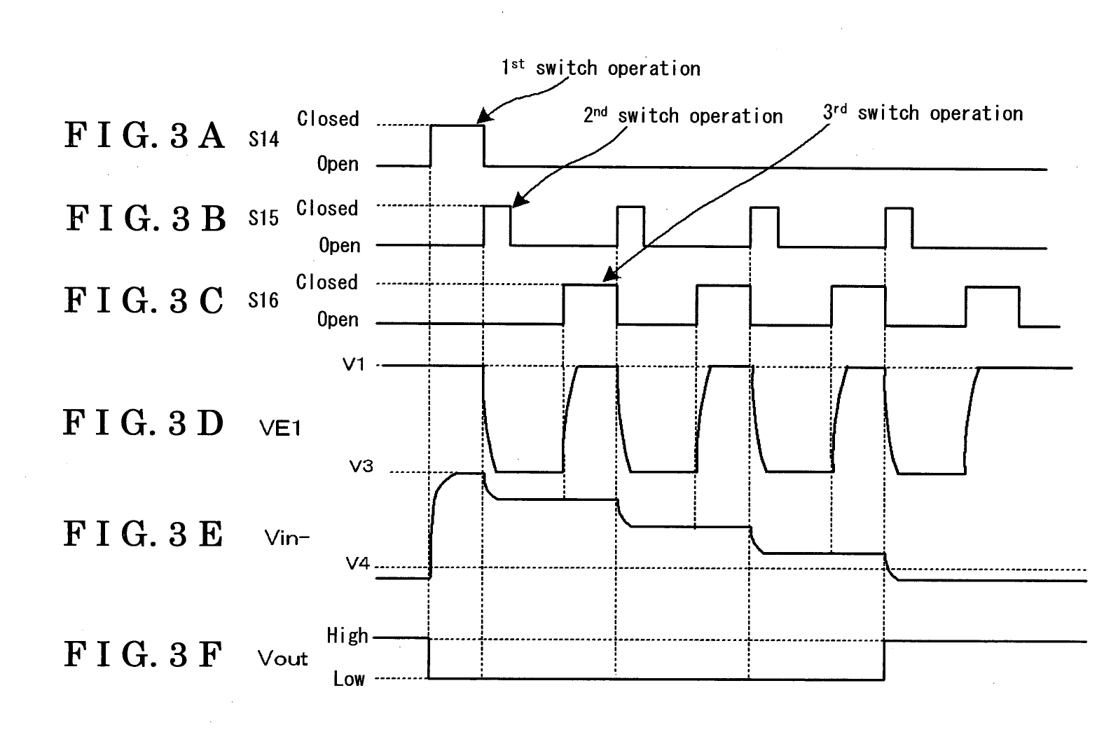

An operation of the capacitance detecting apparatus 10 illustrated in FIG. 1 will be explained with reference to FIGS. 3A to 3F. FIGS. 3A to 3F are timing charts for explaining the operation of the capacitance detecting apparatus depicted in FIG. 1. In FIGS. 3A to 3F, a relationship of magnitude of voltages (electric potentials) V1, V3, and V4 is defined to be V1>V3>V4. However, alternatively, it may be defined to be V1<V3<V4.

In FIGS. 3D and 3E, initially, an electric potential VE1 of the sensor electrode E1 is electrically charged at the power-supply voltage V1 while an electric potential Vin− of the comparator 12 is below the voltage V4. The control unit 17 performs a first switch operation, and thereafter repeatedly and alternately performs a second switch operation and a third switch operation. In the first switch operation, the on/off switch 14 is brought to a closed state for a predetermined time from an open state and is then returned to the open state as illustrated in FIG. 3A. In the second switch operation, the on/off switch 15 is brought to a closed state for a predetermined time from an open state and is then returned to the open state as illustrated in FIG. 3B. In the third switch operation, the on/off switch 16 is brought to a closed state for a predetermined time from an open state and is then returned to the open state as illustrated in FIG. 3C. In this case, the on/off switch 16 may be retained in the closed state for at least a portion of a time period while the on/off switch 14 is in the closed state. Then, before the on/off switch 15 is shifted from the open state to the closed state, the on/off switch 16 may be shifted to the open state from the closed state.

According to the first switch operation, both electrodes of the reference capacitor 13 are short-circuited to each other. Then, an electric potential of the output terminal of the Op-Amp 11 and the electric potential Vin− of the input terminal (−) of the comparator 12 both exceed the voltage V4 and increase to the voltage V3 as illustrated in FIG. 3E. As a result, an output signal Vout of the comparator 12 changes from the high level to the low level as illustrated in FIG. 3F.

According to the second switch operation, the reference capacitor 13 is electrically charged by the electric charge stored at the sensor electrode E1 until that moment, and at the same time, the electric potential Vin− decreases. In addition, the electric potential VE1 of the sensor electrode E1 decreases through the second switch operation. However, the electric potential VE1 of the sensor electrode E1 turns to the power-supply voltage V1 again through the third switch operation.

In response to the number of times the second and third switch operations are repeated, the electric potential Vin− of the input terminal (−) of the comparator 12 decreases. When the electric potential Vin− of the input terminal of the comparator 12 becomes equal to or smaller than the voltage V4, the output signal Vout of the comparator 12 changes to the high level from the low level. The control unit 17 counts the number of times the second switch operation is repeated before the output signal Vout of the comparator 12 appears to change to the high level and then outputs a calculation result of a function of that number of times counted.

A parallel circuit formed by the reference capacitor 13 and the on/off switch 14 functions as a negative feedback impedance of the Op-Amp 11. According to the first switch operation, the electric potential of the output terminal of the Op-Amp 11, i.e., the electric potential Vin− of the input terminal of the comparator 12 becomes equal to the fixed voltage V3. Upon repetition of the second and third switch operations, the electric potential Vin− of the input terminal of the comparator 12 is obtained from an equation 1 below based on a relationship among a repeated number of times of the second switch operation, which is represented by “n”, the variable capacitance Cx11 of the capacitor including the sensor electrode E1 at one end, a capacitance value Cs1 of the reference capacitor 13, and the voltages V1 and V3.

Vin−=V3−n·(V1−V3)·Cx11/Cs1 Equation 1:

### The electric potential Vin− of the input terminal of the comparator 12 changes in proportion to the repeat number of times of the second switch operation.

As long as the repeat number of times of the second switch operation before the shifting of the output signal level of the comparator 12, which is represented by “n0”, is sufficiently large, the variable capacitance Cx11 is obtained from an equation 2 below since a relationship of Cx11·(V1−V3)·n0≡Cs1·(V3−V4) is established.

Cx11=(V3−V4)/(V1−V3)·Cx1/n0 Equation 2:

On the assumption that the capacitor including the sensor electrode E1 at one end is constituted by a plate capacitor a distance d between the sensor electrode E1 and the ground electrode E0 that is an object to be detected is inversely proportional to the variable capacitance Cx11. In addition, the variable capacitance Cx11 and the repeat number of times of the second switch operation n0 are inversely proportional to each other according to the equation 2, which leads to a proportional relationship between the distance d and the repeat number of times of the second switch operation n0. Therefore, the capacitance detecting apparatus 10 illustrated in FIG. 1 can be used as a distance sensor without changing a structure thereof. An output of the capacitance detecting apparatus 10 can be directly used as distance information.

### Second Embodiment

According to the aforementioned first embodiment, the fixed voltage V4 is provided to the input terminal (+) of the comparator 12. However, alternatively, the electric potential Vin+ that changes in reverse phase to the electric potential Vin− of the input terminal (−) of the comparator 12 may be provided to the input terminal (+) of the comparator 12. Such example will be explained below as a second embodiment.

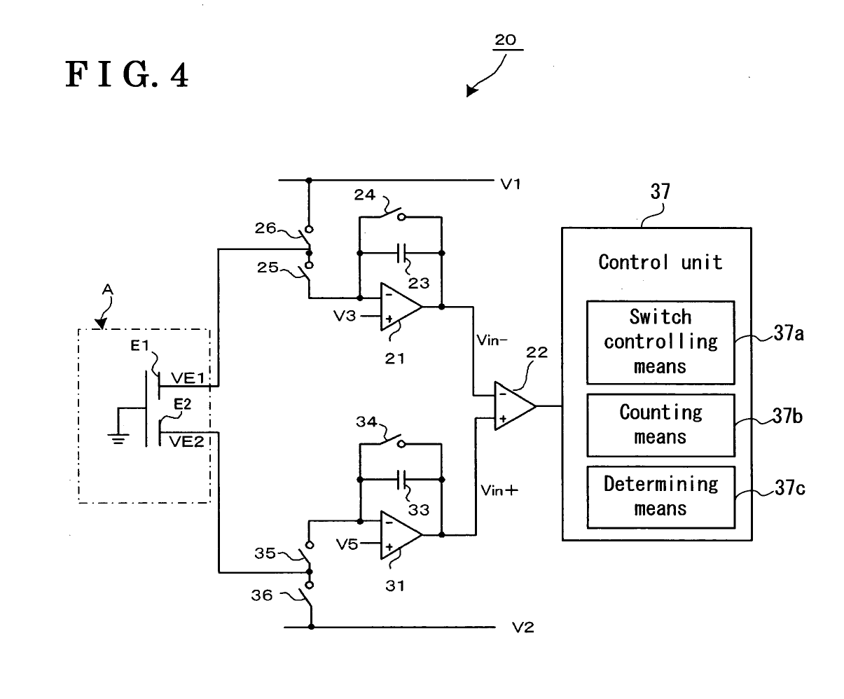

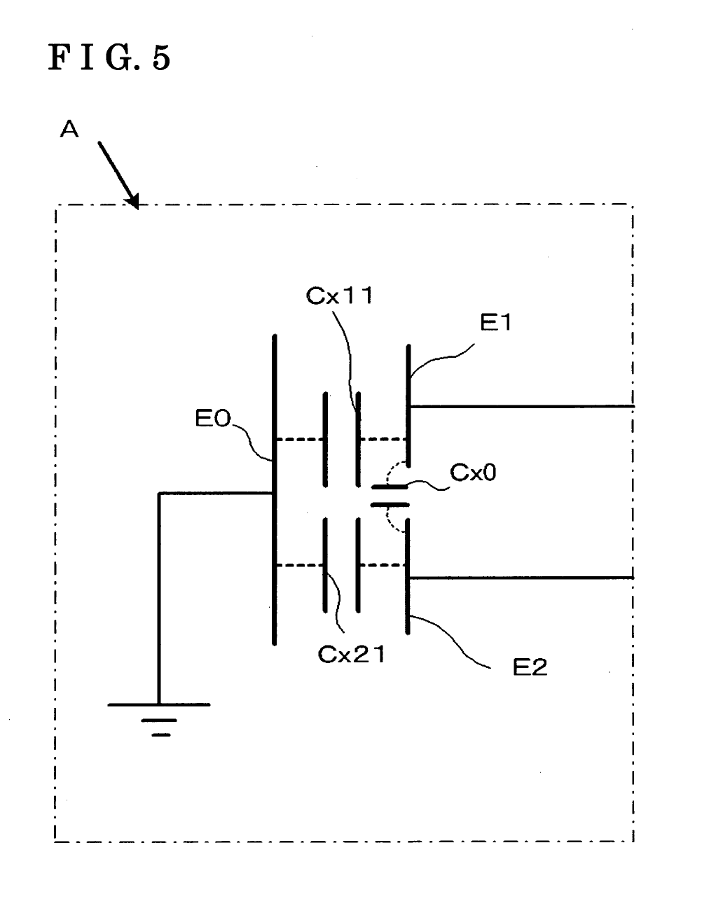

FIG. 4 is a schematic circuit diagram illustrating a capacitance detecting apparatus 20 according to the second embodiment. FIG. 5 is an explanatory view of a portion depicted from A in FIG. 4.

The capacitance detecting apparatus 20 includes a first differential amplifier, i.e., operational amplifier (hereinafter referred to as “Op-Amp”) 21. An output terminal of the Op-Amp 21 is connected to a first input terminal, i.e., input terminal (−), of the comparator 22, a first electrode of a first reference capacitor 23, and a first end of a first on/off switch 24 (S24). An inverting input terminal (−) of the Op-Amp 21 is connected to a second electrode of the reference capacitor 23, a second end of the first on/off switch 24, and a first end of a second on/off switch 25 (S25). A second end of the second on/off switch 25 is connected to a second end of a third on/off switch 26 (S26), of which a first end is connected to the power-supply voltage V1, and to the first sensor electrode E1. A non-inverting input terminal (+) of the Op-Amp 21 is connected to the first fixed voltage V3.

The capacitance detecting apparatus 20 further includes a second differential amplifier, i.e., operational amplifier (hereinafter referred to as “Op-Amp”) 31. An output terminal of the Op-Amp 31 is connected to first electrode of a second reference capacitor 33, a first end of a fourth on/off switch 34, and a second input terminal, i.e., input terminal (+), of the comparator 22. An inverting input terminal (−) of the Op-Amp 31 is connected to the second electrode of the reference capacitor 33, a second end of the on/off switch 34, and a first end of a fifth on/off switch 35.

A second end of the on/off switch 35 is connected to a second end of a sixth on/off switch 36, of which a first end is connected to a second power-supply voltage V2, and a second sensor electrode E2. A non-inverting input terminal (+) of the Op-Amp 31 is connected to a second fixed voltage V5. An output terminal of the comparator 22 is connected to a control unit 37. The control unit 37 includes switch controlling means 37a for controlling a switch operation of each of the on/off switches 25, 26, and 34 to 36, counting means 37b for counting the number of “on” and “off” of each of the on/off switches 25 and 35, and determining means 37c for determining whether or not an output level of the comparator 22 is changed so as to output a signal (i.e., output signal) in response to the number counted by the counting means 37b before the output level of the comparator 22 appears to change.

As illustrated in FIG. 5, in the same way as the reference sine Cx11, a reference sign Cx21 hereinbelow depicts a second variable capacitance or a second variable capacitor. The second variable capacitor Cx21 includes the ground electrode B0 and the second sensor electrode E2 arranged to face the ground electrode E0. Hence, the second sensor electrode E2 serves as an electrode at one side of the second variable capacitor Cx21, and the ground electrode E0 is a grounded medium (measured object), such as a hand of an operator or head of an occupant. The second variable capacitance Cx21 varies in response to a distance between the second sensor electrode E2 and the ground electrode E0. The first and second sensor electrodes E1 and E2 are arranged adjacent to each other. A capacitor Cx0 illustrated in FIG. 5 is a parasitic capacitor formed between the first sensor electrode E1 and the second sensor electrode E2. A relationship of magnitude of the voltages (electric potentials) V1, V2, V3, and V5 is defined to be V1>V3>V5>V2. Alternatively, the relationship may be V1<V3<V5<V2.

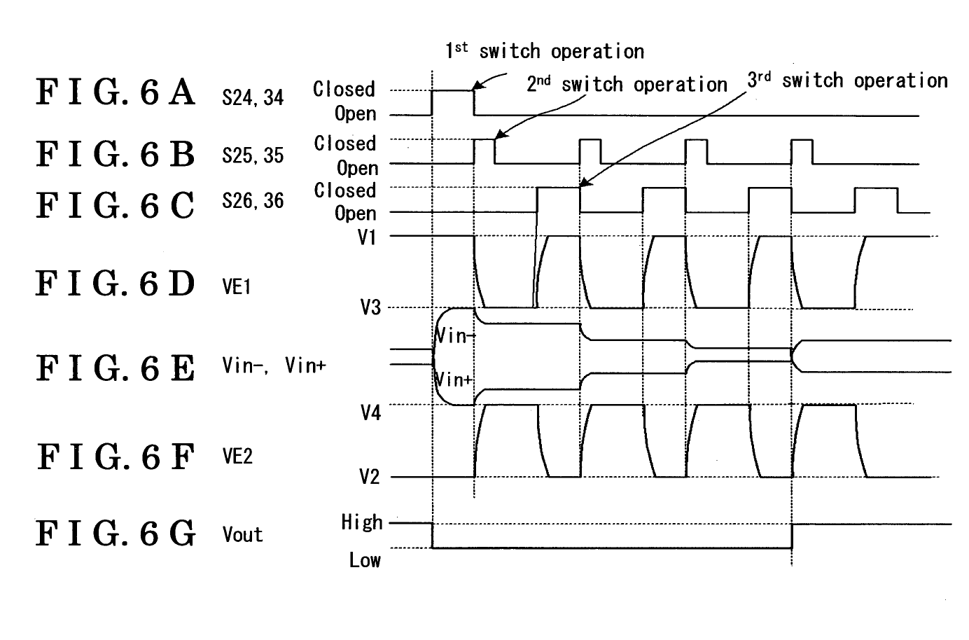

Next, an operation of the capacitance detecting apparatus 20 will be explained with reference to FIGS. 6A to 6G. FIGS. 6A to 6G are timing charts for explaining the operation of the capacitance detecting apparatus 20 illustrated in FIG. 4. Initially, an electric potential VE1 of the sensor electrode E1 is electrically charged at the power-supply voltage V1 while an electric potential VE2 of the sensor electrode E2 is electrically charged at the power-supply voltage V2.

The control unit 37 performs a first switch operation, and thereafter repeatedly and alternately performs a second switch operation and a third switch operation. In the first switch operation, the on/off switches 24 and 34 are each brought to a closed state for a predetermined time from an open state and then are each returned to the open state. In the second switch operation, the on/off switches 25 and 35 are each brought to a closed state for a predetermined time from an open state and then are each returned to the open state. In the third switch operation, the on/off switches 26 and 36 are each brought to a closed state for a predetermined time from an open state and then are each returned to the open state.

According to the first switch operation (see FIG. 6A), the reference capacitors 23 and 33 are electrically discharged. Then, the output terminal of the Op-Amp 21, i.e., electric potential Vin− of the input terminal (−) of the comparator 22, increases while the output terminal of the Op-Amp 31, i.e., electric potential Vin+ of the input terminal (+) of the comparator 22, decreases as illustrated in FIG. 6E. In the cases where levels of the electric potentials Vin− and Vin+, i.e., a relation which is higher or lower, are inverted, the output signal Vout of the comparator 22 changes, for example, from a high level to a low level as illustrated in FIG. 6G.

According to the second switch operation (see FIG. 6B), the reference capacitors 23 and 33 are electrically charged by the electric charge at the sensor electrodes E1 and E2 (see FIGS. 6D and 6F). In addition, the electric potential Vin− of the input terminal (−) of the comparator 22 decreases while the electric potential Vin+ of the input terminal (+) of the comparator 22 increases. According to the third switch operation (see FIG. 6C), the electric potential VE1 of the sensor electrode E1 returns to the power-supply voltage V1 while the electric potential VE2 of the sensor electrode E2 returns to the power-supply voltage V2.

In response to the number of times the second and third switch operations are repeated, levels of the electric potential Vin− of the input terminal (−) of the comparator 22 and the electric potential Vin+ of the input terminal (+) of the comparator 22, i.e., the relation which is higher or lower, are inverted, to each other. As a result, the output signal Vout of the comparator 22 changes to the high level again.

The control unit 37 counts the number of times the second switch operation is repeated before the output signal Vout of the comparator 22 appears to change to the high level and then outputs a calculation result of a function of that number of times counted.

As mentioned above, according to the second embodiment, the Op-Amp 21, the reference capacitor 23, the on/off switches 24 to 26, and the sensor electrode E1 operate in the same way as the Op-Amp 11, the reference capacitor 13, the on/off switches 14 to 16, and the sensor electrode E1 according to the first embodiment. While the Op-Amp 21, the reference capacitor 23, the on/off switches 24 to 26, and the sensor electrode E1 generate the decreasing electric potential Vin− to be supplied to the comparator 22, the Op-Amp 31, the reference capacitor 33, the on/off switches 34 to 36, and the sensor electrode E2 generate the electric potential Vin+, which is in reverse phase to the electric potential Vin−, to be supplied to the comparator 22.

The change in the electric potential Vin− is proportional to the number of times the second switch operation is repeated and is also substantially proportional to a value of the variable capacitance Cx11. In addition, the change in the electric potential Vin+ is proportional to the number of times the second switch operation is repeated and is substantially proportional to a value of the variable capacitance Cx21. Since the variable capacitances Cx11 and Cx21 are inversely proportional to the distance d between the sensor electrodes E1 and E2, and the ground electrode E0, respectively, the number counted by the counting means 37b before the output signal Vout of the comparator 22 appears to change to a high level is a function of the distance d. Thus, in the cases where the capacitance detecting apparatus 20 is used as a distance sensor, the output of the capacitance detecting apparatus 20 can be used as distance information.

Further, according to the aforementioned embodiment, the electric charges corresponding to the variable capacitances Cx11 and Cx21 are stored in the reference capacitors 23 and 33, respectively. A signal on the basis of a difference between electric potentials at both ends of the reference capacitor 23, and a signal on the basis of a difference between electric potentials at both ends of the reference capacitor 33 are compared in the comparator 22 so as to detect values of the variable capacitances Cx11 and Cx21. Then, a ratio of SE1 to Cs2, i.e., SE1/Cs2, wherein SE1 is an area of the sensor electrode E1 and Cs2 is a capacitance of the first reference capacitor 23, and a ratio of SE2 to Cs3, i.e., SE2/Cs3, wherein SE2 is an area of the sensor electrode E2 and Cs3 is a capacitance of the second reference capacitor 33 are equalized so that an effect of electromagnetic disturbances can be prevented. In addition, SE1·(V1−V3) and SE2·(V5−V2) are equalized so that the generation of radio noise can be prevented. For example, areas of the sensor electrodes E1 and E2 are equal to each other and capacitances of the first and second reference capacitors 23 and 33 are equal to each other to thereby prevent the effect of electromagnetic disturbances input to the comparator 22. Further, according to a relationship of V1−V3=V5−V2, generation of ratio noise at the sensor electrodes E1 and E2 can be prevented.

### Third Embodiment

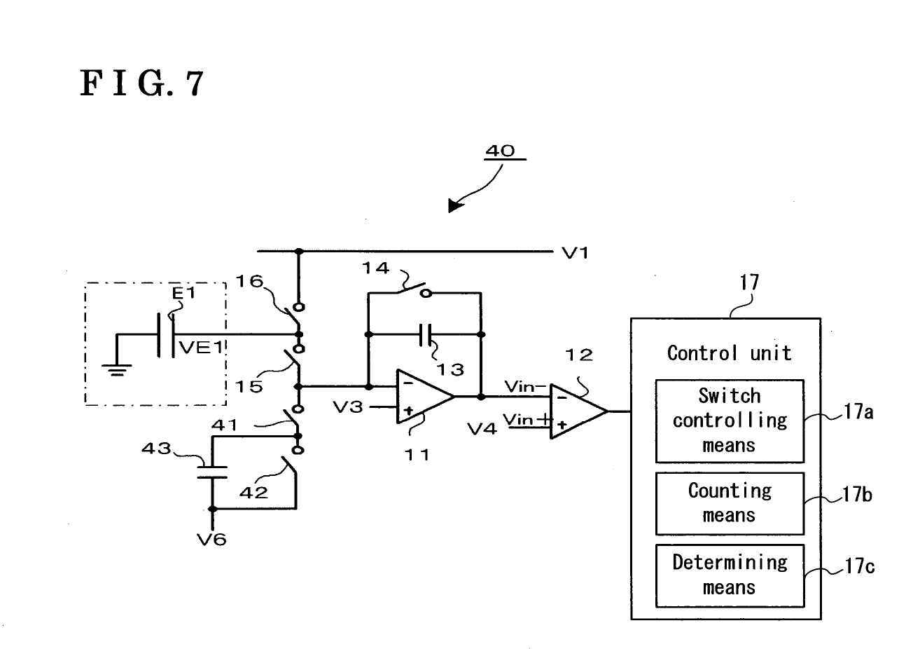

FIG. 7 is a schematic circuit diagram illustrating a capacitance detecting apparatus 40 according to a third embodiment. Parts or elements in FIG. 7 substantially same as those in FIG. 1 bear the same numbers.

The capacitance detecting apparatus 40 includes the Op-Amp 11, the comparator 12, the first reference capacitor 13, the first on/off switch 14, the second on/off switch 15, the third on/off switch 16, the first sensor electrode E1, and the control unit 17 all of which are connected in substantially the same manner as the first embodiment.

The capacitance detecting apparatus 40 further includes a seventh on/off switch 41, an eighth on/off switch 42, and a compensation capacitor 43. A first end of the on/off switch 41 is connected to an inverting input terminal (−) of the Op-Amp 11 while a second end of the on/off switch 41 is connected to a first electrode of the correction capacitor 43 and a first end of the on/off switch 42. A second end of the on/off switch 42 and a second electrode of the compensation capacitor 43 are connected to a compensation voltage V6. The second electrode of the compensation capacitor 43 may be connected to an electric potential having a constant voltage other than the compensation voltage V6. The compensation capacitor 43 and the compensation voltage V6 are provided so as to compensate an electric charge transfer to the reference capacitor 13 because of presence of a parasitic capacitance.

The control unit 17 controls switch operations of the on/off switches 41 and 42 in addition to the on/off switches 14 to 16. According to the control of the control unit 17, the on/off switch 41 is turned on and off at the same timing as the on/off switch 15 while the on/off switch 42 is turned on and off at the same timing as the on/off switch 16.

A relationship of magnitude of the voltages (electric potentials) V1, V3, and the compensation voltage V6 is defined to be V1>V3>V6 or V1<V3<V6. At least one of a capacitance value Cc0 of the compensation capacitor 43 and the compensation voltage V6 is adjustable so as to achieve the following equation 3 as a measure against a parasitic capacitance or capacitor Cα1 (not shown) parasitic on the sensor electrode E1 and a wiring that connects the sensor electrode E1 and the on/off switches 15 and 16.

(V1−V3)·Cα1=(V3−V6)·Cc0 Equation 3:

The control unit 17 of the capacitance detecting apparatus 40 performs a first switch operation, and thereafter repeatedly and alternately performs a second switch operation and a third switch operation. In the first switch operation, the on/off switch 14 is brought to a closed state for a predetermined time from an open state and is then returned to the open state. In the second switch operation, the on/off switches 15 and 41 are each brought to a closed state for a predetermined time from an open state and then are each returned to the open state. In the third switch operation, the on/off switches 16 and 42 are each brought to a closed state for a predetermined time from an open state and then are each returned to the open state.

In the cases where the second switch operation and the third switch operation are repeatedly and alternately performed, the parasitic capacitor Cα1 is electrically charged in addition to a capacitor of which one electrode is formed by the sensor electrode E1 according to the third switch operation. Then, the capacitor of which one electrode is formed by the sensor electrode E1 and the parasitic capacitor Cα1 are made connected to the inverting input terminal (−) of the Op-Amp 11 so as to be electrically discharged according to the second switch operation.

The compensation capacitor 43 is electrically discharged through the third switch operation, and connected to the inverting input terminal (−) of the Op-Amp 11 through the second switch operation. After one cycle of switch operations of the four on/off switches, i.e., open operations of the on/off switches 16 and 42 after the on/off switches 16 and 42 are shifted and retained in the closed state for a predetermined time period, and subsequent open operations of the on/off switches 15 and 41 after the on/off switches 15 and 41 are shifted and retained in the closed state for a predetermined time period, the reference capacitor 13 is electrically charged by the electric charge represented by an equation 4 shown below. In this case, since the capacitance value Cc0 of the compensation capacitor 43 is adjusted in the aforementioned equation 3, the reference capacitor 13 is electrically charged at a value corresponding to the electric charge stored in the parasitic capacitor Cα1 until that moment. Accordingly, on the basis of the relationship between the parasitic capacitor Cα1 and the capacitance value Cc0 in the equation 3, the reference capacitor 13 is electrically charged at (V1−V3)·Cx11, which is substantially equal to the electric charge discharged from the capacitor of which one electrode is formed by the sensor electrode E1. Accordingly, the effect of the parasitic capacitance Cα1 on the reference capacitor 13 and also on the output signal of the Op-Amp 11, i.e., the electric potential Vin− of the inverting input terminal (−) of the comparator 12, can be eliminated.

(V1−V3)·(Cx11+Cα1)+(V6−V3)·Cc0 Equation 4:

In response to the number of times the second and third switch operations are repeated, the electric potential Vin− of the input terminal (−) of the comparator 12 decreases. When the electric potential Vin− of the input terminal of the comparator 12 becomes equal to or smaller than the voltage V4, the output signal Vout of the comparator 12 changes to the high level from the low level. The control unit 17 counts the number of times the second switch operation is repeated before the output signal Vout of the comparator 12 appears to change to the high level and then outputs a calculation result of a function of that number of times counted.

The capacitance detecting apparatus 40 according to the third embodiment includes the Op-Amp 11, the comparator 12, the reference capacitor 13, the on/off switches 14 to 16, and the sensor electrode E1. Since the on/off switches 14 to 16 are turned on and off in the same way as the first embodiment, an output of the capacitance detecting apparatus 40 can be highly accurately converted to distance information in the cases where the capacitance detecting apparatus 40 is used as a distance sensor. Further, the capacitance detecting apparatus 40 includes the on/off switches 41, 42, and the compensation capacitor 43. The on/off switch 41 is turned on and off at the same timing as the on/off switch 15 while the on/off switch 42 is turned on and off at the same timing as the on/off switch 16. Therefore, the effect of the parasitic capacitance Cα1 parasitic on the wiring that connects the sensor electrode E1 and the on/off switches 15 and 16 can be eliminated to thereby improve accuracy of detecting the capacitance.

### Fourth Embodiment

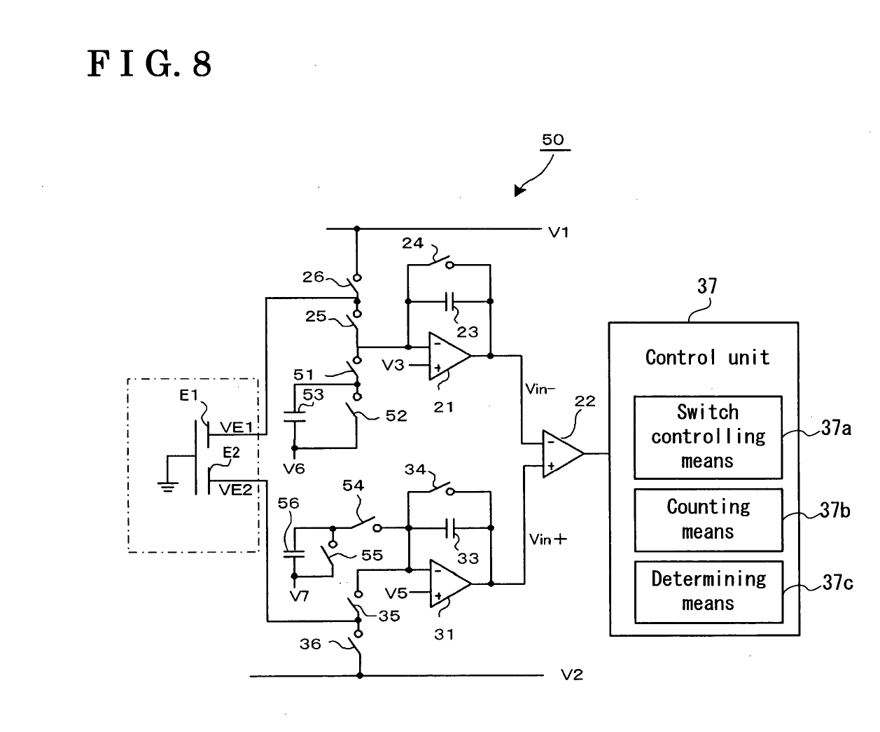

FIG. 8 is a schematic circuit diagram illustrating a capacitance detecting apparatus 50 according to a fourth embodiment. Parts or elements in FIG. 8 substantially same as those in FIG. 4 bear the same numbers. The capacitance detecting apparatus 50 includes the first and second Op-Amps 21 and 31, the comparator 22, the first and second reference capacitors 23 and 33, the first to sixth on/off switches 24, 25, 26, 34, 35, and 36, the first and second sensor electrodes E1 and E2, and the control unit 37 all of which are connected in substantially the same manner as the second embodiment illustrated in FIG. 4.

The capacitance detecting apparatus 50 further includes a seventh on/off switch 51, an eighth on/off switch 52, a first compensation capacitor 53, a ninth on/off switch 54, a tenth on/off switch 55, and a second compensation capacitor 56.

A first end of the on/off switch 51 is connected to the inverting input terminal (−) of the Op-Amp 21 while a second end of the on/off switch 51 is connected to a first electrode of the compensation capacitor 53 and a first end of the on/off switch 52. A second end of the on/off switch 52 and a second electrode of the compensation capacitor 53 are connected to the first compensation voltage V6. The second electrode of the compensation capacitor 53 may be connected to an electric potential having a constant voltage other than the compensation voltage V6.

Further, a first end of the on/off switch 54 is connected to the inverting input terminal (−) of the Op-Amp 31 while a second end of the on/off switch 54 is connected to a first electrode of the compensation capacitor 56 and a first end of the on/off switch 55. A second end of the on/off switch 55 and a second electrode of the compensation capacitor 56 are connected to a second compensation voltage V7. The second electrode of the compensation capacitor 56 may be connected to an electric potential having a constant voltage other than the compensation voltage V7. A relationship of magnitude of the voltages (electric potentials) V1 to V3, and V5 to V7 is defined to be V1>V3>V5>V2, V3>V6, and V7>V5.

At least one of the capacitance value Cc1 of the compensation capacitor 53 and the compensation voltage V6 is adjustable while at least one of a capacitance value Cc2 of the compensation capacitor 56 and the compensation voltage V7 is adjustable. The capacitance value Cc1 and the compensation voltage V6 are adjusted beforehand so as to achieve a relationship of (V1−V3)·Cα1=(V3−V6)·Cc1 (Equation 5) as a measure against a parasitic capacitance or capacitor Cα1 (not shown) parasitic on the sensor electrode E1 and a wiring that connects the sensor electrode E1 and the on/off switches 15 and 16.

In addition, the capacitance value Cc2 and the compensation voltage V7 are adjusted beforehand so as to achieve a relationship of (V5−V2)·Cα2=(V7−V5)·Cc2 (Equation 6) as a measure against a parasitic capacitance or capacitor Cα2 (not shown) parasitic on the sensor electrode E2 and a wiring that connects the sensor electrode E2 and the on/off switches 35 and 36.

The control unit 37 controls the switch operations of the on/off switches 51, 52, 54, and 55 in addition to the on/off switches 24 to 26 and 34 to 36. According to the control of the control unit 37, the on/off switches 51 and 54 are turned on and off at the same timing as the on/off switches 25 and 35, and the on/off switches 52 and 55 are turned on and off at the same timing as the on/off switches 26 and 36.

The control unit 37 of the capacitance detecting apparatus 50 performs, in the same way as the capacitance detecting apparatus 20 of the second embodiment, a first switch operation and thereafter repeatedly and alternately performs a second switch operation and a third switch operation. In the first switch operation, the on/off switches 24 and 34 are each brought to a closed state for a predetermined time from an open state and then are each returned to the open state. In the second switch operation, the on/off switches 25, 35, 51, and 54 are each brought to a closed state for a predetermined time from an open state and then are each returned to the open state. In the third switch operation, the on/off switches 26, 36, 52, and 55 are each brought to a closed state for a predetermined time from an open state and then are each returned to the open state.

In the cases where the second switch operation and the third switch operation are repeatedly performed, the parasitic capacitors Cα1 and Cα2 are electrically charged in addition to capacitors of which respective electrodes at one end are formed by the sensor electrodes E1 and E2 according to the third switch operation. Then, the capacitor of which the electrode at one end is formed by the sensor electrode E1 and the parasitic capacitor Cα1 are made connected to the inverting input terminal (−) of the Op-Amp 21 while the capacitor of which the electrode at one end is formed by the sensor electrode E2 and the parasitic capacitor Cα2 are made connected to the inverting input terminal (−) of the Op-Amp 31 according to the second switch operation.

On the other hand, the compensation capacitors 53 and 56 are electrically discharged through the third switch operation and are connected to the respective inverting input terminals (−) of the Op-Amps 21 and 31 through the second switch operation. Accordingly, after one cycle of switch operations, i.e., one time of second switch operation and one time of third switch operation, the reference capacitor 23 is electrically charged at a value represented by an equation 7 shown below. In addition, the reference capacitor 33 is electrically charged at a value represented by an equation 8 shown below. Since the capacitance values Cc1 and Cc2 of the compensation capacitors 53 and 56, respectively, are adjusted according to the aforementioned equations 5 and 6, the reference capacitors 23 and 33 are electrically charged at values corresponding to electric charges stored in the parasitic capacitors Cα1 and Cα2, respectively, until that moment. According to a relationship between Cα1 and Cc1 in the equation 5 and a relationship between Cα2 and Cc2 in the equation 6, the reference capacitor 23 is electrically charged at (V1−V3)·Cx11 while the reference capacitor 33 is electrically charged at (V2−V5)·Cx21. That is, the reference capacitors 23 and 33 are electrically charged at values substantially equal to the electric charges discharged from the capacitors of which respective electrodes at one end are formed by the sensor electrodes E1 and E2. Accordingly, the effect of the parasitic capacitances Cα1 and Cα2 on the reference capacitors 23 and 33, respectively, can be eliminated to thereby remove the effect of the parasitic capacitors Cα1 and Cα2 on the output signals of the Op-Amps 21 and 31, respectively, i.e., electric potentials of both the imputer terminals of the comparator 22.

(V1−V3)·(Cx11+Cα1)+(V6−V3)·Cc1 Equation 7:

(V2−V5)·(Cx21+Cα2)+(V7−V5)·Cc2 Equation 8:

The control unit 37 counts the number of times the second switch operation is repeated before the output signal Vout of the comparator 22 is shifted to a high level from a low level and then outputs a calculation result of a function of that number of times counted.

The aforementioned capacitance detecting apparatus 50 additionally includes the on/off switches 51 to 55, and the correction capacitors 53 and 56 to the second embodiment as illustrated in FIG. 4. The values of Cc1 or V6, and Cc2 or V7 are adjusted to achieve equations (V1−V3)·Cα1=(V3−V6)·Cc1 and (V5−V2)·Cα2=(V7−V5)·Cc2, respectively so as to eliminate the effect of the parasitic capacitors Cα1 and Cα2 and to enhance accuracy for detecting the capacitance. In addition, according to the present embodiment, in the same way as the capacitance detecting apparatus 20 of the second embodiment, the number of cycles of switch operations performed while the comparator 22 is shifted to the low level and then to the high level is substantially proportional to the distance d between the ground electrode E0 and the sensor electrode E1 or E2. Further, the effect of the parasitic capacitors Cα1 and Cα2 can be eliminated to thereby enhance accuracy of capacitance detection. In the cases where the capacitance detecting apparatus 50 is used as a distance sensor, the output of the capacitance detecting apparatus 50 can be highly accurately converted to distance information.

Furthermore, in the same way as the capacitance detecting apparatus 20 of the second embodiment, a ratio of SE1 to Cs2, i.e., SE1/Cs2, wherein SE1 is an area of the sensor electrode E1 and Cs2 is a capacitance of the first reference capacitor 23, and a ratio of SE2 to Cs3, i.e., SE2/Cs3, wherein SE2 is an area of the sensor electrode E2 and Cs3 is a capacitance of the second reference capacitor 33 are equalized so that an effect of electromagnetic disturbances can be prevented. In addition, SE1·(V1−V3) and SE2·(V5−V2) are equalized so that the generation of radio noise can be prevented. For example, areas of the sensor electrodes E1 and E2 are equal to each other and capacitances of the first and second reference capacitors 23 and 33 are equal to each other to thereby prevent the effect of electromagnetic disturbances input to the comparator 22. Further, according to a relationship of V1−V3=V5−V2, generation of ratio noise at the sensor electrodes E1 and E2 can be prevented.

### Fifth Embodiment

According to the aforementioned third and fourth embodiments, an effect of the parasitic capacitors Cα1 and Cα2 parasitic on the wiring is eliminated and the capacitance detection accuracy is enhanced by using the compensation capacitors 43, 53, 56, and the compensation voltages V6 and V7. Alternatively, the effect of the parasitic capacitors Cα1 and Cα2 can be eliminated by means of a shield member for the sensor electrode and on/off switches. According to fifth to tenth embodiments, the capacitance detecting apparatus having a shield member will be explained.

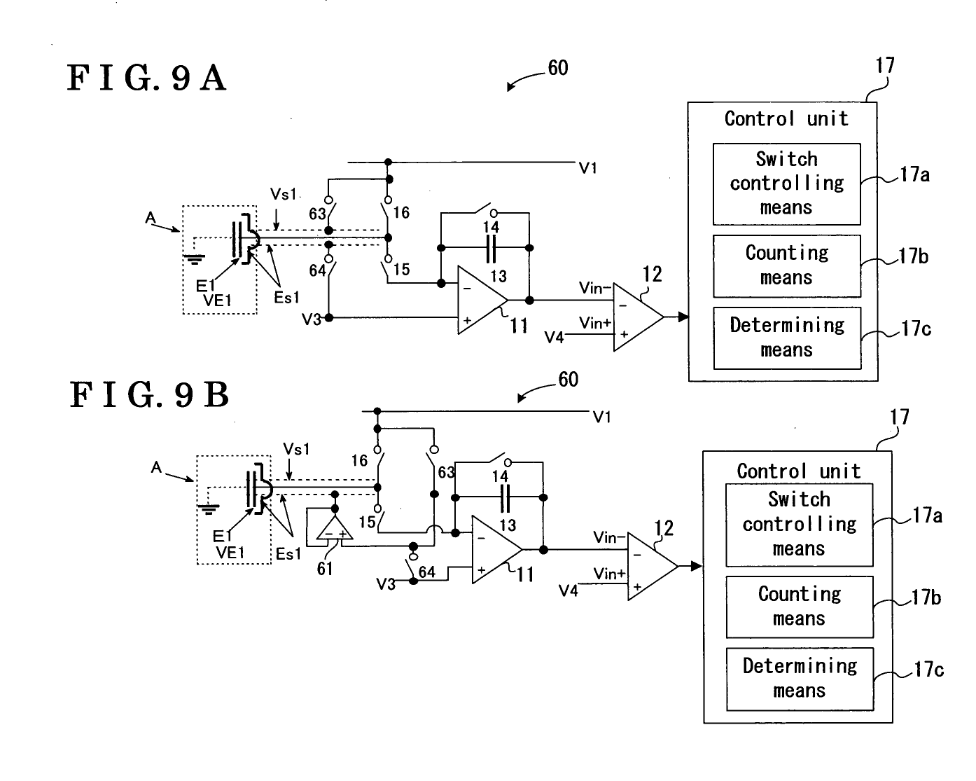

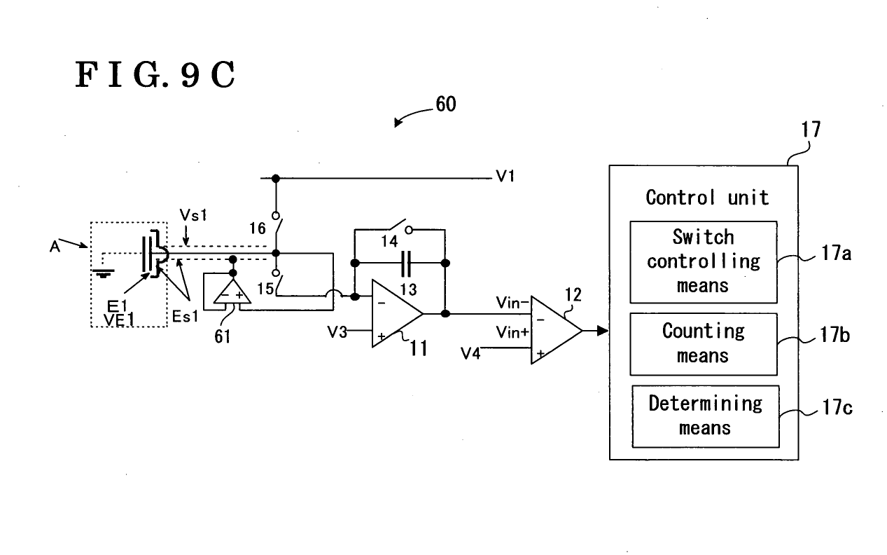

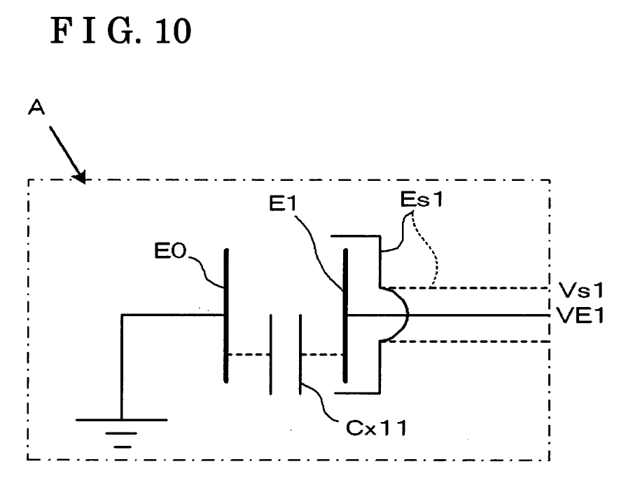

FIG. 9A is a schematic circuit diagram illustrating a capacitance detecting apparatus 60 according to a first example of the fifth embodiment. Parts or elements in FIG. 9A substantially same as those in FIG. 1 bear the same numbers. FIG. 10 is an explanatory view of a portion depicted from A in FIG. 9A.

The capacitance detecting apparatus 60 includes the first Op-Amp 11, the comparator 12, the reference capacitor 13, the first on/off switch 14, the second on/off switch 15, the third on/off switch 16, the sensor electrode E1 forming a capacitor by facing the ground electrode E0 that has substantially a constant electric potential, and the control unit 17 all of which are connected in the same manner as the first embodiment.

The capacitance detecting apparatus 60 further includes a first shield member Es1 that is not included in the first embodiment. The shield member Es1 surrounds electrode surfaces of the sensor electrode E1 except for a surface facing the ground electrode E0 while keeping a predetermined gap with the shielding surfaces. The shield member Es1 also surrounds a wiring connecting the sensor electrode E1 and the on/off switches 15 and 16 while keeping a predetermined gap therebetween.

The shield member Es1 is connected to the power-supply voltage V1 via an eleventh on/off switch 63 (first electric potential supply circuit) and also to the fixed voltage V3 via a twelfth switch 64 (second electric potential supply circuit). Alternatively, according to a second example of the fifth embodiment as illustrated in FIG. 9B, an output terminal of an operational amplifier (Op-Amp) 61, an inverting input terminal of the Op-Amp 61, and the shield member Es1 may be electrically connected to each other. Then, a non-inverting input terminal of the Op-Amp 61 may be connected to the power-supply voltage V1 via the switch 63 and to the fixed voltage V3 via the on/off switch 64. A common operation between the examples of the capacitance detecting apparatus 60 illustrated in FIGS. 9A and 9B will be explained below.

The control unit 17 controls the switch operations of the on/off switches 63 and 64 in addition to the on/off switches 14 to 16. A relationship of magnitude of the voltages (electric potentials) V1, V3, and V4 may be defined to be either V1>V3>V4 or V1<V3<V4.

A basic operation of the capacitance detecting apparatus 60 is substantially the same as that of the first embodiment. FIGS. 11A to 11G are timing charts for explaining an operation of the capacitance detecting apparatus 60 depicted in FIGS. 9A and 9B.

According to the capacitance detecting apparatus 60 of the fifth embodiment, as in the same way as the first embodiment, the control unit 17 of the capacitance detecting apparatus 60 performs a first switch operation, and thereafter repeatedly and alternately performs a second switch operation and a third switch operation. In the first switch operation, the on/off switch 14 is brought to a closed state from an open state and retained in the closed state for a predetermined time, and thereafter is returned to the open state (see FIG. 11A). In the second switch operation, the on/off switch 15 is brought to a closed state from an open state and retained in the closed state for a predetermined time, and thereafter is returned to the open state (see FIG. 11B). In the third switch operation, the on/off switch 16 is brought to a closed state from an open state and retained in the closed state for a predetermined time, and thereafter is returned to the open state (see FIG. 11C). In this case, as illustrated in FIG. 11C, the on/off switch 16 may be shifted from the open state to the closed state so as to be held in the closed state for a predetermined time during the first switch operation.

According to the first switch operation, both electrodes of the reference capacitor 13 are short-circuited to each other. Then, the electric potential Vin− of the input terminal (−) of the comparator 12 increases to the voltage V3 as illustrated in FIG. 11E. As a result, the output signal Vout of the comparator 12 changes from a high level to a low level as illustrated in FIG. 11F.

According to the second switch operation, the reference capacitor 13 is electrically charged by the electric charge stored at the sensor electrode E1 until that moment, and at the same time, the electric potential Vin− decreases. In addition, the electric potential VE1 of the sensor electrode E1 decreases through the second switch operation (see FIG. 11D). However, the electric potential VE1 of the sensor electrode E1 turns to the power-supply voltage V1 again through the third switch operation.

In response to the number of times the second and third switch operations are repeated, the electric potential Vin− of the input terminal (−) of the comparator 12 decreases. When the electric potential Vin− of the input terminal of the comparator 12 becomes equal to or smaller than the voltage V4, the output signal Vout of the comparator 12 changes to the high level from the low level. The control unit 17 counts the number of times the second switch operation is repeated before the output signal Vout of the comparator 12 appears to change to the high level and then outputs a calculation result of a function of that number of times counted.

As mentioned above, the capacitance detecting apparatus 60 according to the fifth embodiment includes the Op-Amp 11, the comparator 12, the reference capacitor 13, the on/off switches 14 to 16, and the sensor electrode E1. Since the on/off switches 14 to 16 are turned on and off in the same way as the first embodiment, the output of the capacitance detecting apparatus 60 can be highly accurately converted to distance information in the cases where the capacitance detecting apparatus 60 is used as a distance sensor. Electrode surfaces of the sensor electrode E1 other than the surface facing the ground electrode E0 and the wiring that connects the sensor electrode E1 and the on/off switches 15 and 16 produce a parasitic capacitor Cα1 not shown. The parasitic capacitor C1 is electrically charged (i.e., electric charge is stored) when the on/off switch 16 is in the closed state and then electrically discharged (i.e., electric charge is transferred to the reference capacitor 13) when the electric charge stored at the capacitor of which the electrode at one end is formed by the sensor electrode E1 is transferred to the reference capacitor 13. Thus, unnecessary electric charge due to presence of the parasitic capacitor is stored at the reference capacitor 13 to thereby decrease the detection accuracy of the capacitance detecting apparatus 60 and to cause the capacitance detecting apparatus 60 to be very susceptible to an effect of electromagnetic disturbances.

Therefore, the control unit 17 controls the on/off switches 63 and 64 in such a manner that the on/off switch 63 is shifted from the open state to the closed state after the on/off switch 15 is shifted from the closed state to the open state and before the on/off switch 16 is shifted from the closed state to the open state, that the on/off switch 63 is shifted from the closed state to the open state before the on/off switch 15 is shifted from the open state to the closed state, that the on/off switch 64 is shifted from the open state to the closed state at the same time as the on/off switch 15, and that the on/off switches 63 and 64 are prevented from being shifted to the closed state at the same time. According to the control of the on/off switches 63 and 64 as mentioned above, an electric potential Vs1 of the shield member Es1 (see FIG. 11G) is specified to be equal to the voltage V3 for at least a time period from immediately before the on/off switch 15 is shifted from the open state to the closed state to immediately after the on/off switch 15 is shifted from the closed state to the open state.

Accordingly, the electric charge is prevented from being stored at a portion where capacitors are formed between the shield member Es1 and both of the sensor electrode E1 and the wiring connecting the sensor electrode E1 and the on/off switches 15 and 16 for at least a time period from immediately before the on/off switch 15 is shifted from the open state to the closed state to immediately after the on/off switch 15 is shifted from the closed state to the open state. The transfer of the electric charge to the reference capacitor 13 from the unnecessary capacitor (i.e., parasitic capacitor) is prevented to thereby avoid decrease in accuracy of the capacitance detection caused by an effect of the parasitic capacitance Cα1.

As mentioned above, the capacitance detecting apparatus 60 according to the present embodiment prevents the effect of the parasitic capacitor Cα1 parasitic on the sensor electrode E1 and the wiring connecting the sensor electrode E1 and the on/off switches 15 and 16, and also produces the following additional advantages.

As illustrated in FIG. 11G, since the electric potential Vs1 of the shield member Es1 is substantially equal to the electric potential VE1 of the sensor electrode E1 for a time period from immediately before the on/off switch 1S is shifted from the open state to the closed state to immediately after the on/off switch 15 is shifted from the closed state to the open state, a possible leakage current between the sensor electrode E1 and the shield member Es1 can be prevented even if insulation failure occurs between the sensor electrode E1 and the shield member Es1. Thus, a further accurate detection result can be obtained by the capacitance detecting apparatus 60. In the cases where the output terminal of the Op-Amp 61, the inverting input terminal (−) of the Op-Amp 61, and the shield member Es1 are electrically connected to each other while the non-inverting input terminal (+) of the Op-Amp 11 is connected to the sensor electrode E1 as in a third example of the fifth embodiment illustrated in FIG. 9C, an advantage substantially same as that according to the aforementioned first and second examples illustrated in FIGS. 9A and 9B can be obtained without providing the on/off switches 63 and 64.

### Sixth Embodiment

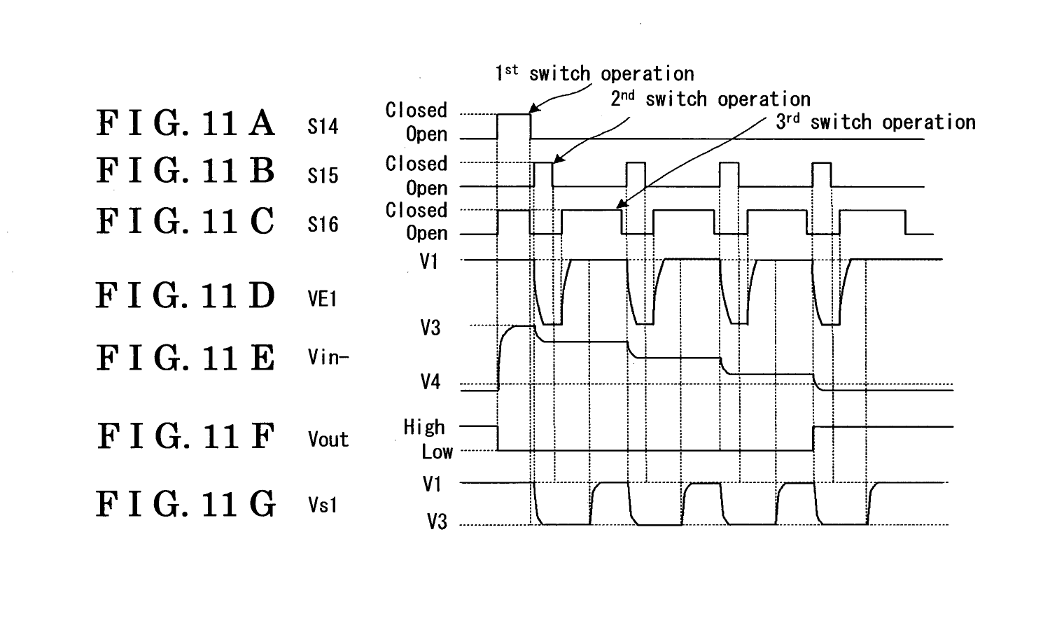

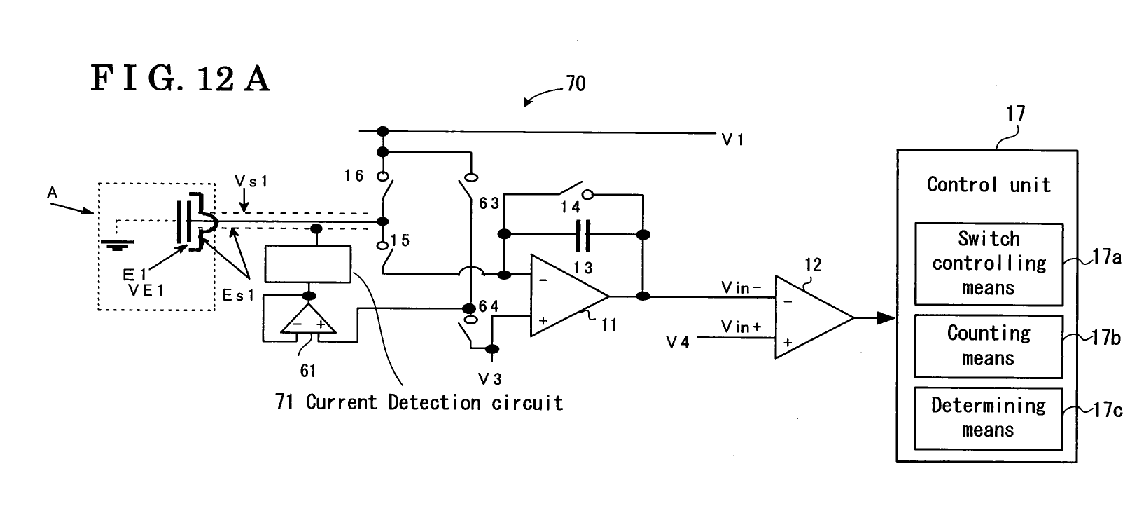

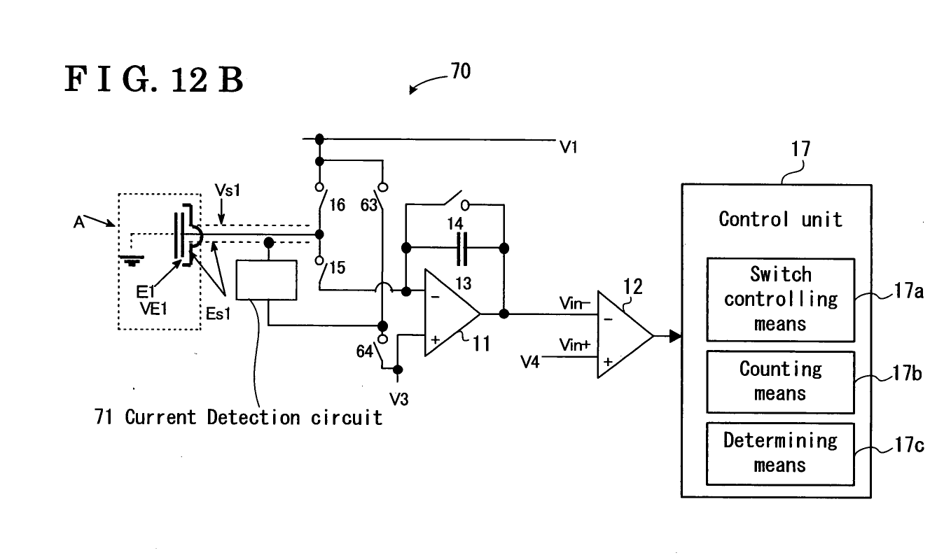

FIG. 12A is a schematic circuit diagram illustrating a capacitance detecting apparatus 70 according to one example of a sixth embodiment. Parts or elements in FIG. 12A substantially same as those in FIG. 9B bear the same numbers. The capacitance detecting apparatus 70 includes a current detection circuit 71 (first current detection circuit) between the shield member Es1 and the output terminal of the Op-Amp 61. The other structure of the capacitance detecting apparatus 70 is same as that of the capacitance detecting apparatus 60 according to the fifth embodiment illustrated in FIG. 9B.

FIGS. 13A to 13G are timing charts for explaining an operation of the capacitance detecting apparatus 70 and are corresponding to FIG. 11A to FIG. 11G. A basic operation of the capacitance detecting apparatus 70 is same as that of the capacitance detecting apparatus 60. As illustrated in FIGS. 13A to 13C, a first switch operation is performed and then second and third switch operations are repeatedly performed.

As illustrated in FIGS. 13A to 13G, according to a control of the control unit 17 (i.e., first electric potential applying means), a time T1 is defined after the on/off switch 16 is shifted from the open state to the closed state through the third switch operation and before the on/off switch 63 is shifted from the closed state to the open state and the on/off switch 64 is shifted to the closed state. When the insulation condition between the sensor electrode E1 and the shield member Es1 is excellent, the electric potential VE1 of the sensor electrode E1 is prevented from being equal to the electric potential Vs1 of the shield member Es1 during the time T1.

Thus, the current detection circuit 71 is added so as to detect a current flowing to the shield member Es1 from the Op-Amp 61 during the time T1. The detection of the current flowing to the shield member Es1 achieves a detection of possible insulation failure between the sensor electrode E1 and the shield member Es1.

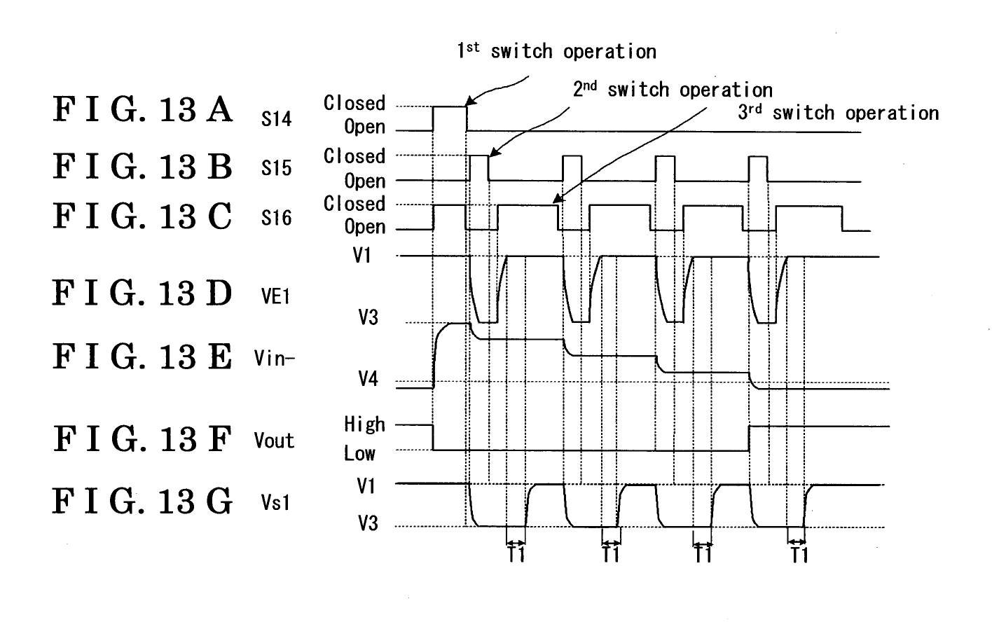

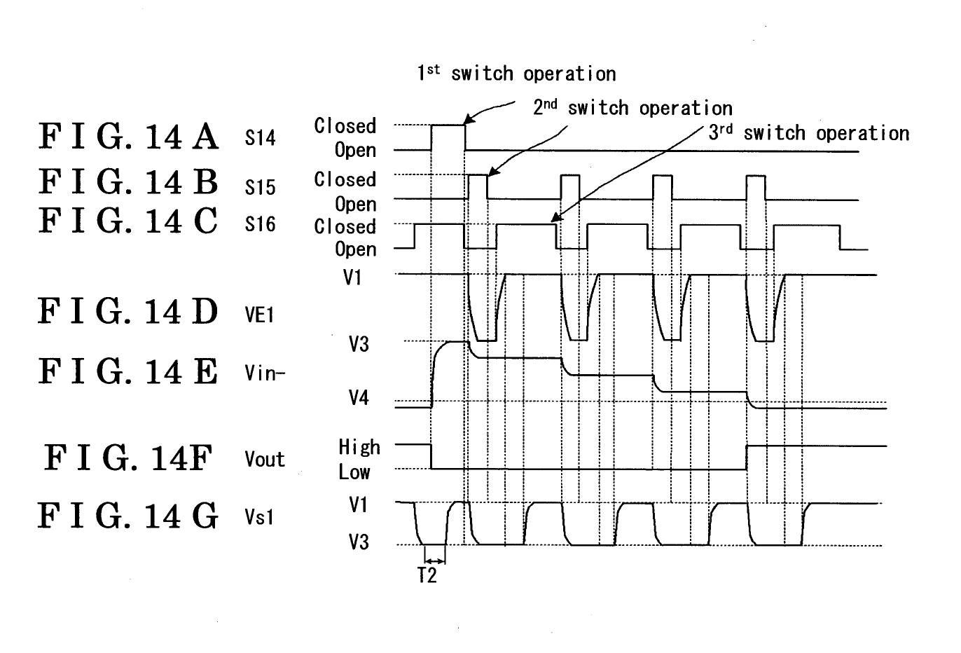

As mentioned above, the capacitance detecting apparatus 70 according to the sixth embodiment can immediately detect the possible insulation failure between the sensor electrode E1 and the shield member Es1 so that a response to the insulation failure can be made without delay. Timing for detecting the insulation failure between the shield member Es1 and both the sensor electrode E1 and a wiring connected thereto is not necessarily within the time T1, i.e., it may be out of the time T1. That is, the insulation failure between the shield member Es1 and both the sensor electrode E1 and the wiring, connected thereto may be detected during a time T2 as illustrated in FIGS. 14A to 14G.

FIGS. 14A to 14G are timing charts for detecting the insulation failure at a different timing. First, a predetermined time period is defined that is started after the output signal Vout of the comparator 22 is shifted from a low level to a high level and is finished before the on/off switch 15 is shifted from the open state to the closed state that occurs immediately after the on/off switch 14 is shifted from the closed state to the open state. During the aforementioned predetermined time period, the time T2 is defined during which the on/off switch 15 is in the open state and the on/off switches 16 and 64 are each in the closed state. Then, a time T2 is defined during the aforementioned predetermined time. The current flowing to the shield member Es1 is measured and detected by the current detection circuit 71 during at least a portion of the time T2 to thereby detect the possible insulation failure between the sensor electrode E1 and the shield member Es1. As illustrated in FIGS. 14A to 14G, the on/off switch 16 is shifted from the open state to the closed state with the on/off switch 15 in the open state (see FIGS. 14B and 14C) before the on/off switch 14 is shifted from the open state to the closed state through the first switch operation (see FIG. 14A). Then, the electric potential VE1 of the sensor electrode E1 and an electric potential of the wiring connected thereto are fixed at the power-supply voltage V1. At this time, while the on/off switch 16 is in the closed state, the on/off switch 64 is shifted from the open state to the closed state so that the electric potential Vs1 of the shield member Es1 is specified to be the fixed voltage V3 (see FIG. 14G). In such circumstances, the current flowing between the Op-Amp 61 and the shield member Es1 is measured by the current detection circuit 71 during the time T2. The electric potential VE1 of the sensor electrode E1 and an electric potential of the wiring connected thereto are both specified to be the voltage V1 while the electric potential Vs1 of the shield member Es1 is specified to be the voltage V3 during the time T2. That is, VE1≠Vs1 and thus the flowing current is not detected by the current detection circuit 71 as long as the insulation between the shield member Es1 and both the sensor electrode E1 and the wiring connected thereto is excellent. However, in the cases where the insulation failure occurs between the shield member Es1 and both the sensor electrode E1 and the wiring connected thereto, the flowing current can be detected by the current detection circuit 71. As illustrated in FIG. 14A, the on/off switch 14 is shifted from the open state to the closed state while the on/off switch 16 is in the closed state. Alternatively, the on/off switch 14 may be shifted from the open state to the closed state regardless of “on” and “off” states of the on/off switches 16 and 64. After the lapse of the time T2 and before the start of the second switch operation, the on/off switch 64 is shifted from the closed state to the open state, the on/off switch 63 is shifted from the open state to the closed state, and the on/off switches 14 and 16 are each shifted from the closed state to the open state. According to another example of the capacitance detecting apparatus 70 as illustrated in FIG. 12B, the Op-Amp 61 is eliminated from the first example illustrated in FIG. 12A. In addition, a wiring connected to one end of the on/off switch 63, one end of the on/off switch 64, and the non-inverting input terminal of the Op-Amp 61 in FIG. 12A is replaced by a wiring connected to one end of the on/off switch 63, one end of the on/off switch 64, and the first shield member Es1 in FIG. 12B. The open and close operations of each of the on/off switches in FIG. 12B are same as those in FIG. 12A so that the same advantage can be obtained.

The capacitance detecting apparatus 70 according to the sixth embodiment, which additionally includes the current detection circuit 71 to the capacitance detecting apparatus 60 according to the fifth embodiment, can obtain substantially the same advantage as that of the capacitance detecting apparatus 60. Further, the capacitance detecting apparatus 70 can promptly detect the insulation failure between the sensor electrode E1 and the shield member Es1.

### Seventh Embodiment

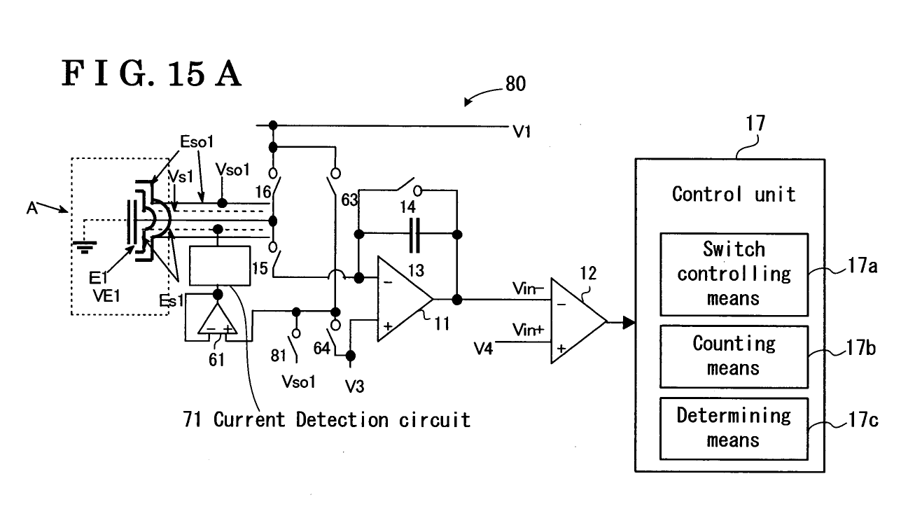

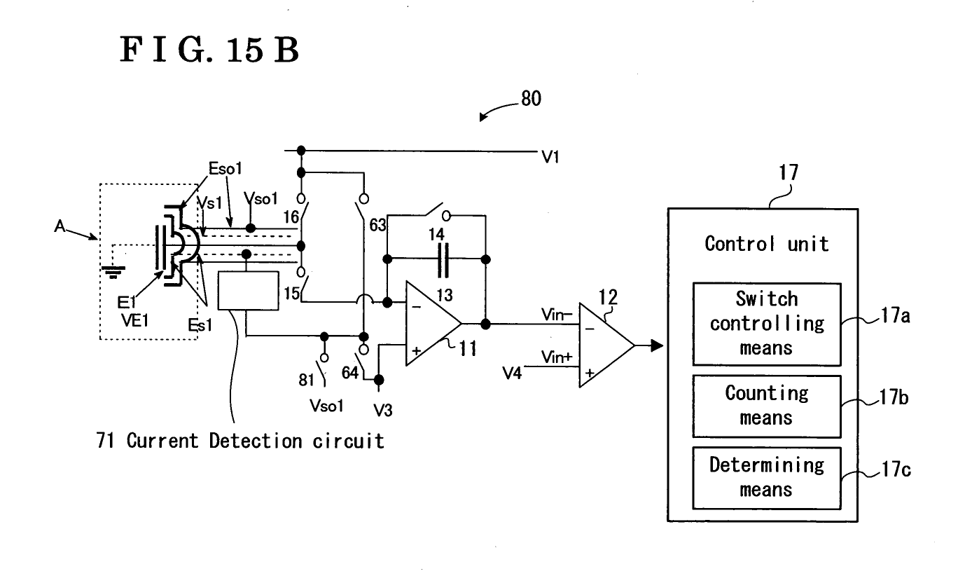

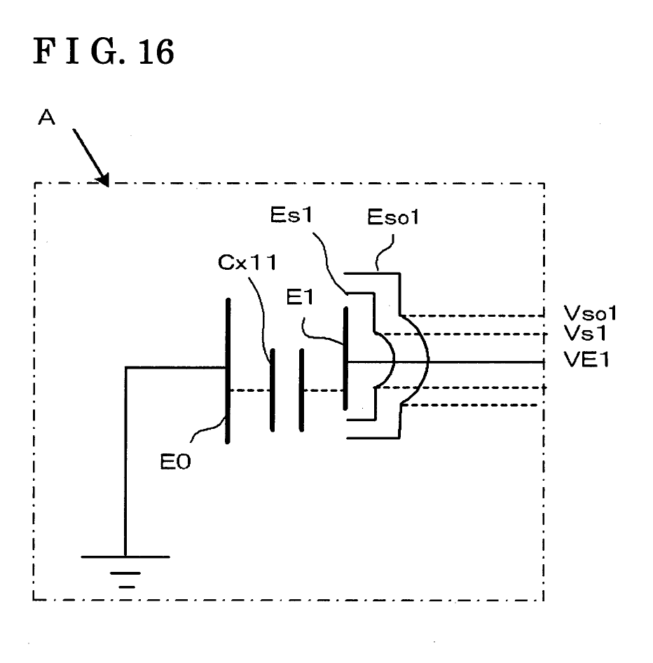

FIG. 15A is a schematic circuit diagram illustrating a capacitance detecting apparatus 80 according to one example of a seventh embodiment. FIG. 16 is an explanatory view of a portion depicted from A in FIG. 15A.

The capacitance detecting apparatus 80 additionally includes a first external shield member Eso1 and an on/off switch 81 to the capacitance detecting apparatus 70 according to the sixth embodiment. The external shield member Eso1 surrounds at least a portion of the sensor electrode E1, a wiring that connects the sensor electrode E1 and the second and third on/off switches 15 and 16, and the first shield member Es1. In addition, the external shield member Eso1 is connected to a third fixed voltage Vso1. A first end of the on/off switch 81 is connected to the fixed voltage Vso1. A second end of the on/off switch 81 is connected to the non-inverting input terminal of the Op-Amp 61, to a second end of the on/off switch 63 of which a first end is connected to the first power-supply voltage V1, and to a second end of the on/off switch 64 of which a first end is connected to the first fixed voltage V3. The control unit 17 controls timings of “on” and “off” operations of each of the on/off switches 14, 15, 16, 63, 64, and 81 in such a way that the on/off switches 15 and 16 are prevented from being shifted to the closed states at the same time and that two or more of the on/off switches 63, 64, and 81 are prevented from being shifted to the closed states at the same time. The other structure of the capacitance detecting apparatus 80 is same as that of the capacitance detecting apparatus 70 according to the sixth embodiment.

In the case where a portion of electrode surfaces of the sensor electrode E1 except for a surface facing the variable capacitor Cx11, and the wiring that connects the sensor electrode E1 and the second and third on/off switches 15 and 16 is not surrounded by the shield member Es1, a parasitic capacitor may be formed between the external shield member Eso1 or an adjacent wiring and an electric member such as an electrode, which may cause increase of measurement errors in the variable capacitance Cx11. Therefore, the electrode surfaces of the sensor electrode E1 not facing the ground electrode E0 and the wiring that connects the sensor electrode E1 and the on/off switches 15 and 16 should be desirably surrounded by the shield member Es1. Further, the electric potential Vs1 of the shield member Es1 fluctuates in association with the electric potential VE1 of the sensor electrode E1 to thereby highly possibly generate electromagnetic noises. Accordingly, the external shield member Eso1 connected to the third fixed voltage Vso1 should desirably surround the shield member Es1.

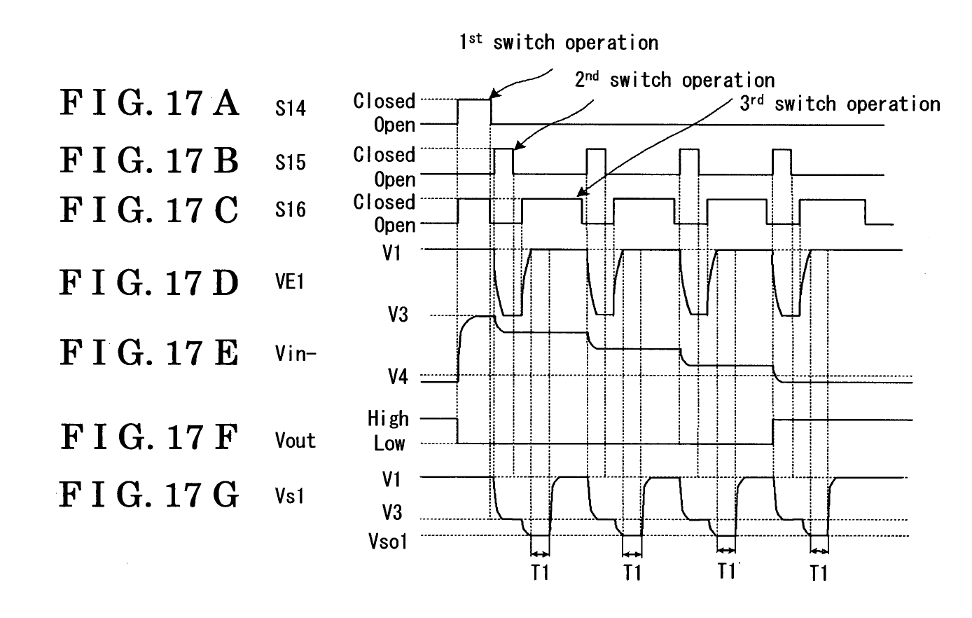

FIGS. 17A to 17G are timing charts for explaining an operation of the capacitance detecting apparatus 80. Basically, the capacitance detecting apparatus 80, precisely, the control unit 17, performs a first switch operation in which the on/off switches 14, 16 and 63 are each shifted to the closed state from a state where the on/off switches 14, 15, 64, and 81 are each in the closed state, and are afterwards shifted to the open state so that at least the on/off switches 16 and 63 are shifted in a synchronization manner. The control unit 17 then repeatedly and alternately performs a second switch operation in which the on/off switches 15 and 64 are each retained in the closed state in the synchronization manner for a predetermined time and then are each returned to the open state, and a third switch operation in which the on/off switch 16 is retained in the closed state for a predetermined time after the second switch operation is performed and then at least the on/off switches 16 and 63 are shifted from the closed state to the open state both in the synchronization manner. In the third switch operation, a time period is defined during which the on/off switches 63 and 64 are each retained in the open state and the on/off switch 81 is retained in the closed state while the on/off switch 16 is in the closed state. According to the timing charts illustrated in FIGS. 17A to 17G, the on/off switch 16 is in the open state and the on/off switch 63 is in the closed state before the first switch operation is performed. Then, through the first switch operation, the on/off switches 16 and 14 are synchronously shifted from the open state to the closed state and afterwards the on/off switches 14, 16, and 63 are synchronously shifted from the closed state to the open state. Through the second switch operation, the on/off switches 15 and 64 are synchronously retained in the closed state for a predetermined time period and then are each returned to the open state. Through the third switch operation, the on/off switches 16 and 81 are synchronously shifted from the open state to the closed state and afterwards the on/off switch 81 only is shifted to the open state in addition to the shifting of the on/off switch 63 from the open state to the closed state and the synchronous shifting of the on/off switches 16 and 63 from the closed state to the open state.

Immediately before the second switch operation, the on/off switches 16 and 63 are synchronously shifted from the closed state to the open state. Then, since the on/off switches 15 and 64 are synchronously opened and closed through the second switch operation, the electric potentials VE1 and Vs1 of the sensor electrode E1 and the shield member Es1, respectively, are substantially equal to each other from immediately before the on/off switches 16 and 63 are synchronously shifted from the closed state to the open state to a point where the on/off switches 15 and 64 are synchronously shifted from the closed state to the open state. At this time, therefore, no electric charges are present resulting from the parasitic capacitor Cα11 formed between the shield member Es1 and both the sensor electrode E1 and the wiring connecting the sensor electrode E1 and the on/off switches 15 and 16. Further, even when the insulation failure occurs between the shield member Es1 and both the sensor electrode E1 and the wiring connecting the sensor electrode E1 and the on/off switches 15 and 16, no electric charges are present that are transferred from the shield member Es1 via the insulation failure portion to the sensor electrode E1 and the wiring connecting the sensor electrode E1 and the on/off switches 15 and 16. Accordingly, the accuracy of capacitance detection may increase. The electric potential Vs1 of the shield member Es1 periodically changes through the second and third switch operations. However, since the external shield member Eso1 is fixed at the voltage Vso1, a radiation of the noise to the outside may be prevented.

According to the control of the control unit 17, a predetermined time period, started after the on/off switch 16 is shifted from the closed state to the open state and is finished before the on/off switch 16 is returned to the open state, is defined. Then, a time T1 is defined during the aforementioned predetermined time period during which the on/off switch 81 is retained in the closed state.

Since the electric potential VE1 of the sensor electrode E1 and the electric potential Vs1 of the shield member Es1 are prevented from being equal to each other during the time T1, the capacitance detecting apparatus 80 is able to detect a current flowing between the sensor electrode E1 and the shield member Es1 during the time T1 by means of the current detection circuit 71. In the cases where the insulation between the sensor electrode E1 and the shield member Es1 is excellent, no current flows between the sensor electrode E1 and the shield member Es1. On the other hand, in the case that the insulation failure occurs between the sensor electrode E1 and the shield member Es1, the current flows therebetween, so that the insulation failure can be detected by measuring the current flowing between the sensor electrode E1 and the shield member Es1.

Furthermore, the electric potential Vs1 of the shield member Es1 is equal to the voltage Vso1 of the external shield member Eso1 during the time T1. Thus, even when the insulation failure occurs between the shield member Es1 and the external shield member Eso1, no current flows from the shield member Es1 to the external shield member Eso1 to thereby securely detect the insulation failure between the shield member Es1 and both the sensor electrode E1 and the wiring connecting the sensor electrode E1 and the on/off switches 15 and 16.

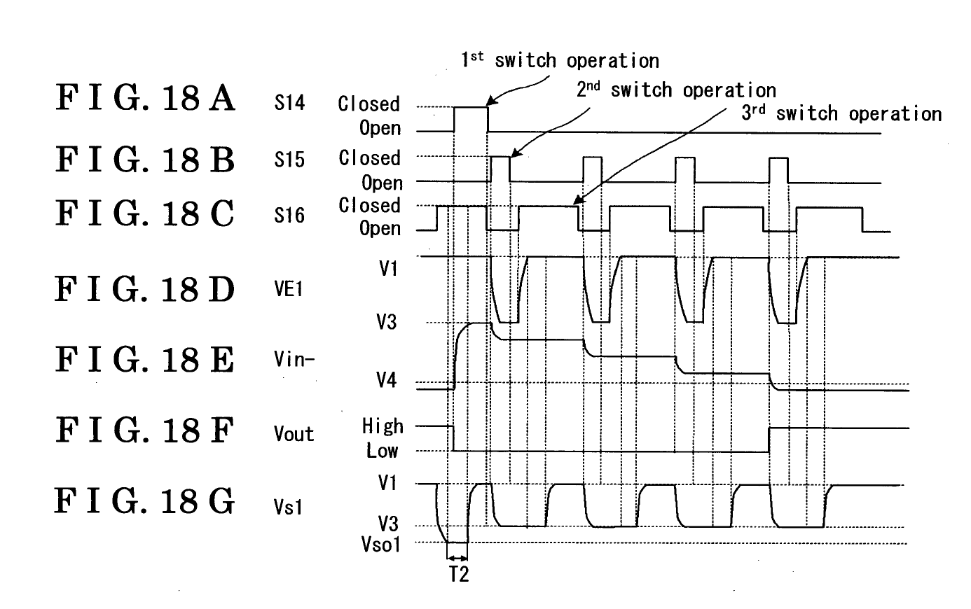

The insulation failure between the shield member Es1 and both the sensor electrode E1 and the wiring connecting the sensor electrode E1 and the on/off switches 15 and 16 is not necessarily detected at the time T1. For example, the insulation failure may be detected during a time T2 as illustrated in FIG. 18A to 18G.

FIGS. 18A to 18G are timing charts for detecting the insulation failure at a different timing. A predetermined time period is defined that is started after the output signal Vout of the comparator 22 is shifted from a low level to a high level and is finished before the on/off switch 15 is shifted from the open state to the closed state that occurs immediately after the on/off switch 14 is shifted from the closed state to the open state. During the aforementioned predetermined time period, the time T2 is defined during which the on/off switch 15 is in the open state and the on/off switches 16 and 81 are each in the closed state. Then, the current flowing to the shield member Es1 is measured by means of the current detection circuit 71 at least during a portion of the time T2 to thereby detect the insulation failure between the sensor electrode E1 and the shield member Es1. In FIGS. 18A to 18G, the on/off switch 63 is shifted from the closed state to the open state before the on/off switch 14 is shifted from the open state to the closed state through the first switch operation (see FIG. 18A) with the on/off switch 15 in the open state. The on/off switches 16 and 81 are then each shifted from the open state to the closed state so that the electric potential VE1 of the sensor electrode E1 and an electric potential of the wiring connected thereto are fixed at the power-supply voltage V1 while the electric potential Vs1 of the shield member Es1 is fixed at the voltage Vso1 to thereby differentiate the electric potentials. The time T2 is defined in the predetermined time period during which the aforementioned on/off switches 15, 63, and 64 are each retained in the open state, and the on/off switches 16 and 81 are each retained in the closed state so that the current flowing to the shield member Es1 is measured at least during the time T2 by means of the current detection circuit 71. When the on/off switch 14 is shifted from the open state to the closed state and then the time T2 is elapsed, the on/off switch 81 is shifted from the closed state to the open state followed by the shifting of the on/off switch 63 from the open state to the closed state. Afterwards, the on/off switches 14, 16, and 63 are synchronously shifted from the closed state and returned to the open state. That is, the control unit 17 finishes the first switch operation and prepares for the second switch operation. According to another example of the seventh embodiment as illustrated in FIG. 15B, the Op-Amp 61 is eliminated from the first example illustrated in FIG. 15A. In addition, a wiring connected to one end of the on/off switch 63, one end of the on/off switch 64, and the non-inverting input terminal of the Op-Amp 61 in FIG. 15A is replaced by a wiring connected to one end of the on/off switch 63, one end of the on/off switch 64, and the first shield member Es1 in FIG. 15B. The open and close operations of each on/off switch in FIG. 15B are same as those in FIG. 15B so that the same advantage can be obtained.

The aforementioned capacitance detecting apparatus 80 detects the current flowing from the sensor electrode E1 to the shield member Es1 by means of the current detection circuit 71 to thereby detect the possible insulation failure occurring between the sensor electrode E1 and the shield member Es1.

### Eighth Embodiment

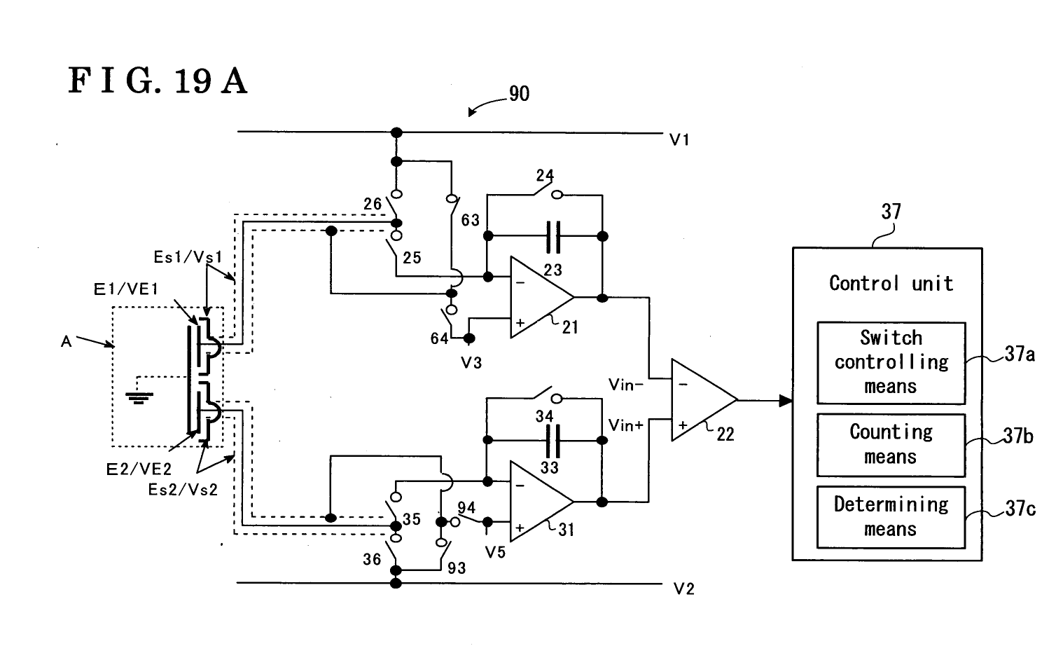

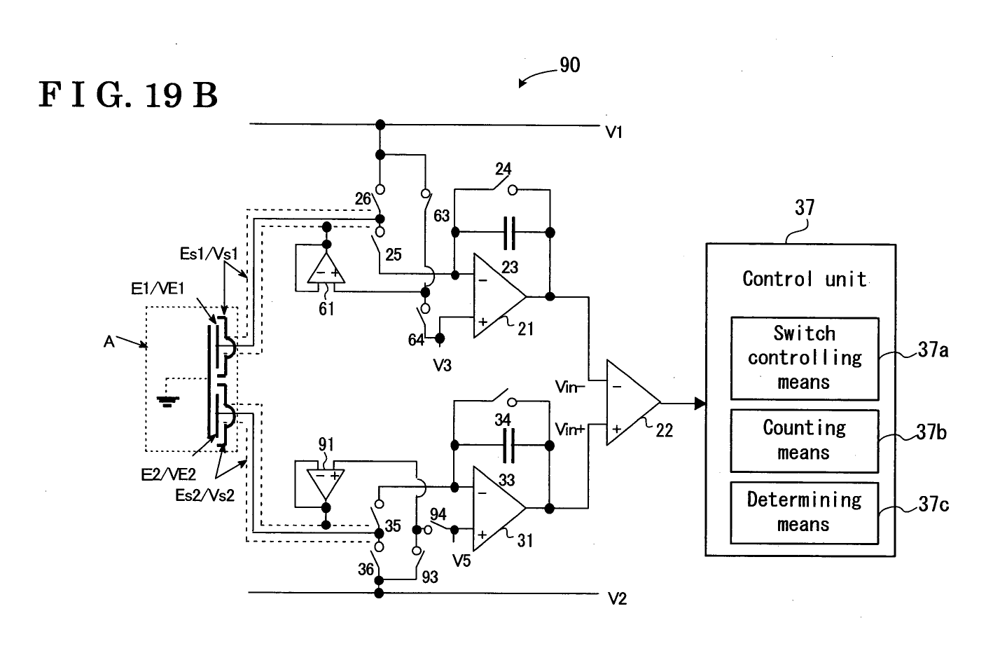

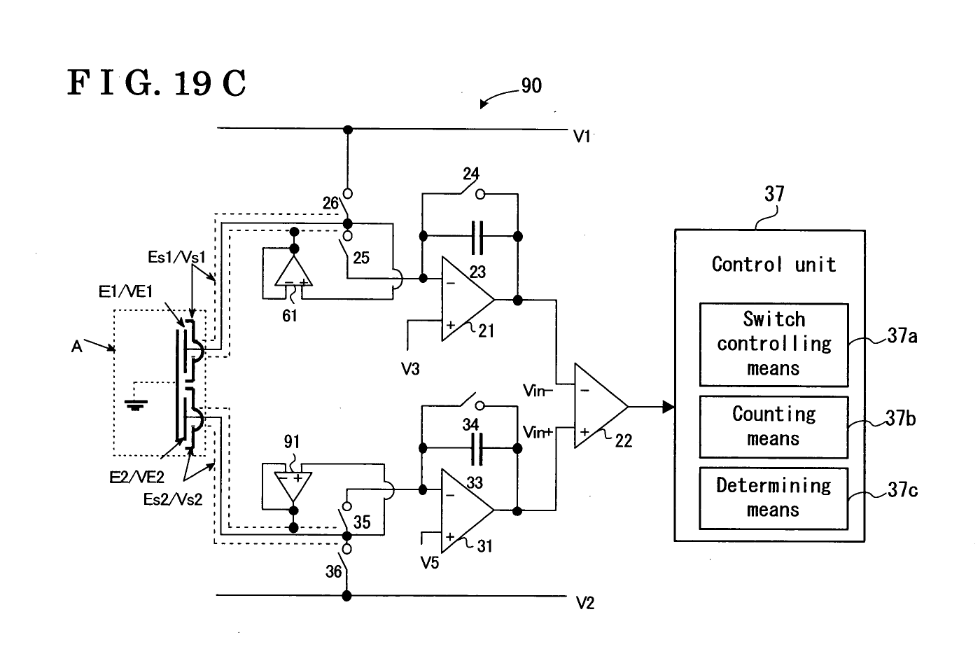

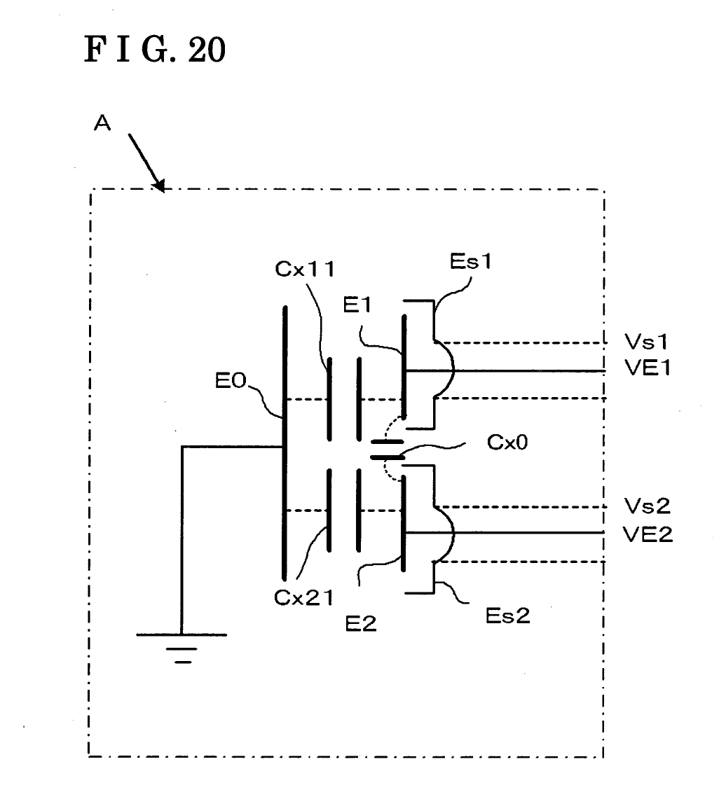

FIG. 19B is a schematic circuit diagram illustrating a capacitance detecting apparatus 90 according to one example of an eighth embodiment. Parts or elements in FIG. 19B substantially same as those in FIG. 4 illustrating the capacitance detecting apparatus 20 according to the second embodiment bear the same numbers. FIG. 20 is an explanatory view of a portion depicted from A in FIG. 19B. The capacitance detecting apparatus 90 includes the first and second Op-Amps 21 and 31, the comparator 22, the first and second reference capacitors 23 and 33; the first to sixth on/off switches 24, 25, 26, 34, 35, and 36, and the first and second sensor electrodes E1 and E2, and the control unit 37 all of which are connected in the same manner as the second embodiment illustrated in FIG. 4.

As illustrated in FIG. 20, a reference sign Cx11 hereinbelow depicts a first variable capacitance or a first variable capacitor. The first variable capacitor Cx11 includes a ground electrode E0 having substantially a constant electric potential, and the first sensor electrode E1 arranged to face the ground electrode E0. Hence, the sensor electrode E1 serves as an electrode at one end of the first variable capacitor Cx11, and the ground electrode E0 is a grounded medium (measured object), such as a hand of an operator or head of an occupant. The first variable capacitance Cx11 varies in response to a distance between the sensor electrode E1 and the ground electrode E0. In the same way as the reference sine Cx11, a reference sign Cx21 hereinbelow depicts a second variable capacitance or a second variable capacitor. The second variable capacitor Cx21 includes the ground electrode E0 and the second sensor electrode E2 arranged to face the ground electrode E0. Hence, the second sensor electrode E2 serves as an electrode at one side of the second variable capacitor Cx21, and the ground electrode E0 is a grounded medium (measured object), such as a hand of an operator or head of an occupant. The second variable capacitance Cx21 varies in response to a distance between the second sensor electrode E2 and the ground electrode E0. Since the first and second sensor electrodes E1 and E2 are arranged adjacent to each other, a parasitic capacitance or a capacitor Cx0 is formed between the first sensor electrode E1 and the second sensor electrode E2.

The capacitance detecting apparatus 90 includes a first shield member Es1 and a second shield member Es2, which are not provided in the second embodiment. The shield member Es1 surrounds electrode surfaces of the sensor electrode E1 except for a surface facing the ground electrode E0 while keeping a predetermined gap with the shielding surfaces. The shield member Es1 also surrounds a wiring connecting the sensor electrode E1 and the on/off switches 25 and 26 while keeping a predetermined gap therebetween.

The shield member Es2 surrounds electrode surfaces of the sensor electrode E2 except for a surface facing the ground electrode E0 while keeping a predetermined gap with the shielding surfaces. The shield member Es2 also surrounds a wiring connecting the sensor electrode E2 and the on/off switches 35 and 36 while keeping a predetermined gap therebetween.

As illustrated in FIG. 19B, the output terminal of the Op-Amp 61 is connected to the shield member Es1. The non-inverting input terminal (+) of the Op-Amp 61 is connected to a first end of the on/off switch 63 of which a second end is connected to the first power-supply voltage V1 and also to a first end of the on/off switch 64 of which a second end is connected to the first fixed voltage V3. The inverting input terminal (−) of the Op-Amp 61 is connected to the output terminal thereof.

An output terminal of an operational amplifier (i.e., Op-Amp) 91 is connected to the shield member Es2. A non-inverting input terminal (+) of the Op-Amp 91 is connected to a first end of an on/off switch 93 of which a second end is connected to the second power-supply voltage V2 and to a first end of an on/off switch 94 of which a second end is connected to the second fixed voltage V5. An inverting input terminal (−) of the Op-Amp 91 is connected to the output terminal thereof.

The control unit 37 controls the switch operations of the on/off switches 63, 64, 93, and 94 in addition to the on/off switches 24 to 26, and 34 to 36. At this time, in respective combinations of the on/off switches 25 and 26, the on/off switches 35 and 36, the on/off switches 63 and 64, and the on/off switches 93 and 94, both the on/off switches in the identical combination are never shifted to the closed state at the same time. A relationship of magnitude of voltages (electric potentials) V1, V2, V3, and V5 may be defined to be either V1>V3>V5>V2 or V1<V3<V5<V2.

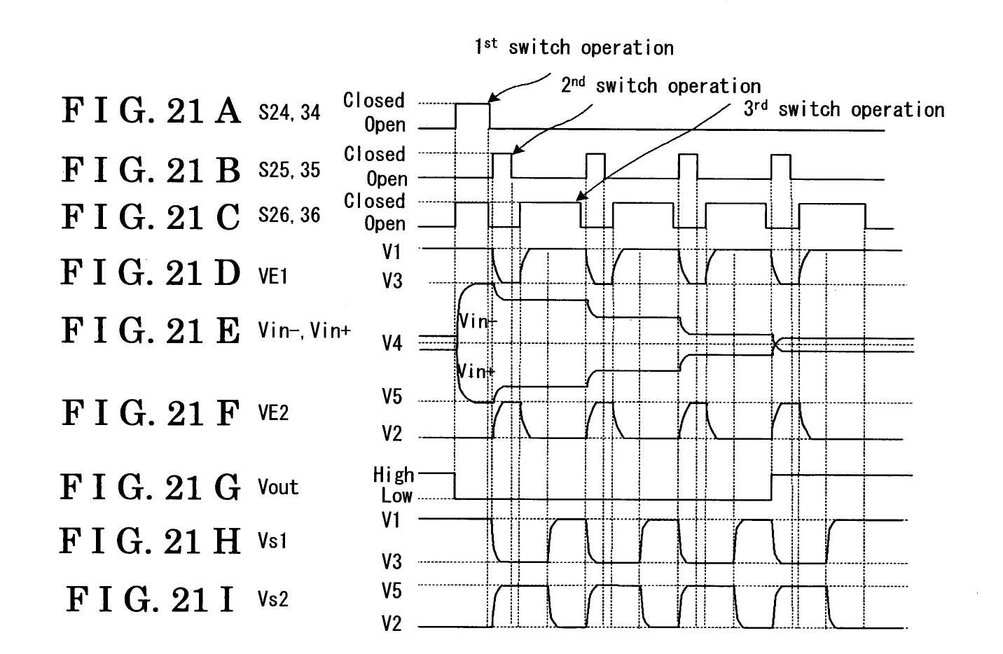

A basic operation of the capacitance detecting apparatus 90 is substantially same as that of the capacitance detecting apparatus 20 according to the second embodiment. FIGS. 21A to 21I are timing charts for explaining an operation of the capacitance detecting apparatus 90 depicted in FIGS. 19A, 19B and 19C. In FIGS. 21A to 21I, a relationship of magnitude of voltages (electric potentials) V1, V2, V3, and V5 is defined to be V1>V3>V5>V2.

According to the capacitance detecting apparatus 90, as in the same way as the second embodiment, the control unit 37 performs a first switch operation in which the on/off switches 24 and 34 are each brought to a closed state for a predetermined time from an open state and then are each returned to the open state (see FIG. 21A). Afterwards, the control unit 37 repeatedly and alternately performs a second switch operation in which the on/off switches 25 and 35 are each brought to a closed state for a predetermined time from an open state and then are each returned to the open state (see FIG. 21B), and a third switch operation in which the on/off switches 26 and 36 are each brought to a closed state for a predetermined time from an open state and then are each returned to the open state (see FIG. 21C). At this time, the on/off switches 26 and 36 may be each shifted from the open state to the closed state to be retained therein for a predetermined time after the first switch operation is performed as illustrated in FIG. 21C. In the aforementioned switch operations, the on/off switches 63 and 93 are each shifted from the open state to the closed state while the on/off switches 26 and 36 are each in the closed state, and then are each shifted from the closed state to the open state after the on/off switches 26 and 36 are each shifted from the closed state to the open state and also before the second switch operation is performed. Through the second switch operation, the on/off switches 25, 35, 64, and 94 are shifted from the open state to the closed state at the same time. Then, after the on/off switches 25 and 35 are shifted from the closed state to the open state followed by the shifting of the on/off switches 26 and 36 from the open state to the closed state, the on/off switches 64 and 94 are shifted from the closed state to the open state.

According to the first switch operation, both electrodes of the reference capacitor 23 and both electrodes of the reference capacitor 33 are short-circuited, respectively. Then, the electric potential Vin− of the input terminal (−) of the comparator 22 increases to V3 while the electric potential Vin+ of the input terminal (+) of the comparator 22 decreases to V5 as illustrated in FIG. 21E. As a result, the output signal Vout of the comparator 22 changes from a high level to a low level as illustrated in FIG. 21G.

According to the second switch operation, the electric charge (Cx11·(V1−V3)) in association with the fluctuation of the electric potential VE1 of the sensor electrode E1 is charged at the reference capacitor 23 and then the electric potential Vin− decreases. At the same time, the electric charge (Cx21·(V2−V5)) in association with the fluctuation of the electric potential VE2 of the sensor electrode E2 is charged at the reference capacitor 33 and then the electric potential Vin+ increases as illustrated in FIG. 21E.

The electric potential VE1 of the sensor electrode E1 decreases through the second switch operation and then becomes equal to the first fixed voltage V3. However, through the third switch operation, the electric potential VE1 of the sensor electrode E1 again increases to be equal to the power-supply voltage V1 as illustrated in FIG. 21D. The electric potential VE2 of the sensor electrode E2 increases through the second switch operation and then becomes equal to the second fixed voltage V5. However, through the third switch operation, the electric potential VE2 of the sensor electrode E2 again decreases to be equal to the power-supply voltage V2 as illustrated in FIG. 21F.

In response to the number of times the second and third switch operations are repeated, the electric potential Vin− of the input terminal (−) of the comparator 22 decreases while the electric potential Vin+ of the input terminal (+) of the comparator 22 increases.

When the electric potential Vin− of the input terminal (−) of the comparator 22 decreases to or below the electric potential Vin+ of the input terminal (+) of the comparator 22, the output signal Vout of the comparator 12 changes to the high level from the low level. The control unit 37 counts the number of times the second switch operation is repeated before the output signal Vout of the comparator 12 appears to change to the high level and then outputs a calculation result of a function of that number of times counted.

The change in the electric potential Vin− is in proportion to the number of times the second switch operation is repeated. A magnitude of change in the electric potential Vin− is substantially in proportion to the variable capacitance Cx11. In the same way, the change in the electric potential Vin+ is in proportion to the number of times the second switch operation is repeated. A magnitude of change in the electric potential Vin+ is substantially in proportion to the variable capacitance Cx21. Since the variable capacitances Cx11 and Cx21 are inversely proportional to the distance d between the sensor electrodes E1 and E2, and the ground electrode E0, respectively, the output signal Vout of the comparator 22 is a function of the distance d. Thus, in the cases where the capacitance detecting apparatus 90 is used as a distance sensor, the output of the capacitance detecting apparatus 90 can be easily converted to distance information.

In addition, a ratio of SE1 to Cs2, i.e., SE1/Cs2, wherein SE1 is an area of the sensor electrode E1 and Cs2 is a capacitance of the first reference capacitor 23, and a ratio of SE2 to Cs3, i.e., SE2/Cs3, wherein SE2 is an area of the sensor electrode E2 and Cs3 is a capacitance of the second reference capacitor 33 are equalized so that an effect of electromagnetic disturbances can be prevented. In addition, SE1·(V1−V3) and SE2·(V5−V2) are equalized so that the generation of radio noise can be prevented.

In this case, electrode surfaces of the sensor electrode E1 except for the surface facing the ground electrode E0 and the wiring that connects the sensor electrode E1 and the on/off switches 25 and 26 produce a parasitic capacitor Cal (not shown). On the assumption that the electric potential of the ground electrode E0 is constant, the electric charge corresponding to Cα1·(V1−V3) resulting from the parasitic capacitor Cα1 moves towards the reference capacitor 23 in response to the repetition of the second and third switch operations. In addition, on the assumption that the electric potential of the ground electrode E0 is constant, the electric charge corresponding to Cx0·(V1−V2−V3+V5) resulting from the parasitic capacitor Cx0 formed between the sensor electrodes E1 and E2 moves towards the reference capacitor 23 in response to the repetition of the second and third switch operations. Accordingly, unnecessary electric charge is accumulated at the reference capacitor 23.

In the same way, electrode surfaces of the sensor electrode E2 except for the surface facing the ground electrode E0 and the wiring that connects the sensor electrode E2 and the on/off switches 35 and 36 produce a parasitic capacitor Cα2 (not shown). The electric charge corresponding to Cα2·(V2−V5) resulting from the parasitic capacitor Cα2 moves towards the reference capacitor 33 in response to the repetition of the second and third switch operations. In addition, the electric charge corresponding to Cx0·(V2−V1−V5+V3) resulting from the parasitic capacitor Cx0 formed between the sensor electrodes E1 and E2 moves towards the reference capacitor 33 in response to the repetition of the second and third switch operations. Accordingly, unnecessary electric charge is accumulated at the reference capacitor 33. Thus, unnecessary electric charge due to presence of the parasitic capacitors Cα1, Cα2, and Cx0 results in decrease in detection accuracy of the capacitance detecting apparatus 90 and also results in the capacitance detecting apparatus 90 to easily receive an effect of electromagnetic disturbances.

Therefore, according to the capacitance detecting apparatus 90 of the eighth embodiment, the shield member Es1 surrounds electrode surfaces of the sensor electrode E1 except for the surface facing the ground electrode E0 while keeping a predetermined gap with the shielding surfaces. The shield member Es1 also surrounds the wiring connecting the sensor electrode E1 and the on/off switches 25 and 26 while keeping a predetermined gap therebetween. In addition, the shield member Es2 surrounds electrode surfaces of the sensor electrode E2 except for the surface facing the ground electrode E0 while keeping a predetermined gap with the shielding surfaces. The shield member Es2 also surrounds the wiring connecting the sensor electrode E2 and the on/off switches 35 and 36 while keeping a predetermined gap therebetween. Accordingly, as compared to the capacitance detecting apparatus 20 of the second embodiment, on the assumption that the equally structured sensor electrodes and the wiring connected thereto are used, areas of the sensor electrodes E1 and E2 facing the respective wirings connected thereto are less to thereby achieve a small value of the parasitic capacitance Cx0. Further, the parasitic capacitor Cα1 is formed since the shield member Es1 surrounds electrode surfaces of the sensor electrode E1 except for the surface facing the ground electrode E0 while keeping a predetermined gap with the shielding surfaces, and also surrounds the wiring connecting the sensor electrode E1 and the on/off switches 25 and 26 while keeping a predetermined gap therebetween. In the same way, the parasitic capacitor Cα2 is formed since the shield member Es2 surrounds electrode surfaces of the sensor electrode E2 except for the surface facing the ground electrode E0 while keeping a predetermined gap with the shielding surfaces, and also surrounds the wiring connecting the sensor electrode E2 and the on/off switches 35 and 36 while keeping a predetermined gap therebetween. In this case, as illustrated in FIGS. 21D, 21F, 21H, and 21I, at least during a period from before the on/off switches 26 and 36 are each shifted from the closed state to the open state to immediately after the on/off switches 25 and 35 are each shifted from the closed state to the open state, the electric potential VE1 of the first sensor electrode E1 and the electric potential Vs1 of the first shield member Es1 become equal to each other, and the electric potential VE2 of the second sensor electrode E2 and the electric potential Vs2 of the second shield member Es2 become equal to each other.

As mentioned above, the electric potential VE1 of the first sensor electrode E1 and the electric potential Vs1 of the first shield member Es1 are equalized at least during the period from before the on/off switch 26 is shifted from the closed state to the open state to immediately after the on/off switch 25 is shifted from the closed state to the open state. Thus, in a state where no electric charge is accumulated at a capacitor formed between the shield member Es1 and both the sensor electrode E1 and the wiring connected between the sensor electrode E1 and the on/off switches 25 and 26, the changing electric charge accumulated at the sensor electrode E1 that forms one electrode, together with the wiring connecting the sensor electrode E1 and the on/off switches 25 and 26, of capacitors (i.e., Cx11, Cα1, and Cx0) is accumulated at the reference capacitor 23 before and after the on/off switch 25 is shifted from the open state to the closed state. At this time, as mentioned above, the value of Cx0 is smaller than that in the capacitance detecting apparatus 20 according to the second embodiment. Since the shield member Es1 surrounds electrode surfaces of the sensor electrode E1 except for the surface facing the ground electrode E0 while keeping a predetermined gap with the shielding surfaces, and also surrounds the wiring connecting the sensor electrode E1 and the on/off switches 25 and 26 while keeping a predetermined gap therebetween, a main component of the parasitic capacitance Cα1 become equal to a capacitance produced between the shield member Es1 and both the sensor electrode E1 and the wiring connecting the sensor electrode E1 and the on/off switches 25 and 26. As a result, the movement of the electric charge to the reference capacitor 23 resulting from the parasitic capacitances Cα1 and Cx0 is reduced to thereby prevent decrease in the capacitance detection accuracy caused by the effect of the parasitic capacitance or capacitor.

In the same way, the electric potential VE2 of the second sensor electrode E2 and the electric potential Vs2 of the second shield member Es2 are equalized at least from before the on/off switch 36 is shifted from the closed state to the open state to immediately after the on/off switch 35 is shifted from the closed state to the open state. Thus, in a state where no electric charge is accumulated between the shield member Es2 and both the sensor electrode E2 and the wiring connected between the sensor electrode E2 and the on/off switches 35 and 36, the changing electric charge accumulated at the sensor electrode E2 that forms one electrode, together with the wiring connecting the sensor electrode E2 and the on/off switches 35 and 36, of capacitors (i.e., Cx21, Cα2, and Cx0) is accumulated at the reference capacitor 33 before and after the on/off switch 35 is shifted from the open state to the closed state. At this time, as mentioned above, the value of Cx0 is smaller than that in the capacitance detecting apparatus 20 according to the second embodiment. Since the shield member Es2 surrounds electrode surfaces of the sensor electrode E2 except for the surface facing the ground electrode E0 while keeping a predetermined gap with the shielding surfaces, and also surrounds the wiring connecting the sensor electrode E2 and the on/off switches 35 and 36 while keeping a predetermined gap therebetween, a main component of the parasitic capacitance Cα2 become equal to a capacitance generated between the shield member Es2 and both the sensor electrode E2 and the wiring connecting the sensor electrode E2 and the on/off switches 35 and 36. As a result, the movement of the electric charge to the reference capacitor 33 resulting from the parasitic capacitances Cα2 and Cx0 is reduced to thereby prevent decrease in the capacitance detection accuracy caused by the effect of the parasitic capacitance or capacitor.

The capacitance detecting apparatus 90 according to the eighth embodiment possesses an advantage shown below in addition to an advantage of reducing the effect of the parasitic capacitor parasitic on portions between the sensor electrodes E1 and E2, and respective wirings connected thereto.

Even in the case of insulation failure occurring between the sensor electrode E1 and the shield member Es1, the electric charge due to the current flowing between the sensor electrode E1 and the shield member Es1 is prevented from being accumulated at the reference capacitor 23 since the electric potential VE1 of the first sensor electrode E1 and the electric potential Vs1 of the first shield member Es1 are equalized at least from before the on/off switch 26 is shifted from the closed state to the open state to immediately after the on/off switch 25 is shifted from the closed state to the open state as illustrated in FIGS. 21D and 21H.

Further, even in the case of insulation failure occurring between the sensor electrode E2 and the shield member Es2, the electric charge due to the current flowing between the sensor electrode E2 and the shield member Es2 is prevented from being accumulated at the reference capacitor 33 since the electric potential VE2 of the second sensor electrode E2 and the electric potential Vs2 of the second shield member Es2 are equalized at least from before the on/off switch 36 is shifted from the closed state to the open state to immediately after the on/off switch 35 is shifted from the closed state to the open state as illustrated in FIGS. 21F and 21I. As a result, accuracy for detecting a capacitance formed between the sensor electrodes one of which is an object to be detected can be enhanced.

According to another example of the capacitance detecting apparatus 90 illustrated in FIG. 19A, the Op-Amps 61 and 91 are eliminated from the example illustrated in FIG. 19B. In FIG. 193, one end of the on/off switch 63, one end of the on/off switch 64, and the non-inverting input terminal of the Op-Amp 61 are connected to each other while, in FIG. 19A, one end of the on/off switch 63, one end of the on/off switch 64, and the first shield member Es1 are connected to each other. In the same way, in FIG. 19B, one end of the on/off switch 93, one end of the on/off switch 94, and the non-inverting input terminal of the Op-Amp 91 are connected to each other while, in FIG. 19A, one end of the on/off switch 93, one end of the on/off switch 94, and the second shield member Es2 are connected to each other. The open and close operations of each of the on/off switches in FIG. 19A become equal to those in FIG. 19B to thereby achieve the same advantage. Further, according to still another example of the capacitance detecting apparatus 90 illustrated in FIG. 19C, the on/off switches 63, 64, 93, and 94 are eliminated from the example illustrated in FIG. 19B. A wiring connected to the sensor electrode E1 in FIG. 19B is connected to the non-inverting input terminal of the Op-Amp 61 in FIG. 19C. A wiring connected to the sensor electrode E2 in FIG. 19B is connected to the non-inverting input terminal of the Op-Amp 91 in FIG. 19C. Then, by eliminating the control of the on/off switches 63, 64, 93, and 94, the same advantage as the example in FIG. 19B can be achieved.

### Ninth Embodiment

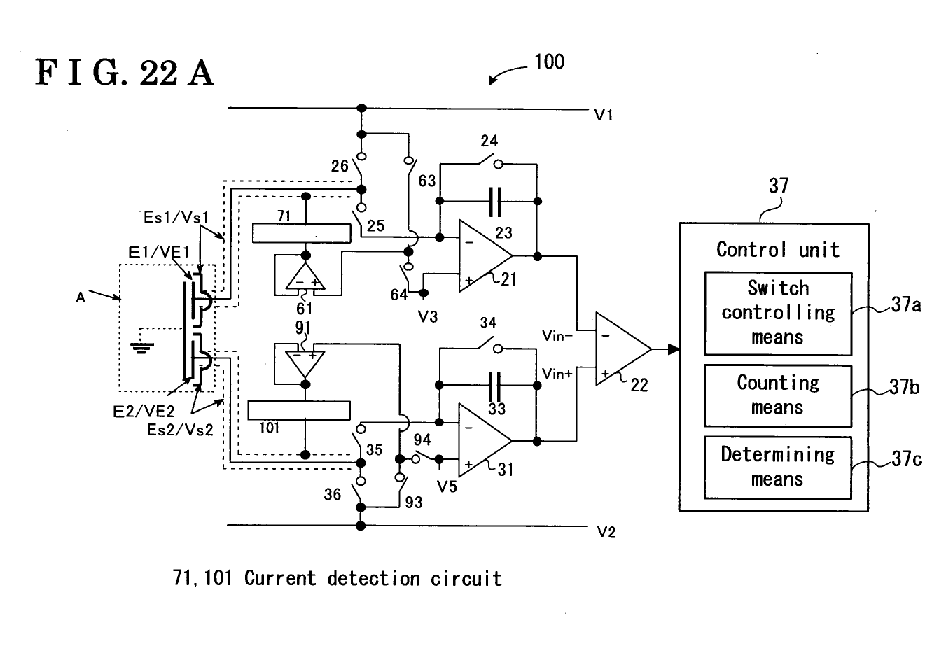

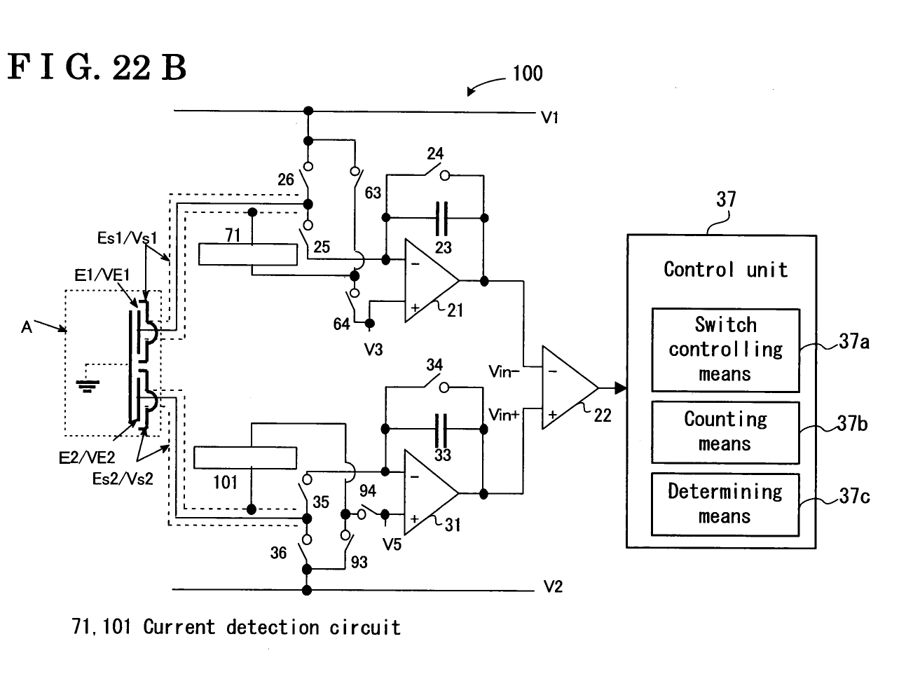

FIG. 22A is a schematic circuit diagram illustrating a capacitance detecting apparatus 100 according to one example of ninth embodiment. Parts or elements in FIG. 22A substantially same as those in FIG. 19B bear the same numbers. The capacitance detecting apparatus 100 additionally includes a first current detection circuit 71 between the shield member Es1 and the output terminal of the Op-Amp 61, and a second current detection circuit 101 between the shield member Es2 and the output terminal of the Op-Amp 91 in contrast to the capacitance detecting apparatus 90 of the eighth embodiment. The other structure of the capacitance detecting apparatus 100 is same as that of the capacitance detecting apparatus 90 according to the eighth embodiment.

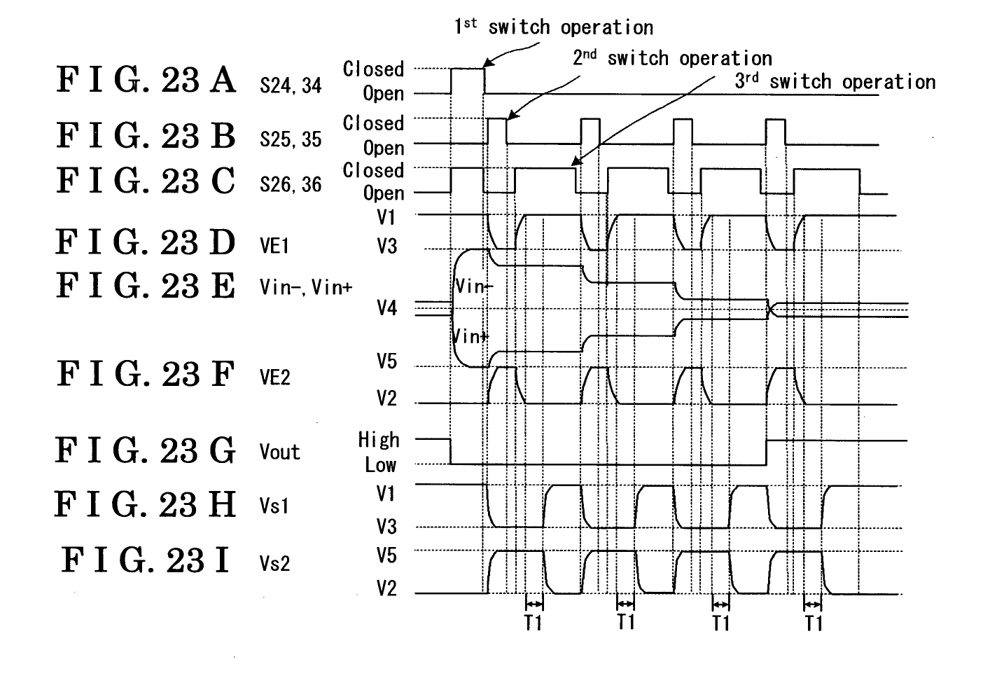

FIGS. 23A to 23I are timing charts for explaining an operation of the capacitance detecting apparatus 100 and are corresponding to FIGS. 21A to 21I. A basic operation of the capacitance detecting apparatus 100 is same as that of the capacitance detecting apparatus 90. That is, a first switch operation is performed and then second and third switch operations are repeatedly and alternately performed. At this time, in respective combinations of the on/off switches 25 and 26, the on/off switches 35 and 36, the on/off switches 63 and 64, and the on/off switches 93 and 94, both the on/off switches in the identical combination are never shifted to the closed state at the same time as in the same way as the capacitance detecting apparatus 90 according to the eighth embodiment.

According, to the control of the control unit 37 (i.e., first and second electric potential applying means), the on/off switches 63 and 93 are each shifted from the open state to the closed state before the on/off switches 26 and 36 are each shifted from the closed state to the open state, and then are each shifted from the closed state to the open state after the on/off switches 26 and 36 are each shifted from the closed state to the open state. Then, through the second switch operation, the on/off switches 25, 35, 64, and 94 are shifted from the open state to the closed state at the same time. After the on/off switches 25 and 35 are each shifted from the closed state to the open state, the on/off switches 64 and 94 are each shifted from the closed state to the open state. Afterwards, a time T1 is defined during which the on/off switches 26 and 36 are each in the closed state, the on/off switches 25 and 35 are each in the open state, the on/off switches 64 and 94 are each in the closed state, and the on/off switches 63 and 93 are each in the open state.

The capacitance detecting apparatus 100 detects a current flowing via the on/off switch 63 into the shield member Es1 by means of the current detection circuit 71 during the time T1 for the purposes of detecting the possible insulation failure between the sensor electrode E1 and the shield member Es1. In addition, the capacitance detecting apparatus 100 detects a current flowing via the on/off switch 93 into the shield member Es2 by means of the current detection circuit 101 during the time T1 for the purposes of detecting the possible insulation failure between the sensor electrode E2 and the shield member Es2. The electric potential VE1 of the sensor electrode E1 and an electric potential of the wiring connected thereto are both specified to be the voltage V1, and the electric potential Vs1 of the shield member Es1 is specified to be the voltage V3 during the time T1. That is, VE1≠Vs1 and thus the flowing current is not detected by the current detection circuit 71 as long as the insulation between the shield member Es1 and both the sensor electrode E1 and the wiring connected thereto is excellent. However, in the cases where the insulation failure occurs between the shield member Es1 and both the sensor electrode E1 and the wiring connected thereto, the flowing current can be detected by the current detection circuit 71. Further, the electric potential VE2 of the sensor electrode E2 and an electric potential of the wiring connected thereto are both specified to be the voltage V2, and the electric potential Vs2 of the shield member Es2 is specified to be the voltage V5 during the time T1. That is, VE2≠Vs2 and thus the flowing current is not detected by the current detection circuit 101 as long as the insulation between the shield member Es2 and both the sensor electrode E2 and the wiring connected thereto is excellent. However, in the cases where the insulation failure occurs between the shield member Es2 and both the sensor electrode E2 and the wiring connected thereto, the flowing current can be detected by the current detection circuit 101. Accordingly, the current detection circuit 71 detects the possible insulation failure between the shield member Es1 and both the sensor electrode E1 and the wiring connected thereto while the current detection circuit 101 detects the insulation failure between the shield member Es2 and both the sensor electrode E2 and the wiring connected thereto.

According to the capacitance detecting apparatus 100 of the ninth embodiment, the insulation failure between the sensor electrode E1 and the shield member Es1, and between the sensor electrode E2 and the shield member Es2 can be promptly detected so that an action can be immediately taken for the possible insulation failure.

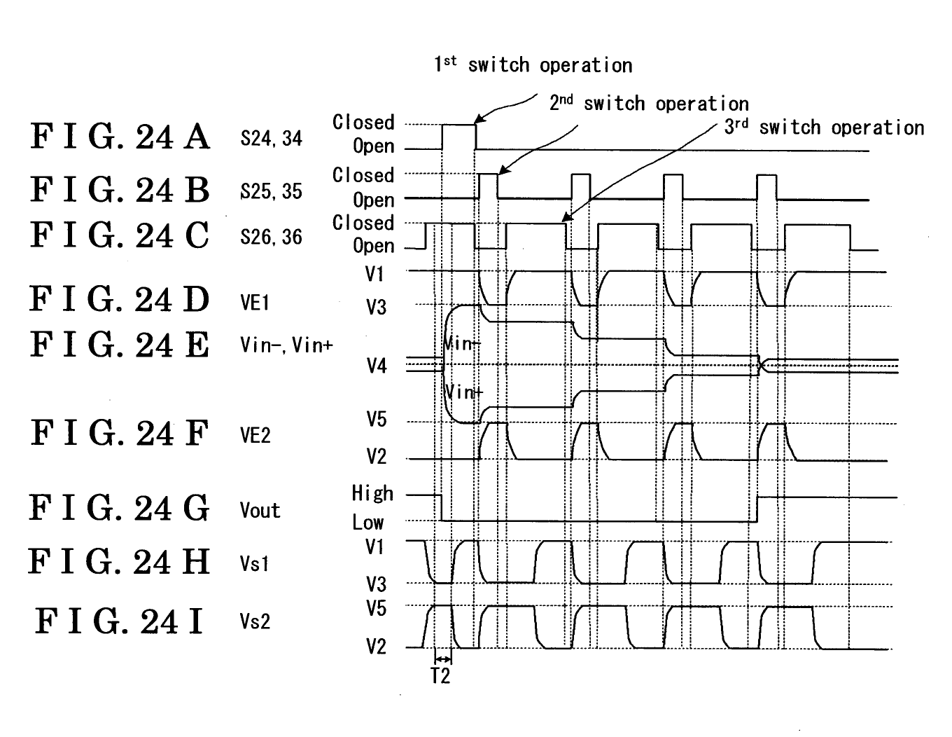

The detection of the insulation failure between the sensor electrode E1 and the shield member Es, and between the sensor electrode E2 and the shield member Es2 is not necessarily conducted during the time T1 in FIGS. 23A to 23I. That is, the detection of the insulation failure between the sensor electrode E1 and the shield member Es1, and between the sensor electrode E2 and the shield member Es2 can be conducted during a time T2 as illustrated in FIGS. 24A to 24I.

FIGS. 24A to 24I are timing charts for detecting the insulation failure at a different timing and are corresponding to FIGS. 23A to 23I. The second and third switch operations in FIGS. 24B and 24C are same as those in FIGS. 23B and 23C. First, a predetermined time period is defined that is started after the output signal Vout of the comparator 22 is shifted from the low level to the high level and is finished before the on/off switches 25 and 35 are each shifted from the open state to the closed state that occurs immediately after the on/off switches 24 and 34 are each shifted from the closed state to the open state. Then, the time T2 is defined during the aforementioned predetermined time. The current flowing to the shield member Es1 is measured and detected by the current detection circuit 71 during at least a portion of the time T2 to thereby detect the possible insulation failure between the sensor electrode E1 and the shield member Es1. In addition, the current flowing to the shield member Es2 is measured and detected by the current detection circuit 101 during at least a portion of the time T2 to thereby detect the possible insulation failure between the sensor electrode E2 and the shield member Es2. As illustrated in FIGS. 24A to 24I, the on/off switches 26 and 36 are each shifted from the open state to the closed state with the on/off switches 25 and 35 in the open state (see FIG. 24C) before the on/off switches 24 and 34 are each shifted from the open state to the closed state through the first switch operation (see. FIG. 24A). Then, the electric potential VE1 of the sensor electrode E1 and the wiring connected thereto are fixed at the power-supply voltage V1, and also the electric potential VE2 of the sensor electrode E2 and the wiring connected thereto are fixed at the power-supply voltage V2. At this time, while the on/off switches 26 and 36 are each in the closed state, the on/off switches 63 and 93 are each shifted to the open state. Then, the on/off switches 64 and 94 are each shifted from the open state to the closed state and the electric potential Vs1 of the shield member Es1 is connected to the fixed voltage V3 while the electric potential Vs2 of the shield member Es2 is connected to the second fixed voltage V5. In such circumstances, the current flowing between the Op-Amp 61 and the shield member Es1 is measured by the current detection circuit 71 and also the current flowing between the Op-Amp 91 and the shield member Es2 is measured by the current detection circuit 101 during the time T2. The electric potential VE1 of the sensor electrode E1 and an electric potential of the wiring connected thereto are both specified to be the voltage V1, and the electric potential Vs1 of the shield member Es1 is specified to be the voltage V3 during the time T2. That is, VE1≠Vs1 and thus the flowing current is not detected by the current detection circuit 71 as long as the insulation between the shield member Es1 and both the sensor electrode E1 and the wiring connected thereto is excellent. However, in the cases where the insulation failure occurs between the shield member Es1 and both the sensor electrode E1 and the wiring connected thereto, the flowing current can be detected by the current detection circuit 71. In the same way, the electric potential VE2 of the sensor electrode E2 and an electric potential of the wiring connected thereto are both specified to be the voltage V2, and the electric potential Vs2 of the shield member Es2 is specified to be the voltage V5 during the time T2. That is, VE2≠Vs2 and thus the flowing current is not detected by the current detection circuit 101 as long as the insulation between the shield member Es2 and both the sensor electrode E2 and the wiring connected thereto is excellent. However, in the cases where the insulation failure occurs between the shield member Es2 and both the sensor electrode E2 and the wiring connected thereto, the flowing current can be detected by the current detection circuit 101. As illustrated in FIG. 24A, the on/off switches 24 and 34 are each shifted from the open state to the closed state with the on/off switches 26 and 36 each in the closed state. Alternatively, the on/off switches 24 and 34 may be each shifted from the open state to the closed state regardless of “on” and “off” states of the on/off switches 26, 36, 64, and 94. After the lapse of the time T2 and before the start of the second switch operation, the on/off switches 64 and 94 are each shifted from the closed state to the open state, and the on/off switches 63 and 93 are each shifted from the open state to the closed state. Afterwards, the on/off switches 24 and 34, and the on/off switches 26 and 36 are each shifted from the closed state to the open state to thereby finish the first switch operation. Next, the on/off switches 63 and 93 are each shifted from the closed state to the open state to thereby prepare for the second switch operation. According to another example illustrated in FIG. 22B, the Op-Amps 61 and 91 are eliminated from the example illustrated in FIG. 22A. The wiring connecting one end of the on/off switch 63, one end of the on/off switch 64, and the non-inverting input terminal of the Op-Amp 61 in FIG. 22A is replaced by a wiring connecting one end of the on/off switch 63, one end of the on/off switch 64, and the current detection circuit 71 in FIG. 22B. Further, the wiring connecting one end of the on/off switch 93, one end of the on/off switch 94, and the non-inverting imputer terminal of the Op-Amp 91 in FIG. 22A is replaced by a wiring connecting one end of the on/off switch 93, one end of the on/off switch 94, and the current detection circuit 101 in FIG. 22B. The open and close operations of the on/off switches in FIG. 22B are same as those in FIG. 22A to thereby achieve the same advantage thereof.

According to the capacitance detecting apparatus 100 of the ninth embodiment, the current flowing to the shield member Es1 is measured by the current detection circuit 71 while the current flowing to the shield member Es2 is measured by the current detection circuit 101 during the time T2 to thereby detect the possible insulation failure between the sensor electrode E1 and the shield member Es1, and between the sensor electrode E2 and the shield member Es2.

### Tenth Embodiment

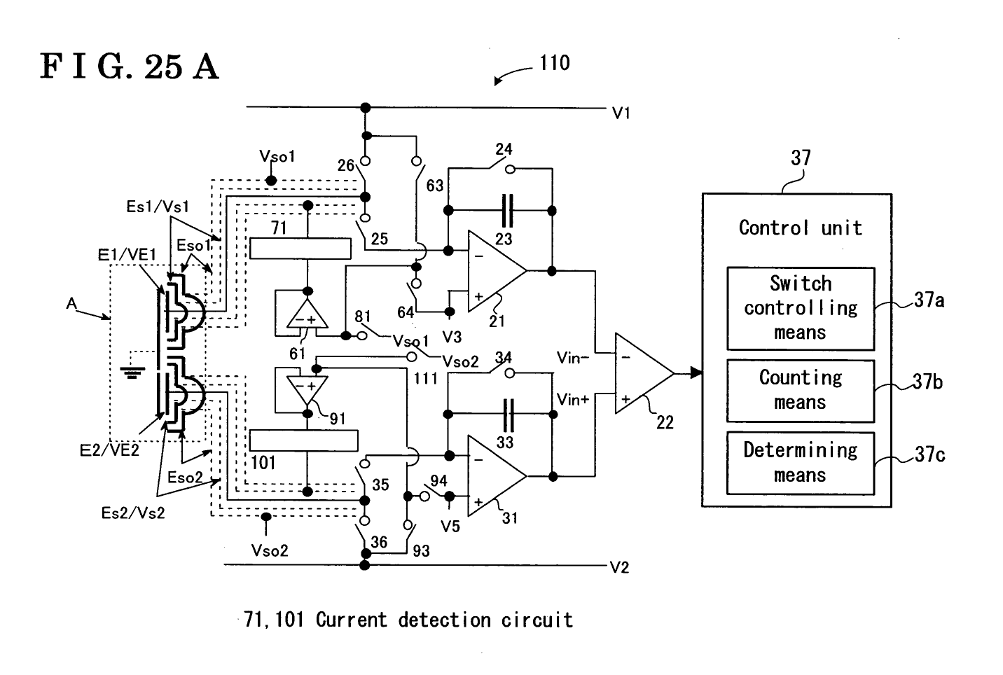

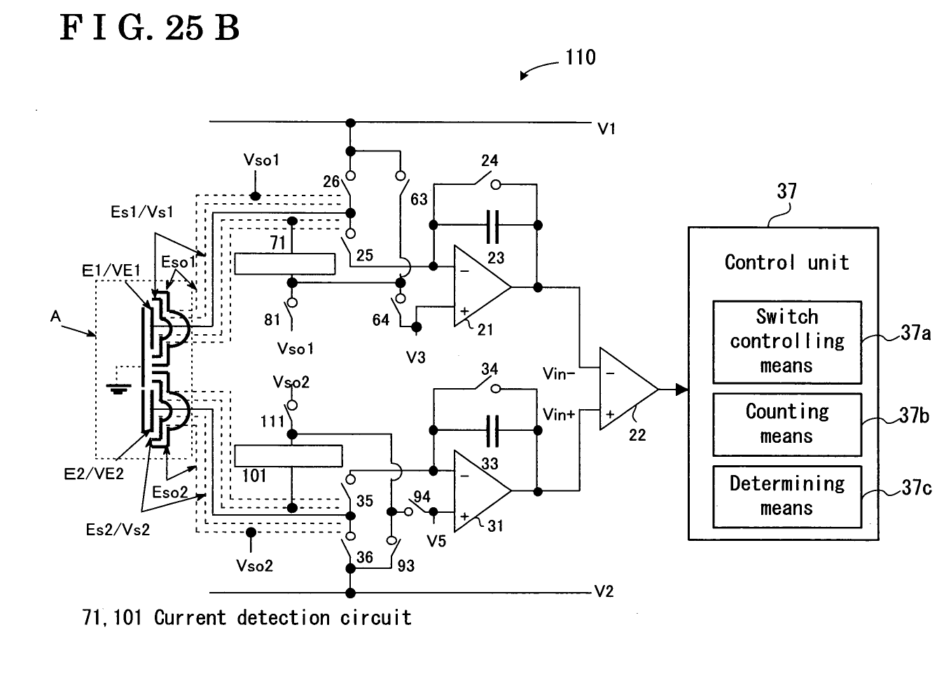

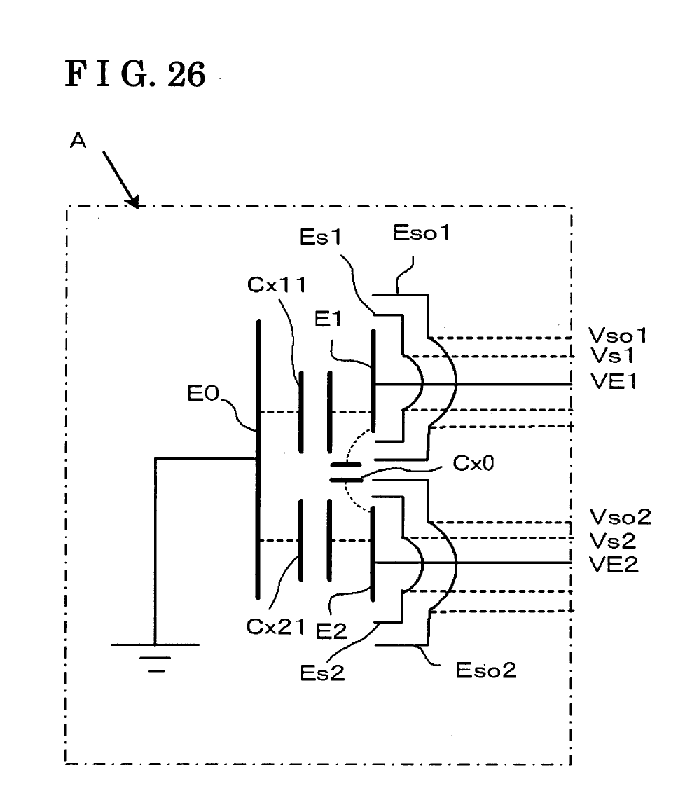

FIG. 25A is a schematic circuit diagram illustrating a capacitance detecting apparatus 110 according to one example of a tenth embodiment. FIG. 26 is an explanatory view of a portion depicted from A in FIG. 25A.

The capacitance detecting apparatus 110 additionally includes a first external shield member Eso1, a second external shield member Eso2, an on/off switch 81, and an on/off switch 111 in contrast to the capacitance detecting apparatus 100 according to the ninth embodiment. The external shield member Eso1 surrounds at least a portion of the sensor electrode E1, the wiring that connects the sensor electrode E1 and the on/off switches 25 and 26, and the first shield member Es1. In addition, the external shield member Eso1 is connected to the third fixed voltage Vso1. A first end of the on/off switch 81 is connected to the third fixed voltage Vso1 while a second end of the on/off switch 81 is connected to a second end of the on/off switch 64 of which a first end is connected to the first fixed voltage V3, a second end of the on/off switch 63 of which a first end is connected to the first power-supply voltage V1, and the non-inverting input terminal of the Op-Amp 61. The open and close operations of the on/off switch 81 are controlled by the control unit 37.

The external shield member Eso2 surrounds at least a portion of the sensor electrode E2, a wiring that connects the sensor electrode E2 and the on/off switches 35 and 36, and the second shield member Es2. In addition, the external shield member Eso2 is connected to a fourth fixed voltage Vso2. A first end of the on/off switch 111 is connected to the fourth fixed voltage Vso2 while a second end of the on/off switch 111 is connected to a second end of the on/off switch 94 of which a first end is connected to the second fixed voltage V5, a second end of the on/off switch 93 of which a first end is connected to the second power-supply voltage V2, and the non-inverting input terminal of the Op-Amp 91. The open and close operations of the on/off switch 111 are controlled by the control unit 37. The structure of the capacitance detecting apparatus 110 other than the aforementioned external shield members Eso1 and Eso2, and the on/off switches 81 and 111 is same as that of the capacitance detecting apparatus 100 according to the ninth embodiment. In respective combinations of the on/off switches 25 and 26, the on/off switches 35 and 36, the on/off switches 63, 64, and 81, and the on/off switches 93, 94, and 111, two or more on/off switches in the identical combination are never shifted to the closed state at the same time.

In the cases where the shield member Es1 fails to surround a portion of electrode surfaces of the sensor electrode E1 except for the surface facing the ground electrode E0 and the wiring connecting the sensor electrode E1 and the on/off switches 25 and 26, a parasitic capacitor is generated between that portion not surrounded by the shield member Es1 and the external shield member Eso1. Thus, the shield member Es1 should desirably surround, to the greatest possible extent, the electrode surfaces of the sensor electrode E1 except for the surface facing the ground electrode E0 and the wiring connecting the sensor electrode E1 and the on/off switches 25 and 26. Then, the external shield member Eso1 should desirably surround the shield member Es1.

Because of the same reason as the above, the shield member Es2 should desirably surround, to the greatest possible extent, the electrode surfaces of the sensor electrode E2 except for the surface facing the ground electrode E0 and the wiring connecting the sensor electrode E2 and the on/off switches 35 and 36. Then, the external shield member Eso2 should desirably surround the shield member Es2.

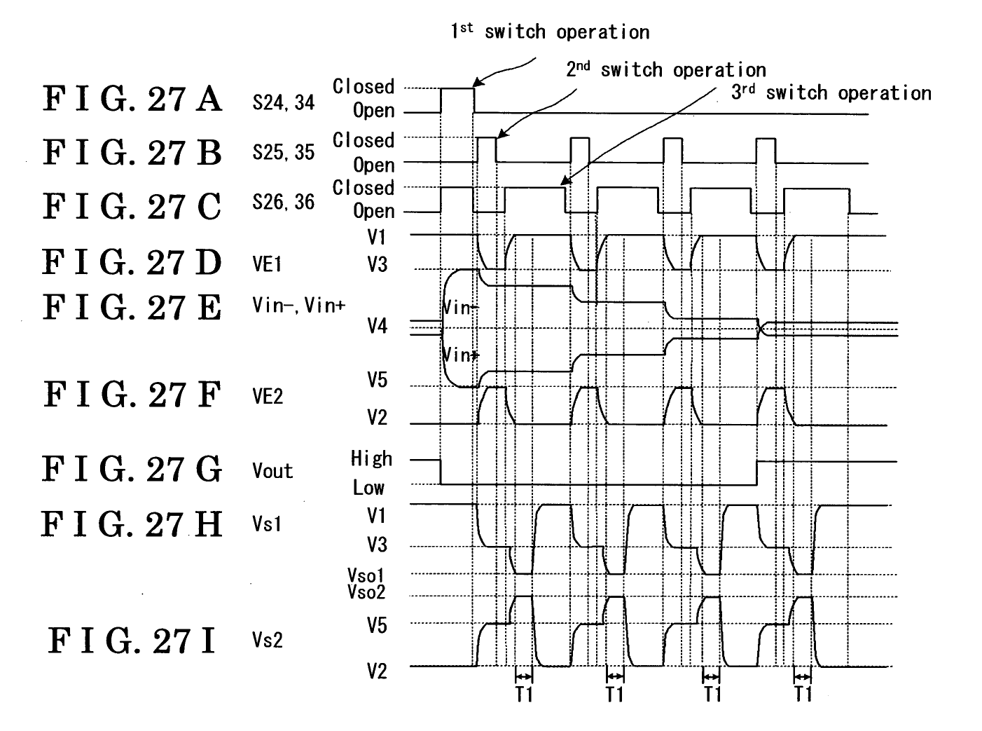

FIGS. 27A to 27I are timing charts for explaining an operation of the capacitance detecting apparatus 110. A basic operation of the capacitance detecting apparatus 110 is same as that of the capacitance detecting apparatus 100 according to the ninth embodiment. That is, the capacitance detecting apparatus 100 performs a first switch operation followed by repetition of second and third switch operations. Precisely, in the same way as the second embodiment, the control unit 37 performs the first switch operation in which the on/off switches 24 and 34 are each brought to the closed state for a predetermined time from the open state and then are each returned to the open state (see FIG. 27A). Afterwards, the control unit 37 repeatedly and alternately performs the second switch operation in which the on/off switches 25 and 35 are each brought to the closed state for a predetermined time from the open state and then are each returned to the open state (see FIG. 27B), and the third switch operation in which the on/off switches 26 and 36 are each brought to the closed state for a predetermined time from the open state and then are each returned to the open state (see FIG. 27C). In this case, as illustrated in FIGS. 27A to 27C, the on/off switches 26 and 36 may be shifted from the open state to the closed state and retained therein for a predetermined time before the second switch operation is performed after the first switch operation. Through the second switch operation, the on/off switches 25, 35, 64, and 94 are shifted from the open state to the closed state at the same time. Afterwards, the on/off switches 64 and 94 are each shifted from the closed state to the open state after the on/off switches 25 and 35 are each shifted from the closed state to the open state. Then, while the on/off switches 26 and 36 are each in the closed state in the third switch operation, a time T1 is defined during which the on/off switches 63, 64, 93, and 94 are each in the open state and the on/off switches 81 and 111 are each in the closed state. The on/off switches 64, 94, 81, and 111 are each shifted to the open state and the on/off switches 63 and 93 are each shifted to the closed state before the on/off switches 26 and 36 are each shifted from the closed state to the open state. After the on/off switches 26 and 36 are each shifted from the closed state to the open state and before the on/off switches 25 and 35 are each shifted from the open state to the closed state, the on/off switches 63 and 93 are each shifted from the closed state to the open state.

In FIGS. 27H and 27I, at the time the on/off switches 25 and 35 are each returned to the open state from the closed state through the second switch operation, the electric potential Vs1 of the shield member Es1 is set to the first fixed voltage V3, and the electric potential Vs2 of the shield member Es2 is set to the second fixed voltage V5.

At the time the on/off switches 26 and 36 are each returned to the open state from the closed state through the third switch operation, the electric potential Vs1 of the shield member Es1 is set to the power-supply voltage V1, and the electric potential Vs2 of the shield member Es2 is set to the power-supply voltage V2. Accordingly, in response to the repetition of the second and third switch operations, the electric potentials Vs1 and Vs2 of the shield members Es1 and Es2, respectively, periodically change to thereby generate a noise. However, since the external shield members Eso1 and Eso2 are fixed at the voltages Vso1 and Vso2, respectively, radiation of noise to the outside is prevented. In this case, the voltages Vso1 and Vso2 may be equal to each other.

According to the control of the control unit 37, the time T1 is defined after the on/off switches 26 and 36 are each shifted from the open state to the closed state through the third switch operation and before the on/off switches 63 and 93 are each shifted from the open state to the closed state. The on/off switches 81 and 111 are each retained in the closed state during the time T1. During the time T1, the electric potential VE1 of the sensor electrode E1 is set to the power-supply voltage V1, and the electric potential Vs1 of the shield member Es1 is set to the third fixed voltage Vso1. In addition, during the time T1, the electric potential VE2 of the sensor electrode E2 is set to the power-supply voltage V2 and the electric potential Vs2 of the shield member Es2 is set to the fourth fixed voltage Vso2.

The electric potential VE1 of the sensor electrode E1 and an electric potential of the wiring connected thereto are both specified to be the voltage V1, and the electric potential Vs1 of the shield member Es1 is specified to be the voltage Vso1 during the time T1. That is, VE1≠Vs1 and thus the flowing current is not detected by the current detection circuit 71 as long as the insulation between the shield member Es1 and both the sensor electrode E1 and the wiring connected thereto is excellent. However, in the cases where the insulation failure occurs between the shield member Es1 and both the sensor electrode E1 and the wiring connected thereto, the flowing current can be detected by the current detection circuit 71. In addition, the electric potential VE2 of the sensor electrode E2 and an electric potential of the wiring connected thereto are both specified to be the voltage V2, and the electric potential Vs2 of the shield member Es2 is specified to be the voltage Vso2 during the time T1. That is, VE2≠Vs2 and thus the flowing current is not detected by the current detection circuit 101 as long as the insulation between the shield member Es2 and both the sensor electrode E2 and the wiring connected thereto is excellent. However, in the cases where the insulation failure occurs between the shield member Es2 and both the sensor electrode E2 and the wiring connected thereto, the flowing current can be detected by the current detection circuit 101. As a result, the current detection circuit 71 detects the possible insulation failure between the shield member Es1 and both the sensor electrode E1 and the wiring connected thereto, while the current detection circuit 101 detects the possible insulation failure between the shield member Es2 and both the sensor electrode E2 and the wiring connected thereto. Further, since the electric potentials of the shield member Es1 and the first external shield member Eso1 are substantially equal to each other during the time T1, the current flowing between the shield member Es1 and the first external shield member Eso1 is substantially zero during the time T1 even if the insulation failure Occurs between the shield member Es1 and the first external shield member Eso1. In the same way, since the electric potentials of the shield member Es2 and the second external shield member Eso2 are substantially equal to each other, the current flowing between the shield member Es2 and the second external shield member Eso2 is substantially zero during the time T1 even if the insulation failure occurs between the shield member Es2 and the second external shield member Eso2. As a result, the effect of the insulation failure between the shield member Es1 and the first external shield member Eso1, and between the shield member Es2 and the second external shield member Eso2 can be prevented from being added to the respective currents flowing through the current detection circuits 71 and 101 and thus only the insulation failure resulting from the decrease in the capacitance detection accuracy can be detected.

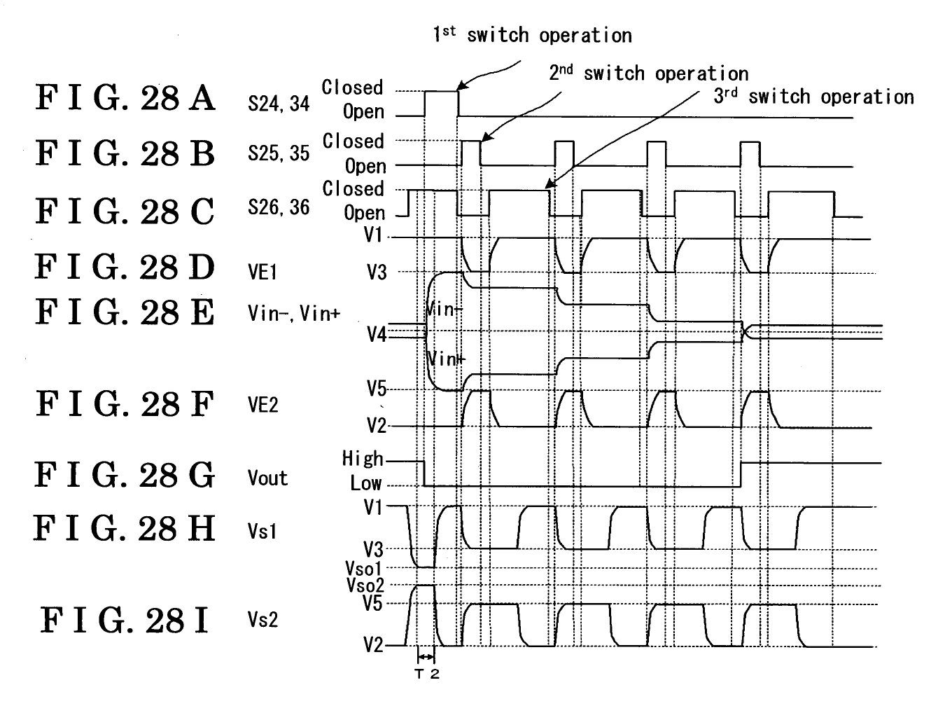

The insulation failure between the shield member Es1 and the sensor electrode E1, and between the shield member Es2 and the sensor electrode E2 is not necessarily detected during the time T1 illustrated in FIGS. 27A to 27I. The insulation failure between the shield member Es1 and the Sensor electrode E1, and between the shield member Es2 and the sensor electrode E2 may be detected during a time T2 illustrated in FIGS. 28A to 28I.

FIGS. 28A to 28I are timing charts for explaining the detection of the insulation failure at a different timing and are corresponding to FIGS. 27A to 27I. The second and third switch operations in FIGS. 28B and 28C are same as those in FIGS. 27B and 27C. First, a predetermined time period is defined that is started after the output signal Vout of the comparator 22 is shifted from a low level to a high level and is finished before the on/off switches 25 and 35 are each shifted from the open state to the closed state that occurs immediately after the on/off switches 24 and 34 are each shifted from the closed state to the open state. Then, the time T2 is defined during the aforementioned predetermined time. The current flowing to the shield member Es1 is measured and detected by the current detection circuit 71 during at least a portion of the time T2 to thereby detect the possible insulation failure between the sensor electrode E1 and the shield member Es1. In addition, the current flowing to the shield member Es2 is measured and detected by the current detection circuit 101 during at least a portion of the time T2 to thereby detect the possible insulation failure between the sensor electrode E2 and the shield member Es2. As illustrated in FIGS. 28A to 28I, the on/off switches 26 and 36 are each shifted from the open state to the closed state with the on/off switches 25 and 35 in the open state (see FIG. 28C) before the on/off switches 24 and 34 are each shifted from the open state to the closed state through the first switch operation (see FIG. 28A). Then, the electric potential VE1 of the sensor electrode E1 and the wiring connected thereto are fixed at the power-supply voltage V1 while the electric potential VE2 of the sensor electrode E2 and the wiring connected thereto are fixed at the power-supply voltage V2. At this time, while the on/off switches 26 and 36 are each in the closed state, the on/off switches 63, 64, 93, and 94 are each shifted to be retained in the open state and then the on/off switches 81 and 111 are each shifted from the open state to the closed state. The electric potential Vs1 of the shield member Es1 is connected to the fixed voltage Vso1 and the electric potential Vs2 of the shield member Es2 is connected to the fixed voltage Vso2 (see FIGS. 28H and 28I). In such circumstances, the current flowing between the Op-Amp 61 and the shield member Es1 is measured by the current detection circuit 71 while the current flowing between the Op-Amp 91 and the shield member Es2 is measured by the current detection circuit 101 during the time T2. The electric potential VE1 of the sensor electrode E1 and an electric potential of the wiring connected thereto are both specified to be the voltage V1, and the electric potential Vs1 of the shield member Es1 is specified to be the voltage V3 during the time T2. That is, VE1≠Vs1 and thus the flowing current is not detected by the current detection circuit 71 as long as the insulation between the shield member Es1 and both the sensor electrode E1 and the wiring connected thereto is excellent. However, in the cases where the insulation failure occurs between the shield member Es1 and both the sensor-electrode E1 and the wiring connected thereto, the flowing current can be detected by the current detection circuit 71. In the same way, the electric potential VE2 of the sensor electrode E2 and an electric potential of the wiring connected thereto are both specified to be the voltage V2, and the electric potential Vs2 of the shield member Es2 is specified to be the voltage V5 during the time T2. That is, VE2≠Vs2 and thus the flowing current is not detected by the current detection circuit 101 as long as the insulation between the shield member Es2 and both the sensor electrode E2 and the wiring connected thereto is excellent. However, in the cases where the insulation failure occurs between the shield member Es2 and both the sensor electrode E2 and the wiring connected thereto, the flowing current can be detected by the current detection circuit 101. Further, since the electric potentials of the shield member Es1 and the first external shield member Eso1 are substantially equal to each other, the current flowing between the shield member Es1 and the first external shield member Eso1 is substantially zero during the time T2 even if the insulation failure occurs between the shield member Es1 and the first external shield member Eso1. In the same way, since the electric potentials of the shield member Es2 and the second external shield member Eso2 are substantially equal to each other, the current flowing between the shield member Es2 and the second external shield member Eso2 is substantially zero during the time T2 even if the insulation failure occurs between the shield member Es2 and the second external shield member Eso2. As a result, the effect of the insulation failure between the shield member Es1 and the first external shield member Eso1, and between the shield member Es2 and the second external shield member Eso2 can be prevented from being added to the respective currents flowing through the current detection circuits 71 and 101 and thus only the insulation failure resulting from the decrease in the capacitance detection accuracy can be detected. In FIGS. 28A and 28C, the on/off switches 24 and 34 are each shifted from the open state to the closed state while the on/off switches 26 and 36 are in the closed state. However, the on/off switches 24 and 34 may be each shifted from the open state to the closed state regardless of “on” and “off” states of the on/off switches 26, 36, 81, and 111. After the lapse of the time T2 and before the start of the second switch operation, the on/off switches 81 and 111 are each shifted from the closed state to the open state, and the on/off switches 63 and 93 are each shifted from the open state to the closed state. Afterwards, the on/off switches 24 and 34, and the on/off switches 26 and 36 are each shifted from the closed state to the open state to thereby finish the first switch operation. Next, the on/off switches 63 and 93 are each shifted from the closed state to the open state to thereby prepare for the second switch operation. According to another example illustrated in FIG. 25B, the Op-Amps 61 and 91 are eliminated from the example illustrated in FIG. 25A. The wiring connecting one end of the on/off switch 63, one end of the on/off switch 64, and the non-inverting input terminal of the Op-Amp 61 in FIG. 25A is replaced by a wiring connecting one end of the on/off switch 63, one end of the on/off switch 64, and the current detection circuit 71 in FIG. 25B. Further, the wiring connecting one end of the on/off switch 93, one end of the on/off switch 94, and the non-inverting input terminal of the Op-Amp 91 in FIG. 25A is replaced by a wiring connecting one end of the on/off switch 93, one end of the on/off switch 94, and the current detection circuit 101 in FIG. 25B. The open and close operations of the on/off switches in FIG. 25B are same as those in FIG. 25A to thereby achieve the same advantage thereof.

According to the capacitance detecting apparatus 110 of the tenth embodiment, the current flowing to the shield member Es1 is measured by the current detection circuit 71, and the current flowing to the shield member Es2 is measured by the current detection circuit 101 during the time T2 to thereby detect the possible insulation failure between the sensor electrode E1 and the shield member Es1, and between the sensor electrode E2 and the shield member Es2.

### Eleventh Embodiment

The first and second sensor electrodes E1 and E2 of the second, fourth, and eighth to tenth embodiments are not limited to the above-described structures, and the followings are applicable.

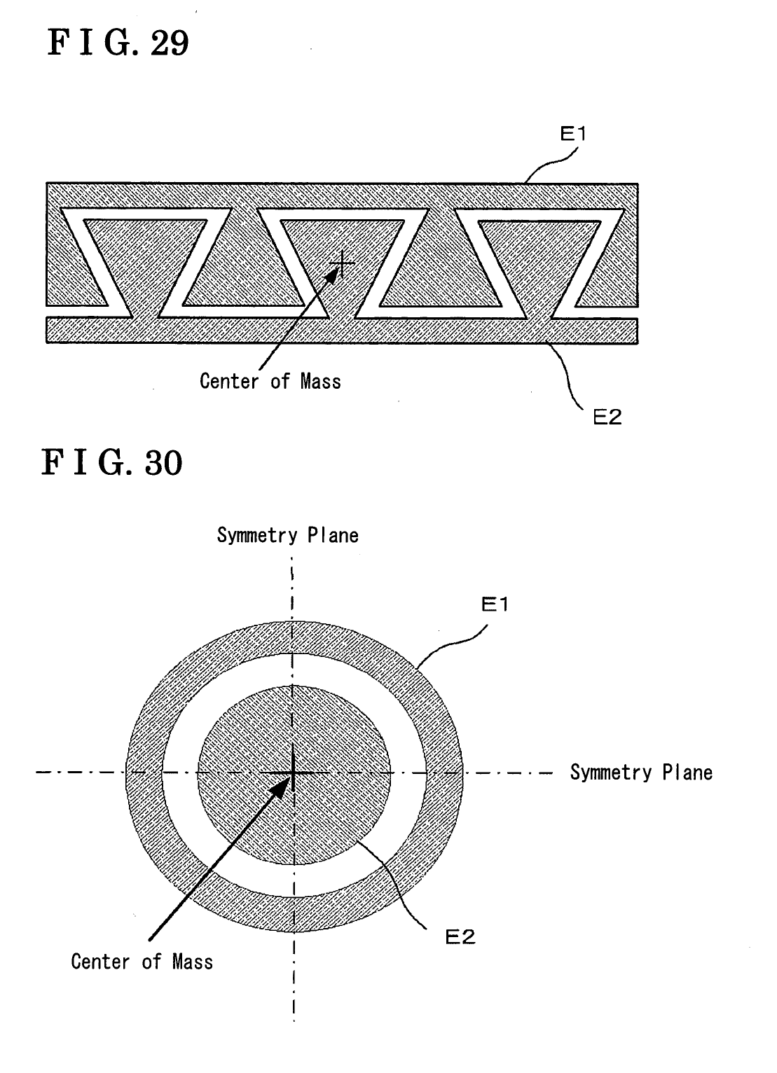

FIG. 29 is a view illustrating an example of the sensor electrodes E1 and E2. The first and second sensor electrodes E1 and E2 are arranged to face each other. The first sensor electrode E1 is characterized with first projections extending towards the second sensor electrode E2, and the second sensor electrode E2 is characterized with second projections extending towards the first sensor electrode E1. The first and second sensor electrodes E1 and E2 are arranged in a manner that each first projection does not overlap the corresponding second projection. An area of the first sensor electrode E1 is substantially equal to the one of the second sensor electrode E2. The center of mass of the first sensor electrode E1 substantially matches the center of mass of the second sensor electrode E2.

As described above, because the area of the first sensor electrode E1 is substantially the same as the one of the second sensor electrode E2, the sum of electric charges accumulated at each electrode E1 and E2 become equal. As described above, when each center of mass substantially matches each other, the electric charges accumulated are focused on the center of mass of each first and second sensor electrode E1 and E2. In such circumstances, changes in an electric dipole moment due to electric charges seen from an exterior ambient are reduced and the generation of radio noise is restrained. Further, an amount of electric charges induced by disturbances at the first sensor electrode E1 become equal to an amount of electric charges induced by disturbances at the second sensor electrode E2, thereby reducing influences of the disturbances.

FIG. 30 is a view illustrating another example of the sensor electrodes E1 and E2. The first sensor electrode E1 is arranged substantially in a concentric configuration with the second sensor electrode E2. The first sensor electrode E1 surrounds an exterior ambient of the second sensor electrode E2. The center of mass of the first sensor electrode E1 substantially matches the center of mass of the second sensor electrode E2. Further, the area of the first sensor electrode E1 is substantially the same as the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass.

As described above, when the first and second sensor electrodes E1 and E2 are symmetrical with respect to the at least two symmetry planes crossing the identical center of mass, changes in an electric dipole moment due to electric charges seen from an exterior ambient are reduced and the generation of ratio noise is restrained. Further, an amount of electric charges induced by disturbances at the first sensor electrode E1 is equal to an amount of electric charges induced by disturbances at the second sensor electrode E2, thereby reducing influences of the disturbances.

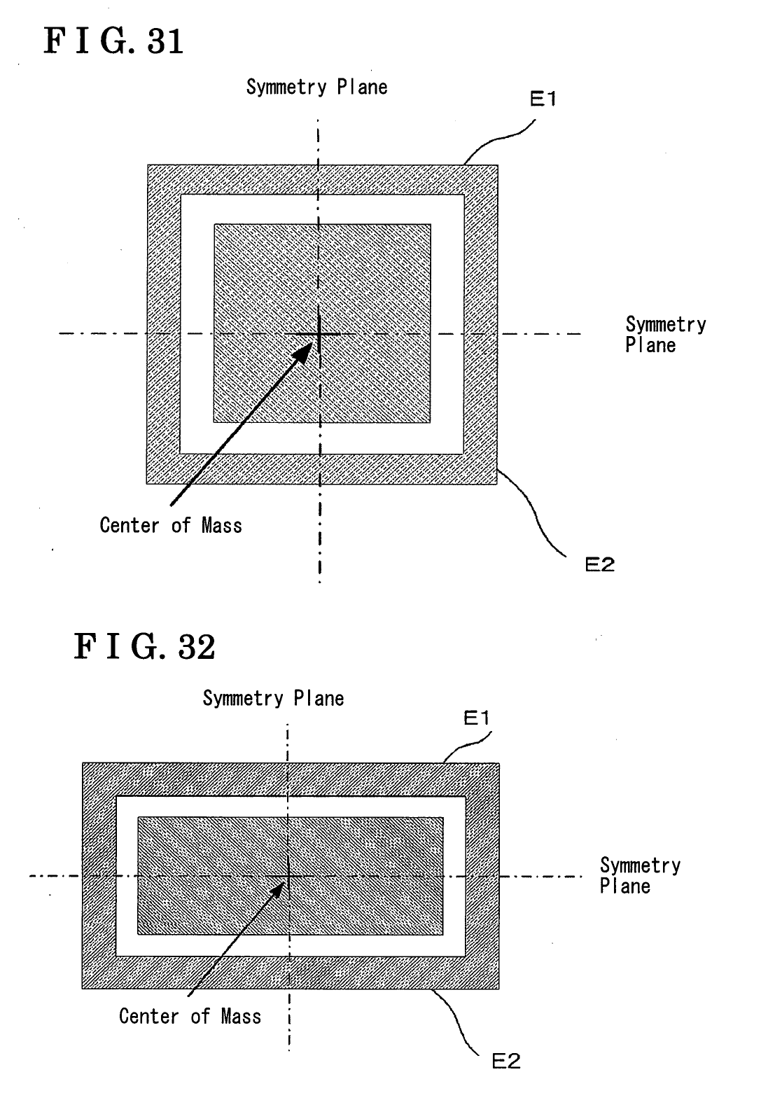

FIG. 31 is a view illustrating still another example of the sensor electrodes E1 and E2. The second sensor electrode E2 is of a square shape, and the first sensor electrode E1 is arranged so as to surround the second sensor electrode E2. The center of mass of the first sensor electrode E1 substantially matches the center of mass of the second sensor electrode E2. An area of the first sensor electrode E1 is substantially equal to the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass.

FIG. 32 is a view illustrating still another example of the sensor electrodes E1 and E2. The second sensor electrode E2 is of a rectangular shape, and the first sensor electrode E1 is arranged so as to surround the second sensor electrode E2. The center of mass of the first sensor electrode E1 substantially matches the center of mass of the second sensor electrode E2. An area of the first sensor electrode E1 is substantially equal to the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass.

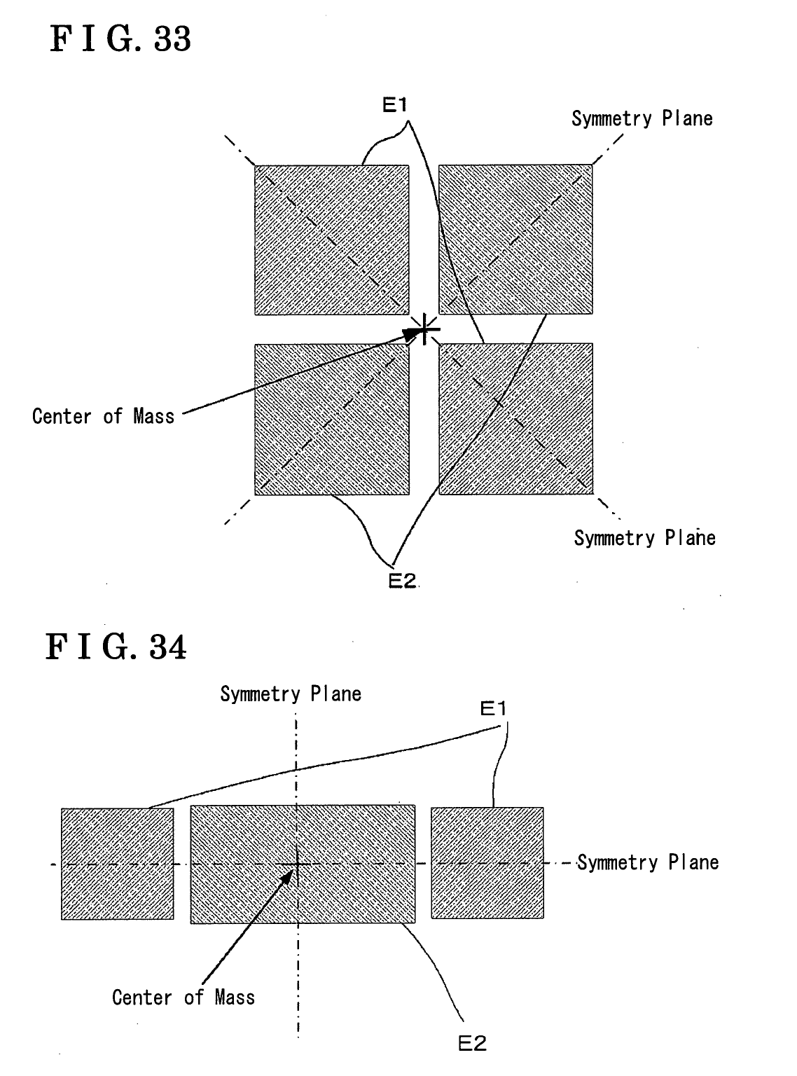

FIG. 33 is a view illustrating still another example of the sensor electrodes E1 and E2. Each of the first and second sensor electrodes E1 and E2 is structured with an arbitrary quantity of electric conductor. In FIG. 33, the first sensor electrode E1 is structured with two square-shaped electric conductors, and the second sensor electrode E2 is also structured with two square-shaped electric conductors. The two square-shaped electric conductors of the first sensor electrode E1 are arranged diagonally. Likewise, the two square-shaped electric conductors of the second sensor electrode E2 are arranged diagonally.

The center of mass of the first sensor electrode E1 substantially matches the center of mass of the second sensor electrode E2. An area of the first sensor electrode E1 is substantially equal to the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass.

FIG. 34 is a view illustrating still another example of the sensor electrodes E1 and E2. The first sensor electrode E1 is structured with two square-shaped electric conductors, and the second sensor electrode E2 is structured with a single rectangular-shaped electric conductor. The electric conductor of the second sensor electrode E2 is interposed between the two square-shaped electric conductors of the first sensor electrode E1. The center of mass of the first sensor electrode E1 substantially matches the center of mass of the second sensor electrode E2. An area of the first sensor electrode E1 is substantially equal to the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass.

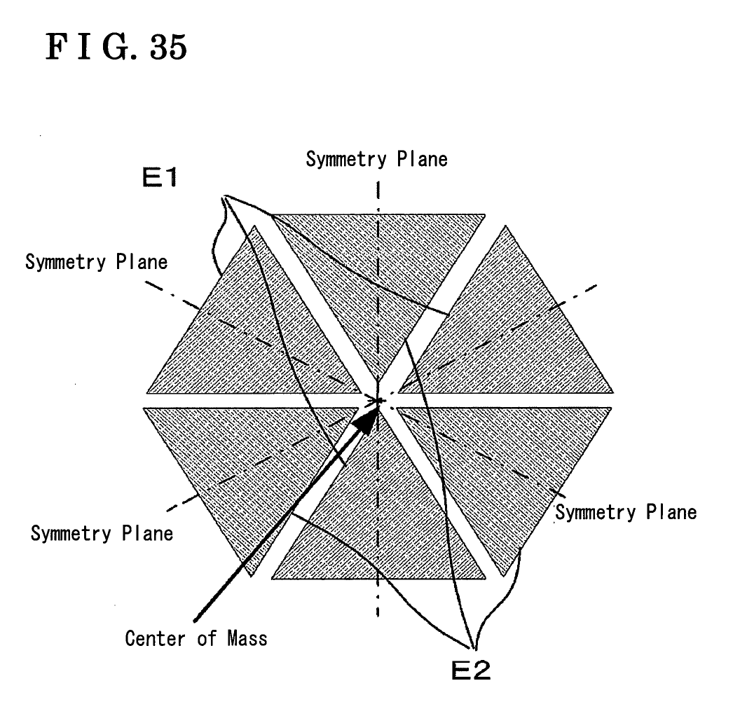

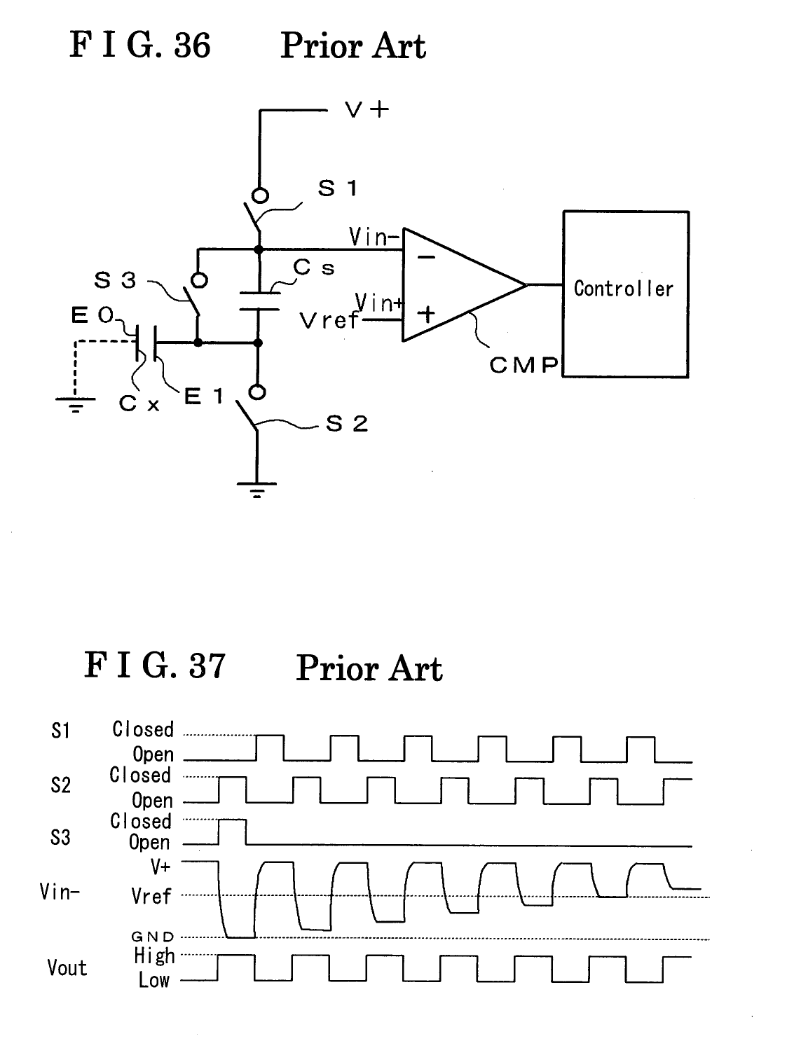

FIG. 35 is a view illustrating still another example of the sensor electrodes E1 and E2. The first sensor electrode E1 is structured with three pieces of first triangular-shaped conductors, and the second sensor electrode E2 is structured with three pieces of second triangular-shaped conductors. The six triangular-shaped conductors in total are arranged alternately to exhibit a hexagon.

The center of mass of the first sensor electrode E1 substantially matches the center of mass of the second sensor electrode E2. An area of the first sensor electrode E1 is substantially equal to the one of the second sensor electrode E2. The first sensor electrode E1 is symmetrical with respect to at least two symmetry planes crossing the identical center of mass. Likewise, the second sensor electrode E2 is symmetrical with respect to the at least two symmetry planes crossing the identical center of mass. The shape of the electrode is not limited to the above embodiments and can be modified in various ways.

According to the aforementioned first embodiment, the capacitance detecting apparatus 10 includes a first differential amplifier 11 including an inverting input terminal, a non-inverting input terminal, and an output terminal, the non-inverting input terminal inputting a first fixed voltage V3, a first reference capacitor 13 including a first electrode connected to the output terminal of the first Op-Amp 11 and a second electrode connected to the inverting input terminal of the first Op-Amp 11, a first on/off switch 14 including a first end connected to the output terminal of the first Op-Amp 11 and a second end connected to the inverting input terminal of the first Op-Amp 11, a second on/off switch 15 including a first end connected to the inverting input terminal of the first Op-Amp 11, a third on/off switch 15 including a first end connected to a first power-supply voltage V1 and a second end connected to the second end of the second on/off switch 15, a first sensor electrode E1 connected to the second end of the second on/off switch 15 and facing a ground electrode E0 having a constant electric potential, a first variable capacitance Cx11 being formed between the first sensor electrode E1 and the ground electrode E0 in response to a distance d between the first sensor electrode E1 and the ground electrode E0, switch controlling means 17a for performing a first switch operation in which the first on/off switch 14 is shifted to a closed state and returned to an open state, and then alternately repeating a second switch operation in which the second on/off switch 15 is shifted to a closed state and returned to an open state and a third switch operation in which the third on/off switch 16 is shifted to a closed state and returned to an open state, a comparator 12 including a first input terminal connected to the output terminal of the first Op-Amp 11 and a second input terminal inputting a voltage, the comparator 12 comparing an output voltage from the first Op-Amp and the voltage input to the second input terminal, counting means 17b for counting the number of times the second switch operation is repeated, and determining means 17c for determining changes in the first variable capacitance Cx11 formed between the first sensor electrode E1 and the ground electrode E0 based on the number of times the second switch operation is repeated that is counted by the counting means 17b before an output level of the comparator 12 is changed.

Accordingly, in the cases where the capacitance detecting apparatus 10 is used as a distance sensor, the capacitance detecting apparatus 10 with a simple structure can obtain an output in proportion to a distance d between the electrodes E1 and E0.

In the above, the fixed voltage V4 is provided to the input terminal (+) of the comparator 12. However, alternatively, the electric potential Vin+ that changes in reverse phase to the electric potential Vin− of the input terminal (−) of the comparator 12 may be provided to the input terminal (+) of the comparator 12 as in the second embodiment.

Further, according to the third embodiment, the capacitance detecting apparatus 40 further includes a fourth on/off switch 41 including a first end connected to the inverting input terminal of the first Op-Amp 11, a first compensation capacitor 43 including a first electrode connected to a second end of the fourth on/off switch 41 and a second electrode connected to a first compensation voltage V6, and a fifth on/off switch 42 including a first end connected to the second end of the fourth on/off switch 41 and a second end connected to the first compensation voltage V6. The switch controlling means 17a controls the fourth on/off switch 41 to be opened and closed at the same timing as the second on/off switch 15 and controls the fifth on/off switch 42 to be opened and closed at the same timing as the third on/off switch 16.

In the above, the fixed voltage V4 is provided to the input terminal (+) of the comparator 12. However, alternatively, the electric potential Vin+ that changes in reverse phase to the electric potential Vin− of the input terminal (−) of the comparator 12 may be provided to the input terminal (+) of the comparator 12 as in the second embodiment.

Furthermore, according to the fifth embodiment, the capacitance detecting apparatus 60 further includes a first shield member Es1 surrounding at least a portion of electrode surfaces of the first sensor electrode E1 except for a surface facing the ground electrode E0 and a wiring that connects the first sensor electrode E1 and the second and third on/off switches 15 and 16, an on/off switch 63 retaining the first shield member Es1 at the first fixed voltage V3 at least at a time the second on/off switch 15 is shifted from the closed state to the open state, and an on/off switch 64 retaining the first shield member Es1 at the first power-supply voltage V1 at least at a time the third on/off switch 16 is shifted from the closed state to the open state. As a result, the effect of the parasitic capacitor parasitic on the wiring can be prevented.

Furthermore, according to the sixth embodiment, the capacitance detecting apparatus 70 further includes a first current detection circuit 71 arranged to be connected between the on/off switch 63 and the first shield member Es1, and the control unit 17 for applying an electric potential different from the first power-supply voltage V1 to the first shield member Es1 during a predetermined time T1 or T2 during which the third on/off switch 16 is in a closed state. As a result, the insulation failure between the sensor electrode E1 and the shield member Es1 can be detected.

Furthermore, according to the seventh embodiment, the capacitance detecting apparatus 80 further includes a first external shield member Eso1 surrounding at least a portion of electrode surfaces of the first sensor electrode E1 except for a surface facing the ground electrode E0, a wiring that connects the first sensor electrode E1 and the second and third on/off switches 15 and 16, and the first shield member Es1, the first external shield member Eso1 being set at a predetermined constant electric potential. As a result, the insulation failure between the sensor electrode E1 and the shield member Es1 can be further easily detected.

Furthermore, according to the second embodiment, the capacitance detecting apparatus 20 includes a first Op-Amp 21 including an inverting input terminal, a non-inverting input terminal, and an output terminal, the non-inverting input terminal inputting a first fixed voltage V3, a first reference capacitor 23 including a first electrode connected to the output terminal of the first Op-Amp 21 and a second electrode connected to the inverting input terminal of the first Op-Amp 21, a first on/off switch 24 including a first end connected to the output terminal of the first Op-Amp 21 and a second end connected to the inverting input terminal of the first Op-Amp 21, a second on/off switch 25 including a first end connected to the inverting input terminal of the first Op-Amp 21, a third on/off switch 26 including a first end connected to a first power-supply voltage V1 and a second end connected to the second end of the second on/off switch 25, a first sensor electrode E1 connected to the second end of the second on/off switch 25 and facing a ground electrode E0 having a constant electric potential, a first variable capacitance Cx11 being formed between the first sensor electrode E1 and the ground electrode E0 in response to a distance d between the first sensor electrode E1 and the ground electrode E0, a second Op-Amp 31 including an inverting input terminal, a non-inverting input terminal, and an output terminal, the non-inverting input terminal inputting a second fixed voltage V5, a second referential capacitor 33 including a first electrode connected to the output terminal of the second Op-Amp 31 and a second electrode connected to the inverting input terminal of the second Op-Amp 31, a fourth on/off switch 34 including a first end connected to the output terminal of the second Op-Amp 31 and a second end connected to the inverting input terminal of the second Op-Amp 31, a fifth on/off switch 35 including a first end connected to the inverting input terminal of the second Op-Amp 31, a sixth on/off switch 36 including a first end connected to a second power-supply voltage V2 and a second end connected to the second end of the fifth on/off switch 35, a second sensor electrode E2 connected to the second end of the fifth on/off switch 35 and facing a ground electrode E0, a second variable capacitance Cx21 being formed between the second sensor electrode E2 and the ground electrode E0 in response to a distance d between the second sensor electrode E2 and the ground electrode E0, switch controlling means 37a for performing a first switch operation in which the first on/off switch 24 and the fourth on/off switch 34 are each shifted to a closed state and returned to an open state, and then alternately repeating a second switch operation in which the second on/off switch 25 and the fifth on/off switch 35 are each shifted to a closed state and returned to an open state and a third switch operation in which the third on/off switch 26 and the sixth on/off switch 36 are each shifted to a closed state and returned to an open state, a comparator 22 including a first input terminal connected to the output terminal of the first Op-Amp 21 and a second input terminal connected to the output terminal of the second Op-Amp 31, the comparator 22 comparing an output voltage from the first Op-Amp 21 and an output voltage from the second Op-Amp 31, counting means 37b for counting the number of times the second switch operation is repeated, and determining means 37c for determining changes in one of the first and second variable capacitances Cx11 and Cx21 formed between the first and second sensor electrodes E1, E2 and the ground electrode E0, respectively, based on the number of times the second switch operation is repeated that is counted by the counting means 37b before an output level of the comparator is changed.

Furthermore, according to the fourth embodiment, the capacitance detecting apparatus 50 further includes a seventh on/off switch 51 including a first end connected to the inverting input terminal of the first Op-Amp 21, a first correction capacitor 53 including a first electrode connected to a second end of the seventh on/off switch 51 and a second electrode connected to a first compensation voltage V6, an eighth on/off switch 52 including a first end connected to the second end of the seventh on/off switch 51 and a second end connected to the first compensation voltage V6, a ninth on/off switch 54 including a first end connected to the inverting input terminal of the second Op-Amp 31, a second compensation capacitor 56 including a first electrode connected to the second end of the ninth on/off switch 54 and a second electrode connected to a second correction voltage V7, and a tenth on/off switch 55 including a first end connected to the second end of the ninth on/off switch 54 and a second end connected to the second correction voltage V7. The switch controlling means 37a controls the seventh and ninth on/off switches 51 and 54 to be opened and closed at the same timing as the second and fifth on/off switches 25 and 35 and controls the eighth and tenth on/off switches 52 and 55 to be opened and closed at the same timing as the third and sixth on/off switches 26 and 36.

Furthermore, according to the eighth embodiment, the capacitance detecting apparatus 90 further includes a first shield member Es1 surrounding at least a portion of electrode surfaces of the first sensor electrode E1 except for a surface facing the ground electrode E0 and a wiring that connects the first sensor electrode E1 and the second and third on/off switches 25 and 26, an on/off switch 63 retaining the first shield member Es1 at the first fixed voltage V3 at least at a time the second on/off switch 25 is shifted from the closed state to the open state, an on/off switch 64 retaining the first shield member Es1 at the first power-supply voltage V1 at least at a time the third on/off switch 26 is shifted from the closed state to the open state, a second shield member Es2 surrounding at least a portion of electrode surfaces of the second sensor electrode E2 except for a surface facing the ground electrode E0 and a wiring that connects the second sensor electrode E2 and the fifth and sixth on/off switches 35 and 36, an on/off switch 93 retaining the second shield member Es2 at the second fixed voltage V5 at least at a time the fifth on/off switch 35 is shifted from the closed state to the open state, and an on/off switch 94 retaining the second shield member Es2 at the second power-supply voltage V2 at least at a time the sixth on/off switch 36 is shifted from the closed state to the open state. As a result, the insulation failure between the sensor electrodes E1 and E2, and the shield member Es1 and Es2, respectively, can be detected.

Furthermore, according to the ninth embodiment, the capacitance detecting apparatus 100 further includes a first current detection circuit 71 arranged to be connected between the on/off switch 63 and the first shield member Es1, the control unit 37 for applying an electric potential different from the first power-supply voltage V1 to the first shield member Es1 during a predetermined time T1 or T2 during which the third on/off switch 26 is in a closed state, a second current detection circuit 101 arranged to be connected between the on/off switch 93 and the second shield member Es2, and the control unit 37 for applying an electric potential different from the second power-supply voltage V2 to the second shield member Es2 during a predetermined time T1 or T2 during which the sixth on/off switch 36 is in a closed state. As a result, the insulation failure can be easily detected by the current detection circuit 71.

Furthermore, according to the tenth embodiment, the capacitance detecting apparatus 110 further includes a first external shield member Eso1 surrounding at least a portion of electrode surfaces of the first sensor electrode E1 except for a surface facing the ground electrode E0, a wiring that connects the first sensor electrode E1 and the second and third on/off switches 25 and 26, and the first shield member Es1, and a second external shield member Eso2 surrounding at least a portion of electrode surfaces of the second sensor electrode E2 except for a surface facing the ground electrode E0, a wiring that connects the second sensor electrode E2 and the fifth and sixth on/off switches 35 and 36, and the second shield member Es2. The first external shield member Eso1 and the second external shield member Eso2 are each set at a predetermined constant electric potential.

Furthermore, according to the eleventh embodiment, an area of the first sensor electrode E1 is equal to an area of the second sensor electrode E2, and a center of mass of the first sensor electrode E1 matches a center of mass of the second sensor electrode E2. As a result, an occurrence of radio noise can be restrained.

In this case, the first sensor electrode E1 is symmetrical with respect to at least two symmetry planes crossing the matched centers of mass, and the second sensor electrode E2 is symmetrical with respect to the at least two symmetry planes crossing the matched centers of mass. As a result, an occurrence of radio noise can be further restrained and the effect of electric charge of the sensor electrode induced by disturbance can be relieved.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

1. A capacitance detecting apparatus comprising:
a first differential amplifier including an inverting input terminal, a non-inverting input terminal, and an output terminal, the non-inverting input terminal inputting a first fixed voltage;
a first reference capacitor including a first electrode connected to the output terminal of the first differential amplifier and a second electrode connected to the inverting input terminal of the first differential amplifier;
a first on/off switch including a first end connected to the output terminal of the first differential amplifier and a second end connected to the inverting input terminal of the first differential amplifier;
a second on/off switch including a first end connected to the inverting input terminal of the first differential amplifier;
a third on/off switch including a first end connected to a first power-supply voltage and a second end connected to the second end of the second on/off switch;
a first sensor electrode connected to the second end of the second on/off switch and facing a ground electrode having a constant electric potential, a first variable capacitance being formed between the first sensor electrode and the ground electrode in response to a distance between the first sensor electrode and the ground electrode;
switch controlling means for performing a first switch operation in which the first on/off switch is shifted to a closed state and returned to an open state, and then alternately repeating a second switch operation in which the second on/off switch is shifted to a closed state and returned to an open state and a third switch operation in which the third on/off switch is shifted to a closed state and returned to an open state;
a comparator including a first input terminal connected to the output terminal of the first differential amplifier and a second input terminal inputting a voltage, the comparator comparing an output voltage from the first differential amplifier and the voltage input to the second input terminal;
counting means for counting the number of times the second switch operation is repeated; and
determining means for determining changes in the first variable capacitance formed between the first sensor electrode and the ground electrode based on the number of times the second switch operation is repeated that is counted by the counting means before an output level of the comparator is changed.

2. A capacitance detecting apparatus according to claim 1, wherein an electric potential input to the first input terminal of the comparator is in reverse phase to an electric potential input to the second input terminal of the comparator.

3. A capacitance detecting apparatus according to claim 1, further comprising:
a fourth on/off switch including a first end connected to the inverting input terminal of the first differential amplifier;
a first compensation capacitor including a first electrode connected to a second end of the fourth on/off switch and a second electrode connected to a first compensation voltage; and
a fifth on/off switch including a first end connected to the second end of the fourth on/off switch and a second end connected to the first compensation voltage; wherein the switch controlling means controls the fourth on/off switch to be opened and closed at the same timing as the second on/off switch and controls the fifth on/off switch to be opened and closed at the same timing as the third on/off switch.

4. A capacitance detecting apparatus according to claim 3, wherein an electric potential input to the first input terminal of the comparator is in reverse phase to an electric potential input to the second input terminal of the comparator.

5. A capacitance detecting apparatus according to claim 1, further comprising:
a first shield member surrounding at least a portion of electrode surfaces of the first sensor electrode except for a surface facing the ground electrode and a wiring that connects the first sensor electrode and the second and third on/off switches;
a first electric potential supply circuit retaining the first shield member at the first fixed voltage at least at a time the second on/off switch is shifted from the closed state to the open state; and
a second electric potential supply circuit retaining the first shield member at the first power-supply voltage at least at a time the third on/off switch is shifted from the closed state to the open state.

6. A capacitance detecting apparatus according to claim 5, further comprising:
a first current detection circuit arranged to be connected between the first electric potential supply circuit and the first shield member; and
a first electric potential applying means for applying an electric potential different from the first power-supply voltage to the first shield member during a predetermined time during which the third on/off switch is in a closed state.

7. A capacitance detecting apparatus according to claim 5, further comprising:
a first external shield member surrounding at least a portion of electrode surfaces of the first sensor electrode except for a surface facing the ground electrode, a wiring that connects the first sensor electrode and the second and third on/off switches, and the first shield member, the first external shield member being set at a predetermined constant electric potential.

8. A capacitance detecting apparatus comprising:
a first differential amplifier including an inverting input terminal, a non-inverting input terminal, and an output terminal, the non-inverting input terminal inputting a first fixed voltage;
a first reference capacitor including a first electrode connected to the output terminal of the first differential amplifier and a second electrode connected to the inverting input terminal of the first differential amplifier;
a first on/off switch including a first end connected to the output terminal of the first differential amplifier and a second end connected to the inverting input terminal of the first differential amplifier;
a second on/off switch including a first end connected to the inverting input terminal of the first differential amplifier;
a third on/off switch including a first end connected to a first power-supply voltage and a second end connected to the second end of the second on/off switch;
a first sensor electrode connected to the second end of the second on/off switch and facing a ground electrode having a constant electric potential, a first variable capacitance being formed between the first sensor electrode and the ground electrode in response to a distance between the first sensor electrode and the ground electrode;
a second differential amplifier including an inverting input terminal, a non-inverting input terminal, and an output terminal, the non-inverting input terminal inputting a second fixed voltage;
a second referential capacitor including a first electrode connected to the output terminal of the second differential amplifier and a second electrode connected to the inverting input terminal of the second differential amplifier;
a fourth on/off switch including a first end connected to the output terminal of the second differential amplifier and a second end connected to the inverting input terminal of the second differential amplifier;
a fifth on/off switch including a first end connected to the inverting input terminal of the second differential amplifier;
a sixth on/off switch including a first end connected to a second power-supply voltage and a second end connected to the second end of the fifth on/off switch;
a second sensor electrode connected to the second end of the fifth on/off switch and facing a ground electrode, a second variable capacitance being formed between the second sensor electrode and the ground electrode in response to a distance between the second sensor electrode and the ground electrode;
switch controlling means for performing a first switch operation in which the first on/off switch and the fourth on/off switch are each shifted to a closed state and returned to an open state, and then alternately repeating a second switch operation in which the second on/off switch and the fifth on/off switch are each shifted to a closed state and returned to an open state and a third switch operation in which the third on/off switch and the sixth on/off switch are each shifted to a closed state and returned to an open state;
a comparator including a first input terminal connected to the output terminal of the first differential amplifier and a second input terminal connected to the output terminal of the second differential amplifier, the comparator comparing an output voltage from the first differential amplifier and an output voltage from the second differential amplifier;
counting means for counting the number of times the second switch operation is repeated; and
determining means for determining changes in one of the first and second variable capacitances formed between the first and second sensor electrodes and the ground electrode, respectively, based on the number of times the second switch operation is repeated that is counted by the counting means before an output level of the comparator is changed.

9. A capacitance detecting apparatus according to claim 8, further comprising:
a seventh on/off switch including a first end connected to the inverting input terminal of the first differential amplifier;
a first compensation capacitor including a first electrode connected to a second end of the seventh on/off switch and a second electrode connected to a first compensation voltage;
an eighth on/off switch including a first end connected to the second end of the seventh on/off switch and a second end connected to the first compensation voltage;
a ninth on/off switch including a first end connected to the inverting input terminal of the second differential amplifier;
a second compensation capacitor including a first electrode connected to the second end of the ninth on/off switch and a second electrode connected to a second compensation voltage; and
a tenth on/off switch including a first end connected to the second end of the ninth on/off switch and a second end connected to the second compensation voltage; wherein the switch controlling means controls the seventh and ninth on/off switches to be opened and closed at the same timing as the second and fifth on/off switches and controls the eighth and tenth on/off switches to be opened and closed at the same timing as the third and sixth on/off switches.

10. A capacitance detecting apparatus according to claim 8, further comprising:
a first shield member surrounding at least a portion of electrode surfaces of the first sensor electrode except for a surface facing the ground electrode and a wiring that connects the first sensor electrode and the second and third on/off switches;
a first electric potential supply circuit retaining the first shield member at the first fixed voltage at least at a time the second on/off switch is shifted from the closed state to the open state;
a second electric potential supply circuit retaining the first shield member at the first power-supply voltage at least at a time the third on/off switch is shifted from the closed state to the open state;
a second shield member surrounding at least a portion of electrode surfaces of the second sensor electrode except for a surface facing the ground electrode and a wiring that connects the second sensor electrode and the fifth and sixth on/off switches;
a third electric potential supply circuit retaining the second shield member at the second fixed voltage at least at a time the fifth on/off switch is shifted from the closed state to the open state; and
a fourth electric potential supply circuit retaining the second shield member at the second power-supply voltage at least at a time the sixth on/off switch is shifted from the closed state to the open state.

11. A capacitance detecting apparatus according to claim 10, further comprising:
a first current detection circuit arranged to be connected between the first electric potential supply circuit and the first shield member;
a first electric potential applying means for applying an electric potential different from the first power-supply voltage to the first shield member during a predetermined time during which the third on/off switch is in a closed state;
a second current detection circuit arranged to be connected between the third electric potential supply circuit and the second shield member; and
a second electric potential applying means for applying an electric potential different from the second power-supply voltage to the second shield member during a predetermined time during which the sixth on/off switch is in a closed state.

12. A capacitance detecting apparatus according to claim 10, further comprising:
a first external shield member at least a portion of electrode surfaces of the first sensor electrode except for a surface facing the ground electrode, a wiring that connects the first sensor electrode and the second and third on/off switches, and the first shield member; and
a second external shield member surrounding at least a portion of electrode surfaces of the second sensor electrode except for a surface facing the ground electrode, a wiring that connects the second sensor electrode and the fifth and sixth on/off switches, and the second shield member;
the first external shield member and the second external shield member each being set at a predetermined constant electric potential.

13. A capacitor detecting apparatus according to claim 8, wherein an area of the first sensor electrode is equal to an area of the second sensor electrode, and a center of mass of the first sensor electrode matches a center of mass of the second sensor electrode.

14. A capacitor detecting apparatus according to claim 13, wherein the first sensor electrode is symmetrical relative to at least two symmetry planes crossing the matched centers of mass, and the second sensor electrode is symmetrical relative to the at least two symmetry planes crossing the matched centers of mass.
